(19) United States
(12) Patent Application Publication
(10) Pub. No.: US 2025/0336837 A1
(43) Pub. Date: Oct. 30, 2025

(54) SEMICONDUCTOR PACKAGE

(71) Applicant: LG INNOTEK CO., LTD., Seoul, (KR)

(72) Inventors: Se Woong NA, Seoul (KR); Jin Ho SONG, Seoul (KR); Kee Han LEE, Seoul (KR); Sang II KIM, Seoul (KR)

(21) Appl. No.: 18/867,917

(22) PCT Filed: Jun. 8, 2023
(86) PCT No.: PCT/KR2023/007896

§ 371 Date: Nov. 21, 2024

(30) Foreign Application Priority Data
Jun. 8, 2022 (KR) 10-2022-0069742
Nov. 4, 2022 (KR) 10-2022-0146412
Feb. 10, 2023 (KR) 10-2023-0018207

(51) Int. Cl. H01L 23/538; H01L 23/00; H01L 23/498; H01L 25/065

(52) U.S. Cl. CPC H01L 23/5386; H01L 23/49894; H01L 23/5384; H01L 24/14; H01L 24/16; H01L 25/0655; H01L 2224/1403; H01L 2224/14132; H01L 2224/16227; H01L 2224/16238

(57) ABSTRACT

A semiconductor package according to an embodiment includes an insulating layer including an upper surface and a lower surface; a protective layer disposed on the upper surface of the insulating layer; a connection member embedded in the insulating layer; and a wiring electrode embedded in the insulating layer and including an upper pad part disposed between the insulating layer and the protective layer, a first via electrode electrically connected to the connection member by passing through a portion of the insulating layer from the upper pad part and having a width narrower than a width of the upper pad part; a second via electrode embedded in the insulating layer and disposed closer to a lower surface of the insulating layer than the connection member; and a bonding part including a protruding portion disposed on the protective layer and a through portion passing through the protective layer from the protruding portion and directly contacting the upper pad part, wherein the bonding part includes a first bonding part overlapping the connection member in a vertical direction, and a second bonding part not overlapping the connection member in the vertical direction, and a slope angle of each of a through portion of the first bonding part and a through portion of the second bonding part with respect to the upper surface of the insulating layer is closer to vertical than a slope angle of the second via electrode with respect to the upper surface of the insulating layer.

### TECHNICAL FIELD

An embodiment relates to a semiconductor package.

### BACKGROUND ART

As the performance of electric/electronic products is being improved, technologies for disposing a larger number of semiconductor devices on a semiconductor package substrate of a limited size are being proposed and studied. However, since a general semiconductor package is based on mounting a single semiconductor device, there is a limit to obtaining the desired performance.

Accordingly, a semiconductor package that arranges a plurality of semiconductor devices using multiple substrates has been recently provided. This semiconductor package has a structure in which multiple semiconductor devices are connected to each other in a horizontal direction and/or a vertical direction on the substrate. Accordingly, the semiconductor package has the advantage of efficiently using a mounting area of the semiconductor devices and transmitting high-speed signals through a short signal transmission path between the semiconductor devices.

In addition, semiconductor packages applied to products that provide the Internet of Things (IoT), autonomous vehicles, and high-performance servers are expanding a concept to a semiconductor chiplet as a number of semiconductor devices and/or a size of each semiconductor device increases or functional parts of the semiconductor device is divided in accordance with a trend of high integration.

Accordingly, an intercommunication between semiconductor devices and/or semiconductor chiplets is becoming important, and accordingly, there is a trend to place an interposer between the substrate of the semiconductor package and the semiconductor devices.

The interposer can function as a redistribution layer that gradually increases a width of a circuit pattern from the semiconductor device toward the semiconductor package in order to facilitate the intercommunication between the semiconductor device and/or semiconductor chiplet, or to interconnect the semiconductor device and the semiconductor package substrate. Accordingly, it is possible to smoothly transmit an electrical signal between a semiconductor device and a semiconductor package substrate having a relatively large circuit pattern compared to a circuit pattern of the semiconductor device.

Meanwhile, a package substrate and/or interposer applied to the semiconductor package may be equipped with a connection member connected to the semiconductor device and/or semiconductor chiplet. The connection member functions to horizontally connect a plurality of semiconductor devices and/or semiconductor chiplets. Accordingly, the connection member may be embedded in the package substrate and/or interposer. At this time, the package substrate and/or the interposer may be provided with a plurality of bonding parts connected to the semiconductor device and/or the semiconductor chiplet. The bonding part may include a first bonding part that does not overlap with the connection member in a vertical direction, and a second bonding part that overlaps with the connection member in the vertical direction and overlaps with the first bonding part in a horizontal direction.

At this time, the first bonding part and the second bonding part may have different widths along the horizontal direction and/or different thicknesses along the vertical direction. That is, the width and/or thickness of the second bonding part may depend on a width of a pad provided in the connection member and a height of an upper surface of the pad, but the width and height of the first bonding part are not dependent on the width and/or height of the pad provided in the connection member. That is, when the integration of the number of I/O (Input and Output) terminals of the connection member increases, an current intensity generated during plating of the first and second bonding parts may differ depending on a diameter and a density of through holes of an insulating layer and/or protective layer disposed on the pad of the connection member, and accordingly, a height of the second bonding part may differ from that of the first bonding part.

Therefore, the first bonding part and the second bonding part according to a prior art may have a height deviation due to a difference in width and/or thickness between the first bonding part and the second bonding part. In addition, when a height deviation occurs between the first bonding part and the second bonding part, a problem may occur in which the semiconductor device and/or the semiconductor chiplet is not stably mounted on the first bonding part and the second bonding part. As a result, operating characteristics, reliability, and yield of the semiconductor device and/or the semiconductor chiplet may deteriorate.

In addition, as a number of pads of the connection member and a number of terminals of the semiconductor device increase, a fine pitch of two bonding parts adjacent to each other among the first bonding parts connected thereto is required. However, according to the prior art, a pitch between the two bonding parts adjacent to each other exceeds at least 60 um. That is, the circuit board includes an electrode part passing through an insulating layer and connected to the pad of the connection member, and a bonding part passing through a protective layer and disposed between a terminal of the semiconductor device and the electrode part. At this time, the electrode part includes a via electrode passing through the insulating layer and a pad electrode disposed on the via electrode. In addition, the bonding part includes a through portion passing through the protective layer and a protruding portion disposed on the through portion. At this time, a pitch between the two bonding parts adjacent to each other is determined by a width/spacing of the via electrode, a width/spacing of the pad electrode, a width/spacing of the through portion, and a width/spacing of the protruding portion. At this time, there is a limit to reducing a width of the via electrode and a width of the through portion, and as a result, a pitch between two adjacent bonding parts exceeds 60 um. Accordingly, there is a limit to improving the circuit integration of the semiconductor package and miniaturizing the semiconductor package.

### DISCLOSURE

### Technical Problem

The embodiment provides a semiconductor package having a novel structure.

In addition, the embodiment provides a semiconductor package capable of controlling a height deviation between a plurality of bump parts connected to a semiconductor device.

In addition, the embodiment provides a semiconductor package capable of minimizing a pitch between a plurality of bumps.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A semiconductor package according to an embodiment comprises an insulating layer including an upper surface and a lower surface; a protective layer disposed on the upper surface of the insulating layer; a connection member embedded in the insulating layer; and a wiring electrode embedded in the insulating layer and including an upper pad part disposed between the insulating layer and the protective layer, a first via electrode electrically connected to the connection member by passing through a portion of the insulating layer from the upper pad part and having a width narrower than a width of the upper pad part; a second via electrode embedded in the insulating layer and disposed closer to a lower surface of the insulating layer than the connection member; and a bonding part including a protruding portion disposed on the protective layer and a through portion passing through the protective layer from the protruding portion and directly contacting the upper pad part, wherein the bonding part includes a first bonding part overlapping the connection member in a vertical direction, and a second bonding part not overlapping the connection member in the vertical direction, and wherein a slope angle of each of a through portion of the first bonding part and a through portion of the second bonding part with respect to the upper surface of the insulating layer is closer to vertical than a slope angle of the second via electrode with respect to the upper surface of the insulating layer.

In addition, the first bonding part is provided in plural, and a separation distance in a horizontal direction between two first bonding parts that are closest to each other among the plurality of first bonding parts is 26 um or less.

In addition, each of the plurality of first bonding parts includes a plurality of first protruding portions, and a width of each of the plurality of first protruding portions in the horizontal direction is 29 μm to 34 μm.

In addition, the protective layer includes a plurality of first fillers, and the through portion of the first bonding part does not contact the plurality of first fillers.

In addition, the first via electrode includes a first overlapping via electrode overlapping the connection member in the vertical direction, and a slope angle of the first overlapping via electrode is same as a slope angle of the through portion of the first bonding part.

In addition, the insulating layer includes a plurality of laminated insulating layers disposed between the upper surface of the insulating layer and the lower surface of the insulating layer, the plurality of laminated insulating layers include an upper insulating layer forming an upper surface of the insulating layer, and a lower insulating layer forming a lower surface of the insulating layer, the wiring layer further includes a plurality of wiring electrodes disposed respectively within the plurality of laminated insulating layers, a plurality of via electrodes connecting the plurality of wiring electrodes, and a lower pad part disposed on the lower surface of the insulating layer, the plurality of via electrodes further include a plurality of upper vias overlapping the connection member along a horizontal direction, and a plurality of lower vias disposed between the plurality of upper vias and the lower surface of the insulating layer, and a slope angle of the upper via is symmetrical to a slope angle of the lower via.

In addition, a thickness of the upper insulating layer is thinner than a thickness of the lower insulating layer.

In addition, a first through portion of the first bonding part vertically overlaps at least a portion of the first overlapping via electrode.

In addition, the insulating layer includes a side surface positioned between the upper surface and the lower surface, the protective layer includes a lower surface facing the upper surface of the insulating layer, an upper surface corresponding to the lower surface, and a side surface positioned between the lower surface and the upper surface, and the side surface of the protective layer includes an inner surface surrounding the first through portion and the second through portion, respectively, and an outer surface adjacent to the side surface of the insulating layer, and a length in the vertical direction of the inner surface is different from a length in the vertical direction of the outer surface.

In addition, the length in the vertical direction of the inner surface is greater than the length in the vertical direction of the outer surface.

### Advantageous Effects

The embodiment includes a protective layer and a bonding part passing through a partial region of the protective layer from an upper surface of the protective layer. At this time, the protective layer has a through hole corresponding to the bonding part. The through hole of the protective layer is formed through a dry film pattern. That is, the through hole is formed corresponding to a width and a pitch that the bonding part provided in the semiconductor package should have. That is, the embodiment forms a dry film pattern in advance considering the width and pitch of the bonding part.

Through this, the embodiment can minimize a pitch between a plurality of bonding parts. For example, the embodiment can arrange a horizontal distance between centers of two adjacent bonding parts to be 40 μm or less. The embodiment can refine a pitch of the bonding part to 40 μm or less, and through this, the embodiment can improve the circuit integration degree and miniaturize the circuit board and the semiconductor package. In addition, the embodiment can reduce a distance between a plurality of bonding parts, and based on this, can minimize a transmission distance of a signal transmitted through a corresponding bump part. Therefore, the embodiment can minimize the signal transmission loss that increases according to the signal transmission distance, thereby improving the electrical characteristics of the circuit board and the semiconductor package. In addition, the embodiment can allow a semiconductor device to be disposed on the circuit board to operate stably, thereby enabling an electronic product such as a server to which the semiconductor package is applied to operate stably.

In addition, the embodiment has an electrode part disposed between the connection member and the bonding part. The electrode part passes through at least a portion of an insulating layer. At this time, the insulating layer has a through hole corresponding to the via electrode of the electrode part. In addition, the through hole of the insulating layer is provided through a dry film formed according to the width and pitch that the bonding part of the embodiment should have. Through this, the embodiment can form the electrode part corresponding to the width and pitch that the bonding part should have. Therefore, the embodiment can enable the bonding part to have a target width and pitch. In addition, the embodiment can form the electrode part at a position corresponding to the bonding part, thereby improving a positional alignment of the bonding part and the electrode part, and further improving the electrical characteristics of the bonding part and the electrode part.

In addition, the embodiment can minimize a height deviation between a plurality of bonding parts. That is, the embodiment includes a first bonding part that overlaps the connection member in the vertical direction and a second bonding part that does not overlap the connection member in the vertical direction. At this time, a size of a first through portion of the first bonding part is the same as a size of a second through portion of the second bonding part. That is, the embodiment can use a dry film pattern to make the through portions of the first bonding part and the second bonding part have the same size, thereby minimizing the height deviation between the first bonding part and the second bonding part that occurs due to a size difference.

Therefore, the embodiment can minimize the height deviation of the first bonding part and the second bonding part, thereby allowing the semiconductor element to be stably disposed on the first bonding part and the second bonding part. Therefore, the embodiment can improve the reliability of the first and second semiconductor devices. Furthermore, the embodiment can enable the operation of the first and second semiconductor elements to be performed smoothly, thereby enabling the operation of electronic products or servers to be performed smoothly.

In addition, the embodiment allows the first bonding part and the second bonding part to have the same height, thereby preventing problems such as impedance changes or signal transmission loss caused by changes in the thickness of the first bonding part and the second bonding part, and problems such as the semiconductor devices being disposed in a tilted state, and thereby further improving electrical reliability.

Furthermore, the embodiment can relatively lower a surface roughness of an interface between a through portion of each of the first bonding part and the second bonding part and the protective layer. Therefore, the embodiment can lower the surface roughness of the through portion, thereby minimizing the signal transmission loss that increases in proportion to the surface roughness. Therefore, the embodiment can further improve the operating characteristics of the semiconductor device.

Meanwhile, the upper surface of the protective layer of the embodiment can have a concave portion and a convex portion that increase an surface area of an upper surface of the protective layer by a process of thinning the thickness. The concave and convex portions can improve the reliability of the circuit board from heat cycles such as expansion and contraction of the circuit board due to heat generated during an operation of the semiconductor chip or applied from an outside. For example, since the convex and concave portions have different thicknesses, a volume deformed during thermal expansion can be different. That is, a thickness of the concave portion can be thinner than that of the convex portion, and the overall thermal deformation of the semiconductor package can be suppressed due to the difference in a thermal expansion coefficient of the convex portion and a thermal expansion coefficient of the concave portion. Therefore, the embodiment can prevent the semiconductor device coupled to an upper portion of the semiconductor package from being electrically separated during thermal expansion, and thus improve product reliability.

Furthermore, a via electrode located on the connection member of the embodiment has a different width and/or slope direction from the via electrode located under the connection member. That is, the via electrode located on the connection member has a more vertical side surface than the via electrode located under the connection member. That is, the embodiment can have the effect of improving the warpage of the circuit board by disposing the via electrode having a vertical side surface to be positioned on the connection member. In addition, when a via electrode having a vertical side surface has a finer pattern than a via electrode having an inclined side surface, the via electrode having a vertical side surface can be implemented to be positioned on the connection member so as to alleviate stress applied to the via electrode and thereby improve the reliability of the electrical connection between the semiconductor chip and the circuit board.

In addition, an upper surface of the protective layer of the embodiment includes a first region adjacent a through hole and including the through hole, and a second region excluding the first region. A height of the first region of the protective layer is greater than a height of the second region. The first region of the protective layer includes a convex portion that is convex in an upward direction. Specifically, the upper surface of the protective layer includes a convex portion that is convex in the upward direction while being connected to the inner surface of the through hole. The convex portion can improve the process characteristics in a process of disposing a connection part such as solder in the through hole of the protective layer. Specifically, the convex portion can serve as a barrier function to prevent diffusion of the connection part without increasing the overall thickness of the protective layer. Through this, the embodiment can prevent diffusion of the connection part disposed in the through hole, and accordingly, it is possible to refine the width and pitch of the connection part. Furthermore, the embodiment can solve the problem of a short circuit connecting to an adjacent pad due to diffusion of the connection part. Through this, the physical and electrical reliability of the circuit board and the semiconductor package can be improved.

In addition, the convex portion of the protective layer of the embodiment can have a closed loop shape that surrounds a periphery of the through hole while being positioned adjacent to the through hole. Through this, the embodiment can more efficiently prevent diffusion of the connection part disposed in the through hole, and thus improve product reliability.

In addition, the embodiment can form a connection part having a width corresponding to a width of an open region of the protective layer while maintaining a distance between the upper surface of the connection part and the upper surface of the protective layer equal to a POR by using the convex portion. Through this, the embodiment can reduce a solder bridge defect rate that may occur during a solder joint process.

In addition, the embodiment can remove a photo initiator provided in the protective layer. At this time, the photo initiator acts as a factor that deteriorates the physical characteristics and electrical characteristics of the semiconductor package. At this time, the embodiment can improve the physical characteristics and electrical characteristics of the circuit board since the photo initiator is not included in the protective layer. Furthermore, the embodiment can expand types of insulating layers that can be used as the protective layer since the photo initiator is not included in the protective layer, and further reduce an unit cost required for developing the protective layer. Furthermore, the embodiment can significantly reduce a tolerance between a center of the through hole of the protective layer and a center of the pad compared to a comparative example. Accordingly, the embodiment may improve mounting reliability of the semiconductor device, thereby improving the physical reliability and electrical reliability of the circuit board and the semiconductor package.

### DESCRIPTION OF DRAWINGS

FIG. 1a is a view illustrating a configuration of a circuit board according to an embodiment.

FIG. 1b is a plan view of a bonding part illustrated in FIG. 1a.

FIG. 1c is an enlarged view of a partial region R1 of FIG. 1a.

FIG. 1d is a cross-sectional view for explaining a surface roughness of a first protective layer of FIG. 1c.

FIGS. 2a and 2b are cross-sectional views showing a bonding part according to a prior art.

FIG. 3 is an enlarged view of a modified example of FIG. 1c.

FIG. 4a is a cross-sectional view illustrating a semiconductor package according to a second embodiment.

FIG. 4b is an enlarged view of a partial region R1 of FIG. 4a.

FIG. 4c is a cross-sectional view for explaining a surface roughness and structure of a first insulating layer according to a second embodiment.

FIG. 5 is an enlarged view of a partial region R1 of a semiconductor package of FIG. 4a according to a third embodiment.

FIG. 6 is an enlarged view of a partial region R1 of a semiconductor package of FIG. 4a according to a fourth embodiment.

FIG. 7 is a view illustrating a semiconductor package according to a fifth embodiment.

FIGS. 8a to 8q are cross-sectional views for describing a method of manufacturing the circuit board according to a second embodiment of FIG. 4A in order of processes.

FIG. 9 is a cross-sectional view illustrating a circuit board according to a comparative example.

FIG. 10 is a cross-sectional view illustrating a circuit board according to a sixth embodiment.

FIG. 11 is a cross-sectional view illustrating a first partial region of a circuit board of FIG. 10 in detail.

FIG. 12 is a cross-sectional view illustrating a second partial region of the circuit board of FIG. 11 in detail.

FIG. 13 is a cross-sectional view of a partial region of a circuit board for explaining a convex portion according to an embodiment.

FIGS. 14 (a) and (b) are plan views of a partial region of a circuit board for explaining a convex portion according to an embodiment.

FIG. 15 is a scanning electron microscope image illustrating a partial region of a circuit board of FIGS. 13 and 14.

FIG. 16 is a scanning electron microscope image illustrating an upper surface of a first protective layer of FIG. 12.

FIG. 17 is a scanning electron microscope image illustrating an inner surface of a through hole of a first protective layer of FIG. 12.

FIG. 18 is a view illustrating a resist pattern used to form a through hole of a first protective layer according to an embodiment.

FIGS. 19 (a) and (b) are plan views for explaining a tolerance (SRR: Solder Resist Registration) according to a comparative example.

FIGS. 20 (a) and (b) are views for explaining a tolerance according to a sixth embodiment.

FIG. 21 is a cross-sectional view illustrating a circuit board according to a seventh embodiment.

FIG. 22 is a cross-sectional view illustrating a circuit board according to an eighth embodiment.

FIG. 23 (a) to (c) are views illustrating various modified examples of the circuit board according to an embodiment.

FIG. 24 is a cross-sectional view illustrating a semiconductor package according to another embodiment.

FIG. 25 (a) to (c) are views showing arrangement reliability of first connection parts of embodiments and comparative examples.

FIGS. 26a to 26h are cross-sectional views for describing a method of manufacturing the circuit board shown in FIG. 10 in order of processes.

FIGS. 27a to 27n are cross-sectional views for describing a method of manufacturing a circuit board according to another embodiment in order of processes.

### BEST MODE

Hereinafter, embodiments of the present disclosure will be described in detail with reference to the accompanying drawings.

However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present disclosure, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

The terms used in the present application are used only to describe specific embodiments and are not intended to limit the present invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms used herein, including technical or scientific terms, have the same meaning as is generally understood by those of ordinary skill in the art to which the present invention pertains. Terms such as those defined in commonly used dictionaries should be interpreted as having meaning consistent with the meaning in the context of the relevant technology and are not interpreted in an ideal or overly formal sense unless explicitly defined in this application.

Hereinafter, the embodiment will be described in detail with reference to the attached drawings, but regardless of drawing symbols, identical or corresponding components will be given same reference numbers and redundant descriptions thereof will be omitted.

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. In addition, the semiconductor package includes a circuit board, a semiconductor chip, a bonding part for electrically connecting the semiconductor chip and the circuit board, a resin part for filling a space between the semiconductor chip and the circuit board, and a molding part for entirely surrounding the semiconductor chip. Here, various semiconductor chips may be mounted in the semiconductor package.

The semiconductor chip may include an active device and/or a passive device. The active device may be a semiconductor chip in a form of integrated circuits (ICs) with hundreds or even millions of them integrated into a single chip. The semiconductor chip may be a logic chip, a memory chip, etc. The logic chip may be a central processor (CPU), a graphics processor (GPU), etc. For example, the logic chip may be an application processor (AP) chip including at least one of a central processor (CPU), a graphics processor (GPU), a digital signal processor, an encryption processor, a microprocessor, a microcontroller, or an analog-to-digital converter, an application-specific IC (ASIC), etc., or a chip set including a specific combination of the above.

The memory chip may be a stack memory such as HBM. In addition, the memory chip may include a memory chip such as a volatile memory (e.g., DRAM), a non-volatile memory (e.g., ROM), a flash memory, etc.

Meanwhile, a product group to which the semiconductor package of the embodiment is applied may be any one of a CSP (Chip Scale Package), an FC-CSP (Flip Chip-Chip Scale Package), an FC-BGA (Flip Chip Ball Grid Array), a POP (Package On Package), and a SIP (System In Package), but is not limited thereto.

In addition, the electronic device may be a smart phone, a personal digital assistant, a digital video camera, a digital still camera, a vehicle, a high-performance server, a network system, a computer, a monitor, a tablet, a laptop, a netbook, a television, a video game, a smart watch, an automotive, etc. However, the present invention is not limited thereto, and may be any other electronic device that processes data in addition to these.

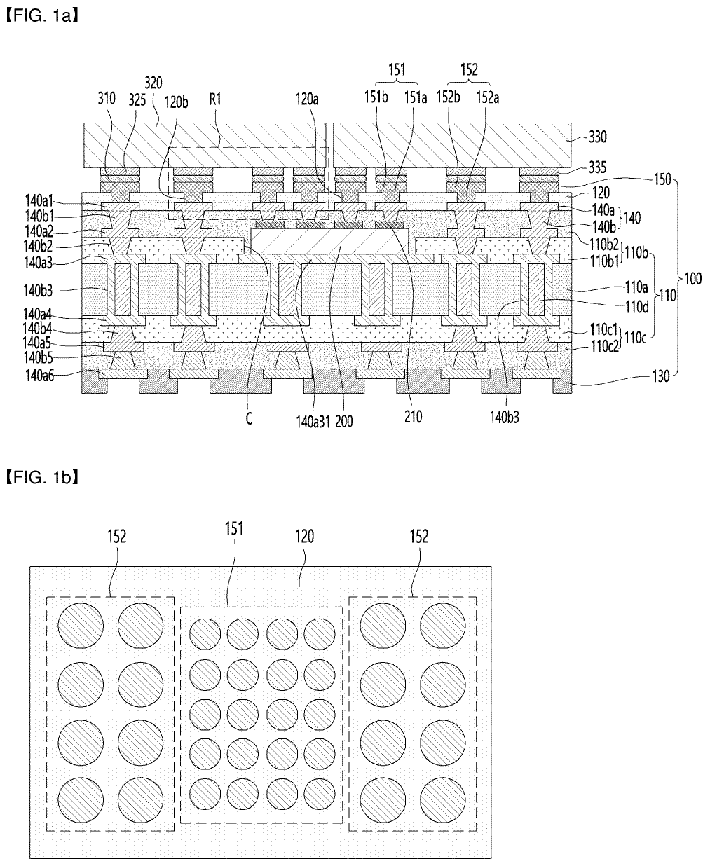

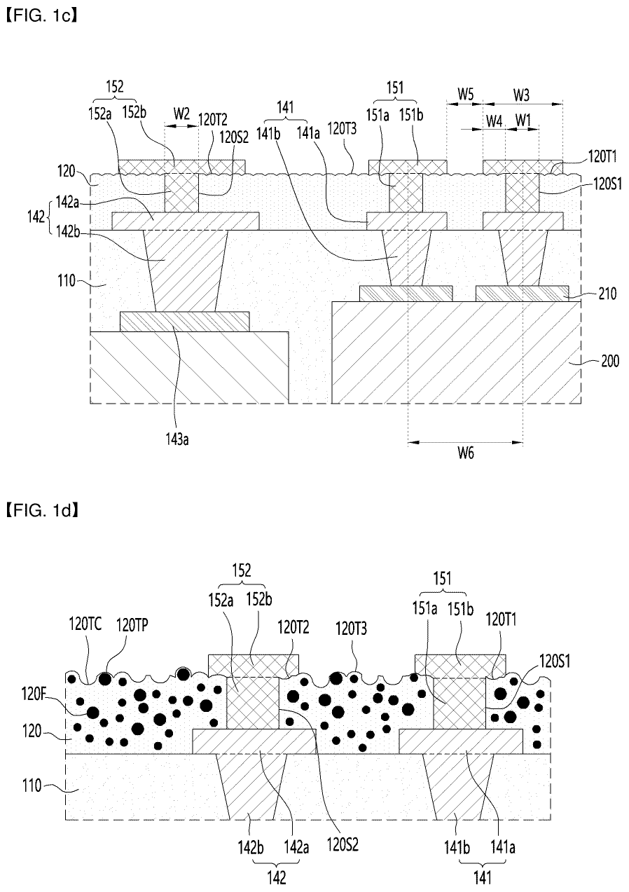

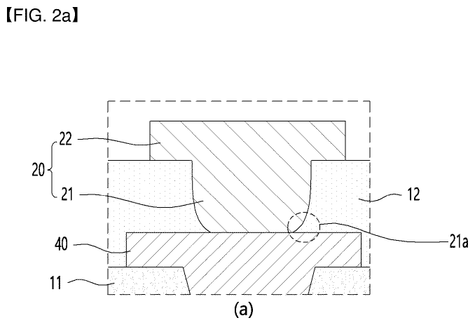

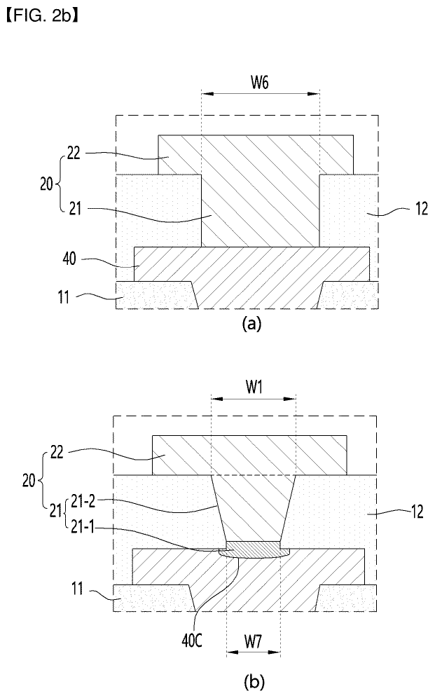

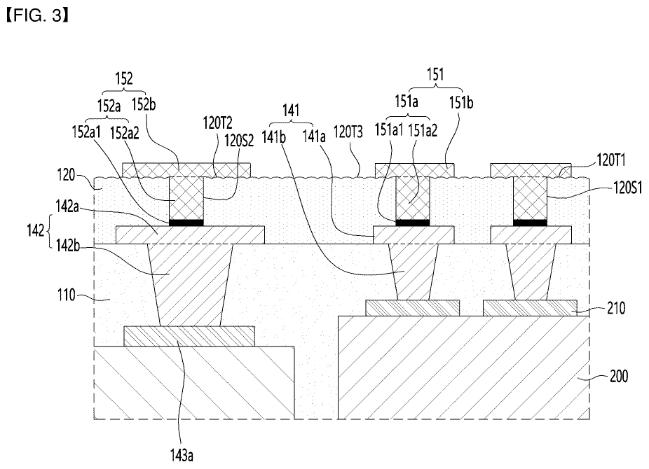

FIG. 1a is a view illustrating a configuration of a circuit board according to an embodiment, FIG. 1b is a plan view of a bonding part illustrated in FIG. 1a, FIG. 1c is an enlarged view of a partial region R1 of FIG. 1a, FIG. 1d is a cross-sectional view for explaining a surface roughness of a first protective layer of FIG. 1c, FIGS. 2a and 2b are cross-sectional views showing a bonding part according to a prior art, and FIG. 3 is an enlarged view of a modified example of FIG. 1c. Hereinafter, a semiconductor package of an embodiment will be described with reference to FIGS. 1a to 3.

Referring to FIG. 1a, a semiconductor package according to an embodiment includes a circuit board 100 electrically connecting a main board of an electronic device and a semiconductor chip 320 and 330, a plurality of semiconductor chips 320 and 330 mounted on the circuit board 100, and a connection member 310 electrically connecting the plurality of semiconductor chips 320 and 330 and the circuit board 100.

For easy explanation of the embodiment, terms referring to components included in the semiconductor package are described, and a description of each of the components referred to is described later.

The circuit board 100 illustrated in FIG. 1a includes an insulating layer 110, an electrode part 140, a protective layer 120 and 130, and a connection member 200. For example, the insulating layer 110 is provided with a structure in which the first to fifth insulating layers 110b2, 110b1, 110a, 110c1, and 110c2 are sequentially laminated. An upper surface of the first insulating layer 110b2 is provided as an upper surface of the insulating layer 110, and a lower surface of the fifth insulating layer 110c2 is provided as a lower surface of the insulating layer 110. At this time, the first insulating layer 110b2 and the second insulating layer 110b1 may be referred to as an upper insulating layer, and the fourth insulating layer 110c1 and the fifth insulating layer 110c2 may be referred to as a lower insulating layer.

A first protective layer 120 is provided on the upper surface of the insulating layer 110, and a second protective layer 130 is provided on the lower surface of the insulating layer 110.

The electrode part 140 includes a wiring electrode 140a, a via electrode 140b, and a bonding part 150.

The wiring electrode 140a includes a first wiring electrode 140a1 disposed on an upper surface of the first insulating layer 110b2, a second wiring electrode 140a2 disposed on an upper surface of the second insulating layer 110b1, a third-first wiring electrode 140a3 disposed on an upper surface of the third insulating layer 110a, a third-second wiring electrode 140a4 disposed on a lower surface of the third insulating layer 110a, a fourth wiring electrode 140a5 disposed on a lower surface of the fourth insulating layer 110c1, and a fifth wiring electrode 140a6 disposed on a lower surface of the fifth insulating layer 110c2. The via electrode 140b includes a first via electrode 140b1 connecting the first wiring electrode 140a1 and the second wiring electrode 140a2, a second via electrode 140b2 connecting the second wiring electrode 140a2 and the third-first wiring electrode 140a3, a third via electrode 140b3 connecting the third-first wiring electrode 140a3 and the third-second wiring electrode 140a4, a fourth via electrode 140b4 connecting the third-second wiring electrode 140a4 and the fourth wiring electrode 140a5, and a fifth via electrode 140b5 connecting the fourth wiring electrode 140a5 and the fifth wiring electrode 140a6.

In addition, each wiring electrode 140a includes a pad and/or a trace. A trace functions to transmit signals and/or power to a semiconductor device, and may be referred to as a circuit pattern. A pad functions as a connection part for electrically connecting a semiconductor device and a trace, or connecting traces disposed on each insulating layer. If a width of a trace is made sufficiently large to directly connect a semiconductor device to the trace, a pad may be unnecessary. However, if the width of a trace is excessively large, there is a problem that the impedance may increase, and there is a problem that the trace cannot be integrated into a limited circuit board area. Therefore, a pad generally has the same function of electrical conductivity as a trace, but is provided to have a wider width than a trace in order to have an additional function of being able to contact a through electrode or a semiconductor device. In addition, FIG. 1a may illustrate a pad of each wiring electrode 140a.

For example, the first wiring electrode 140a1 includes a first pad for connection with the first via electrode 140b1 and/or the bonding part 150. The second wiring electrode 140a2 includes a second pad connected with the first via electrode 140b1 and/or the second via electrode 140b2. The third-first wiring electrode 140a3 includes a third-first pad connected with the second via electrode 140b2 and/or the third via electrode 140b3 and a third-second pad 140a31 connected with the connection member 200. The third-second wiring electrode 140a4 includes a third-second pad connected with the third via electrode 140b3 and/or the fourth via electrode 140b4. The fourth wiring electrode 140a5 includes a fourth pad connected to the fourth via electrode 140b4 and/or the fifth via electrode 140b5. The fifth wiring electrode 140a6 includes a fifth pad connected to the fifth via electrode 140b5 and/or the main board of the electronic device.

In addition, the circuit board 100 includes a bonding part 150 disposed on the first protective layer 120. The bonding part 150 includes a protruding portion 151b and 152b disposed on the first protective layer 120, and a through portion 151a and 152a passing through the first protective layer 120 and connected to the pad of the first wiring electrode 140a1. A connection member 200 may be embedded in the insulating layer 110. According to an embodiment, the connection member 200 is disposed between the first insulating layer 110b1 and the second insulating layer 110b2, but a location where the connection member is embedded is not limited thereto, and the connection member may be embedded in an insulating layer other than the first insulating layer 110b1 and the second insulating layer 110b2.

The laminated first to fifth insulating layers 110b2, 110b1, 110a, 110c1, and 110c2 may be formed of an insulating material having a function of facilitating a process, reducing a loss of a signal transmitted through the electrode part 140, or forming a fine spacing between the electrode parts 140. In addition, the first to fifth insulating layers 110b2, 110b1, 110a, 110c1, and 110c2 may all be formed of the same insulating material, but are not limited thereto, and at least one insulating layer may be formed of an insulating material different from the other insulating layers. For example, ABF (Ajinomoto Build-up Film), a product released by Ajinomoto Co., Ltd., can be used, and FR-4, BT (Bismaleimide Triazine), and PID (Photo Image-able Dielectric resin) can be used.

For example, the third insulating layer 110a can include a reinforcing member including at least one of glass fiber and GCP (Glass Core Primer). The reinforcing member can improve the rigidity of the insulating layer, thereby preventing the circuit board 100 and/or the semiconductor package from being bent in a specific direction. If the insulating layer 110 is bent in a specific direction during the process of forming the circuit board 100, the accuracy of the position may decrease during a process of disposing the electrode part 140, but this problem can be solved as the rigidity of the circuit board 100 is improved. In addition, even when mounting a semiconductor chip 320 and 330 on a circuit board 100, it is possible to prevent problems such as electrical short circuits or open circuits of the semiconductor chip 320 and 330 due to warpage of the circuit board 100. In addition, it may be prevented by a warpage problem caused by a heat cycle occurring during the operation of the semiconductor package, and accordingly, a product such as a server to which the semiconductor package of the embodiment is applied may operate stably, thereby improving the overall reliability of the product.

According to FIG. 1a, an insulating member 110d is provided in a third insulating layer 110a including a reinforcing member. The insulating member 110d passes through the third insulating layer 110a including the reinforcing member. The insulating member 110d may be provided with hole plugging ink, but is not limited thereto. The insulating member 110d is provided surrounded by a third via electrode 142b3 that passes through the third insulating layer 110a. When the third insulating layer 110a is thick, a problem may occur in which the third via electrode 142b3 passing through the third insulating layer 110a layer does not densely fill the through hole of the third insulating layer 110a. This problem may cause the pads of each of the third-first wiring electrodes 140a3 and/or the third-second wiring electrodes 140a4 not to be plated flatly, or a void to be generated inside the third via electrode 142b3. Therefore, the arrangement of the insulating member 110d can solve electrical reliability problems and/or mechanical reliability problems that may occur due to the through hole of the third insulating layer 103a not being entirely filled. For example, the third insulating layer 110a may have a thickness in a range of 0.4T to 1.5T in order to ensure ease of process and rigidity.

For example, at least one of the first insulating layer 110b2, the second insulating layer 110b1, the fourth insulating layer 110c1, and the fifth insulating layer 110c2 may include a filler made of an inorganic material. The filler has a different size and/or shape from the reinforcing member included in the third insulating layer 110a. A diameter and content of the filler may be adjusted in consideration of a coefficient of thermal expansion, rigidity, etc. of each of the first insulating layer 110b2, the second insulating layer 110b1, the fourth insulating layer 110c1, and the fifth insulating layer 110c2, and to solve problems such as light scattering during a laser process for densely disposing the electrode parts 140. For example, to solve the above-described problem, the diameter of the filler may be applied to 0.1 um to 5.0 um, and the content of the filler may be applied to 30 wt % to 40 wt % or 78 wt % to 85 wt %, but is not limited thereto. However, the embodiment is not limited thereto, the first insulating layer 110b2, the second insulating layer 110b1, the fourth insulating layer 110c1, and the fifth insulating layer 110c2 may include a reinforcing member including at least one of glass fiber and GCP (Glass Core Primer).

The circuit board 100 includes a first protective layer 120 disposed on an upper surface of the first insulating layer 110b2 and a second protective layer 130 disposed on a lower surface of the fifth insulating layer 110c2 to protect the surface thereof. The first and second protective layers 120 and 130 may be provided with, for example, a photosensitive material and/or a solder resist, in order to prevent short circuits between the connection parts 310, such as solder or wires, when bonding between the semiconductor chip and the circuit board 100 and/or the main board and the circuit board 100, while protecting the pad from external moisture or contaminants. In addition, a photosensitive solder resist can be applied, for example. According to the present embodiment, the semiconductor chip 320 and 330 and/or the main board of the electronic device, etc. can have a plurality of terminals disposed at a high density for connection to the circuit board 100. In addition, when the plurality of terminals and the bonding part 150 of the circuit board 100 are bonded, a solder can be used. In this case, when using the solder, a solder short circuit problem may occur between terminals having high density. In order to solve this short circuit problem, a solder resist having poor wettability with the solder is disposed to prevent diffusion or movement of the solder, thereby preventing the solder short circuit problem between the terminals. The first protective layer 120 and the second protective layer 130 may be disposed with different thicknesses in consideration of the warpage or coefficient of thermal expansion of the circuit board 100. This may vary depending on the area and thickness of the circuit board 100, but according to the present embodiment, a thickness of the first protective layer 120 may have a portion that is thicker than a thickness of the second protective layer 130. Here, the portion means at least one region of an upper surface of the first protective layer 120, which may mean that the thickness of the first protective layer 120 may not be uniformly disposed, or that the thickness of the first protective layer 120 may be uniformly disposed and thicker than the second protective layer 130.

The traces of the first to fifth wiring electrodes 140a1, 140a2, 140a3, 140a4, 140a5, and 140a6 may be designed in various shapes in consideration of impedance and bending of the circuit board 100 for transmitting signals and power between the semiconductor chip 320 and 330 and the main board of the electronic device. The traces of the first to fifth wiring electrodes 140a1, 140a2, 140a3, 140a4, 140a5, and 140a6 can be designed and disposed with a width and spacing of 2 μm to 10 μm, in order to have a high density while considering the signal and impedance and to secure adhesion with each insulating layer 110 to prevent the problem of peeling. That is, the traces of the first to fifth wiring electrodes 140a1, 140a2, 140a3, 140a4, 140a5, and 140a6 can be disposed to have various widths and spacing, from a design in which the traces are disposed with a width of 2 μm and a spacing of 2 μm, to a design in which the traces are disposed with a width of 10 μm and a spacing of 10 μm.

At this time, the width and spacing of the first to fifth wiring electrodes 140b1, 140b2, 140b3, 140b4, and 140b5 described above are too small to arrange the first to fifth via electrodes 140b1, 140b2, 140b3, 140b4, and 140b5 for vertically connecting the first to fifth wiring electrodes 140a1, 140a2, 140a3, 140a4, 140a5, and 140a6. Therefore, the width of the above-described wiring electrodes 140a1, 140a2, 140a3, 140a4, 140a5, and 140a6 is too narrow to secure the positional alignment of the first to fifth via electrodes 140b1, 140b2, 140b3, 140b4, and 140b5 or to form the first to fifth via electrodes 140b1, 140b2, 140b3, 140b4, and 140b5. Here, vertical means a direction in which the first to fifth insulating layers 110b2, 110b1, 110a, 110c1, and 110c2 are laminated, and vertical and vertical direction may be used in the same sense. In addition, the same definition applies to a vertical relationship of components described below. Accordingly, in order to secure the positional alignment of the first to fifth via electrodes 140b1, 140b2, 140b3, 140b4, and 140b5 and to place the first to fifth via electrodes 140b1, 140b2, 140b3, 140b4, and 140b5, each of the first to fifth wiring electrodes 140a1, 140a2, 140a3, 140a4, 140a5, and 140a6 includes the first to fifth pads, respectively. Each pad of the first to fifth wiring electrodes 140a1, 140a2, 140a3, 140a4, 140a5, and 140a6 has a width wider than the width of each trace of the first to fifth wiring electrodes 140a1, 140a2, 140a3, 140a4, 140a5, and 140a6 described above in order to be connected to the first to fifth via electrodes 140b1, 140b2, 140b3, 140b4, and 140b5. For example, each pad of the first to fifth wiring electrodes 140a1, 140a2, 140a3, 140a4, 140a5, and 140a6 may have a circular structure, and a diameter thereof may range from 30 um to 100 um. However, the embodiment is not limited thereto, depending on technical limitations of a process for disposing the first to fifth via electrodes 140b1, 140b2, 140b3, 140b4, and 140b5, each pad of the first to fifth wiring electrodes 140a1, 140a2, 140a3, 140a4, 140a5, and 140a6 may have the same width as the width of each trace of the first to fifth wiring electrodes 140a1, 140a2, 140a3, 140a4, 140a5, and 140a6.

For example, in order to arrange the first via electrode 140b1, a through hole is processed through a laser in a partial region of the first insulating layer 110b2. At this time, the through hole has a size corresponding to a beam size of the laser. Thereafter, by disposing the pad and trace of the first via electrode 140b1 and the first wiring electrode 140a1 as one, productivity and yield can be improved. Therefore, the first via electrode 140b1 can have a lower surface that is located on the same plane as the upper surface of the pad of the second wiring electrode 140a2. That is, for example, the first via electrode 140b1 can be referred to as a protruding portion in which a part of the pad of the first wiring electrode 140a1 protrudes toward the pad of the second wiring electrode 140a2. Here, the upper surface of the pad of the second wiring electrode 140a2 does not necessarily mean a flat surface, but should be understood to include a concave surface or a convex surface that may appear depending on various processes.

For example, the upper surface of the second wiring electrode 140a2 that contacts the lower surface of the first via electrode 140b1 has a concave surface. In the process of forming the first via electrode 140b1, if the pad of the second wiring electrode 140a2 is exposed to an air, a surface of the pad of the second wiring electrode 140a2 may be oxidized, or the adhesive strength of the surface of the pad of the second wiring electrode 140a2 for contacting the first via electrode 140b1 may decrease or an impedance may increase due to a chemical reaction between the pad of the second wiring electrode 140a2 and the first insulating layer 110b2. Accordingly, by removing a portion of the surface of the pad of the second wiring electrode 140a2 exposed to the through hole of the first insulating layer 110b2 before disposing the first via electrode 140b1 and then disposing the first via electrode 140b1, problems such as cracks, peeling, and increase in impedance between the pads of the first via electrode 140b1 and the second wiring electrode 140a2 can be prevented. In addition, since the first via electrode 140b1 is disposed integrally with the first wiring electrode 140a1, it can be referred to as being positioned on the same plane as the lower surface of the pad of the first wiring electrode 140a1. Since the first via electrode 140b1 has a width smaller than the width of the pad of the first wiring electrode 140a1, it may be referred to as the first via electrode 140b1 as described above in order to distinguish it from the pad of the first wiring electrode 140a1. The second to fifth via electrodes 140b2, 140b3, 140b4, and 140b5 may also be referred to in the same manner as the first via electrode 140b1 described above.

The connection member 200 functions to electrically connect a plurality of semiconductor chips 320 and 330 to each other. In FIG. 1a, two semiconductor chips 320 and 330 are illustrated as examples, but the present invention is not limited thereto and a greater number of semiconductor chips may be mounted. In addition, the connection member 200 is also illustrated as electrically connecting two chips, but it is not limited thereto and can connect a larger number of semiconductor chips. In addition, the semiconductor chips 320 and 330 here can be logic chips such as memory, processor, GPU, etc., and can be chiplets by functional division of each logic chip.

According to FIG. 1a, the connection member 200 includes a plurality of pads 210 and is embedded and disposed in the circuit board 100. A plurality of pads 210 of a connection member 200 are electrically connected to an electrode part 140 of a circuit board 100, and an electrode part 140 of a circuit board 100 connected to a plurality of pads 210 of a connection member 200 is electrically connected to a terminal 325 and 335 of a semiconductor chip 320 and 330 through a bonding part 150, thereby performing a communication function between the semiconductor chips 320 and 330.

In FIG. 1a, the connection member 200 is illustrated as having a structure in which it is embedded and disposed within the circuit board 100, but is not limited thereto, and may be disposed without being embedded on the circuit board 100. That is, the connection member 200 may be embedded in the circuit board 100 in order to make the circuit board 100 thinner, but the connection member 200 can be placed so as not to be buried on the circuit board 100 in order to solve problems such as height deviation between bonding parts 150 of the circuit board 100 and errors in the process of disposing the connection member 200 in the correct position when burying the connection member. In this case, although not shown, a molding member (not shown) may be disposed on the circuit board 100, and the connection member 200 may be embedded in the molding member. The molding member (not shown) may be made of a resin such as EMC (Epoxy Molding Compound), and in this case, the connection member 200 may be electrically connected to the semiconductor chip 320 and 330 through an electrode passing through the molding member.

The connection member 200 is composed of at least one material selected from the group consisting of silicon, organic matter, and glass, and can be disposed on the circuit board 100 and can function as an interposer. When the connection member 200 functions as an interposer, the connection member has a narrower spacing than the spacing of the electrode parts 140 of the circuit board 100, so that a finer pattern than the circuit board 100 is provided, and a buffer function of the pattern can be performed between a pattern of the semiconductor chip 320 and 330 and a pattern of the circuit board 100. Here, the pattern may mean not only the shape of wires or terminals for electrical connections such as the terminal, the wiring electrode and the via electrode of the semiconductor package including the electrode part 140 of the circuit board 100, the terminal 325 and 335 of the semiconductor chip 320 and 330, and the pad 210 of the connection member 200, but also a size, width, and spacing of the wiring or terminal for electrical connection. In addition, in FIG. 1a, the connection member 200 is disposed to have a width smaller than a sum of widths in a horizontal direction of each of the semiconductor chips 320 and 330, but is not limited thereto, and may have a wide width so that all of the semiconductor chips 320 and 330 can be disposed on the connection member 200. When the connection member 200 is made of silicon and has a wide width so that all of the semiconductor chips 320 and 330 can be disposed, the connection member 200 may be referred to as a silicon interposer.

According to FIG. 1c, which is an enlarged view of one region of FIG. 1a, a bonding part 150 is disposed on a first protective layer 120, and the bonding part 150 includes a protruding portion 151b and 152b disposed on the first protective layer 120 and a through portion 151a and 152a passing through the first protective layer 120 and directly contacting a pad 141a and 142a of a first wiring electrode 140a1 disposed on a first insulating layer 110b2 of a circuit board 100. The bonding part 150 includes a protruding portion 151b and 152b disposed on the first protective layer 120 to reduce the volume of solder by using thermal compression bonding and to prevent electrical short circuits between two adjacent bonding parts 150. In addition, the bonding part 150 has a through portion 151a and 152a that directly contacts the pad 141a and 142a of the first wiring electrode 140a1 on the first insulating layer 110b2 in order to connect the above-described protruding portion 151b and 152b with the circuit board 100.

At this time, the pad 141a and 142a of the first wiring electrode 140a1 on the first insulating layer 110b2 can be formed by forming a first via electrode 140b1 passing through a portion of the first insulating layer 110b2 to have a fine pattern spacing, and then performing a polishing process. However, when performing a polishing process, there may be a decrease in yield due to problems such as warping and wrinkles of the circuit board 100, and in particular, there is a problem that it is difficult to secure positional accuracy during a process of connecting the through portion 151a and 152a of the bonding part 150 to the circuit board 100. Therefore, in the present invention, technical ideas and means are described through embodiments within a scope of not performing a polishing process.

Referring to FIG. 1a, the bonding part 150 may include a first bonding part 151 that vertically overlaps the connection member 200 and a second bonding part 152 that does not vertically overlap. Since the connection member 200 has a finer electrode pattern than the electrode part 140 of the circuit board 100 as described above, the first bonding part 151 has a finer electrode pattern than the second bonding part 152. Specifically, the first bonding part 151 located between the connection member 200 and the semiconductor chip 320 and 330 among the bonding parts 150 has a finer electrode pattern than the second bonding part 152. For example, referring to FIG. 1a, the bonding part 150 includes a first bonding part 151 and a second bonding part 152, and the first bonding part 151 has a finer pattern than the second bonding part 152. Similarly, the first wiring electrode 140a1 and the first via electrode 140b1 of the electrode part 140 connected to the bonding part 150 also include a first portion 141 and a second portion 142. For example, the first wiring electrode 140a1 includes a first portion 141a that overlaps the connection member 200 in the vertical direction and a second portion 142a that does not overlap the first portion 141a in the vertical direction, and the first portion 141a of the first wiring electrode 140a1 may have a finer pattern than the second portion 142a of the first wiring electrode 140a1. In addition, the first via electrode 140b1 may similarly include a first portion 141b and a second portion 142b, and the first portion 141b may have a finer pattern than the second portion 142b. Accordingly, electrical connection reliability between the connection member 200, the circuit board 200, and the semiconductor chip 320 and 330 can be improved by performing a buffer function of a pattern for electrically connecting the circuit board 100 and the connection member 200. In addition, according to an embodiment, the third-first wiring electrode 140a3, the third-second wiring electrode 140a4, the fourth wiring electrode 140a5, the fifth wiring electrode 140a6, the second via electrode 140b2, the third via electrode 140b3, the fourth via electrode 140b4, and the fifth via electrode 140b5 are located below the connection member 200 (for example, located below a pad of the connection member) and therefore may not be connected to a fine pattern of the connection member 200. Accordingly, each of the third-first wiring electrode 140a3, the third-second wiring electrode 140a4, the fourth wiring electrode 140a5, the fifth wiring electrode 140a6, the second via electrode 140b2, the third via electrode 140b3, the fourth via electrode 140b4, and the fifth via electrode 140b5 may have the same degree of fineness of pattern regardless of whether or not they overlap with the connection member 200 in the vertical direction. Hereinafter, the first portion 141 of the electrode part 140 refers to an electrode part 140 that is positioned between the connection member 200 and the semiconductor chip 320 and 330 and vertically overlaps with the connection member 200. In addition, the second portion 142 of the electrode part 140 is refers to an electrode part 140 that is positioned between the connection member 200 and the semiconductor chip 320 and 330 and does not vertically overlap with the connection member 200 but horizontally overlaps with the first portion 141.

Referring to FIG. 1A, a size of the first bonding part 151 is depicted as being smaller than a size of the second bonding part 152. This may be because a density of the first bonding part 151 to be connected to the connection member 200 is higher than a density of the second bonding part 152. Therefore, the electrical connection reliability between the connection member 200 and the semiconductor chip 320 and 330 can be improved by disposing a size of the first bonding part 151 to be smaller than a size of the second bonding part 152. FIG. 1b illustrates the upper surface of the first bonding part 151 and the second bonding part 152 of the circuit board 100. For example, FIG. 1b illustrates an upper surface of a protruding portion 151b of the first bonding part 151 and an upper surface of a protruding portion 152b of the second bonding part 152.

As illustrated in FIG. 1b, a size and spacing of the first bonding part 151 are smaller than a size and spacing of the second bonding part 152. The first bonding part 151 connects the connection member 200 and the semiconductor chip 320 and 330 to each other. Accordingly, the first bonding part 151 is disposed with a smaller size and spacing than the second bonding part 152 of the bonding part to correspond to the fine pattern of the pad 210 of the connection member 200 and the terminal 325 and 335 of the semiconductor chip 320 and 330 in a vertically overlapping region. At this time, a part of the first bonding part 151 is disposed between a first semiconductor chip 320 and a connection member 200, and a remaining part of the first bonding part 151 is disposed between a second semiconductor chip 330 and a connection member 200. In addition, a part of the second bonding part 152 overlaps the first semiconductor chip 320 in the vertical direction without overlapping the connection member 200 in the vertical direction, and a remaining part of the second bonding part 152 overlaps the second semiconductor chip 330 in the vertical direction without overlapping the connection member 200 in the vertical direction.

Referring to FIG. 1a, the through portion 151a and 152a of the bonding part 150 gradually narrows in width toward the connection member 200 and passes through the first protective layer 120 to contact the pad 141a and 142a of the first wiring electrode 140a1. A process of processing first and second through holes 120a and 120b in the first protective layer 120 is performed in order to arrange the first bonding part 151 and the second bonding part 152. Recently, in a trend of increasing a number of pads 210 of the connection member 200, increasing a number of terminals 325 and 335 of the semiconductor chip 320 and 330, or increasing a number of semiconductor chips 320 and 330 to be connected, the first through hole 120a may be required to have a width of 20 um or less, and the second through hole 120b may be required to have a width of more than 30 um. At this time, the first protective layer 120 is formed of a photosensitive material, and thus, in a conventional technology, the first protective layer 120 is exposed and developed to form the through hole. However, it is difficult to process a width of the first through hole 120a to be 20 um or less due to a limitation of a resolution of an exposure process. Therefore, in a conventional technology, the first through hole 120a is formed using a laser process. When both the first through hole 120a and the second through hole 120b are processed by a laser process, the yield may be significantly reduced, such as wrinkles occurring on a surface of the circuit board 100 during a process due to stress caused by the laser. Therefore, in a conventional technology, the first through hole 120a is processed by a laser process, and the second through hole 120b is formed using an exposure process. However, in this case, a difference in a width of the first through hole 120a and a width of the second through hole 120b occurs, and accordingly, in a plating process for disposing the first bonding part 151 and the second bonding part 152, a plating deviation occurs due to a difference in current intensity applied to the first through hole 120a and the second through hole 120b, and thus a height deviation occurs between the first bonding part 151 and the second bonding part 152.

In addition, when the first through hole 120a is formed using a laser process, since a laser beam has a Gaussian distribution, an inner wall of the first through hole 120a has a portion extending vertically and a curved portion whose width narrows in a portion adjacent to the pad 141a and 142a of the first wiring electrode 140a1. Specifically, as illustrated in FIG. 2a, in a conventional technology, a through hole is formed in a protective layer 12 through a laser process, thereby minimizing a width of a bonding part 20. However, when the through hole is formed in the protective layer 12 through a laser process, a curved portion whose width is narrowed in a portion adjacent to the pad 40 is included due to the characteristics of the laser beam having a Gaussian distribution. Therefore, a through portion 21 of the bonding part 20 disposed within the through hole of the protective layer 12 has a curved portion 21a whose width is rapidly narrowed in a portion adjacent to the pad 40. At this time, since the bonding part that is not vertically overlapped with the connection member 200 has a larger width than the bonding part that is vertically overlapped with the connection member 200, even if a curved portion is included, no major problems may occur in terms of physical reliability and/or electrical reliability. However, since the bonding part that overlaps the connection member 200 in the vertical direction has a relatively small width, stress may be applied to the curved portion 21a due to a heat cycle of the protective layer 12 caused by heat generated during the operation of the semiconductor chip 320 and 330 or by a subsequent process, and accordingly, a crack may occur at an interface between the through portion 21 of the bonding part 20 and the pad 40, or a reliability problem may occur in which the through portion 21 of the bonding part 20 is peeled off from the pad 40. To solve this, when increasing a width of the bonding part 20, it may be difficult to adjust a pitch between the plurality of bonding parts to 40 um or less, and accordingly, an area of the semiconductor package may be increased, and thus it may be difficult to reduce the thickness. Furthermore, when forming a through hole in the protective layer 12 through a laser process, a process time may increase, which may reduce productivity. Furthermore, when forming a through hole with a relatively small width through a laser process, it may be difficult to align a laser beam to an accurate position, and accordingly, defects such as the position of the through hole being misaligned may occur, which may reduce the product yield.

Here, a pitch means a distance between center lines of each of the plurality of first bonding parts 151 of the bonding part 150, and may be defined as a horizontal distance W6 shown in FIG. 1c. A manufacturing method for implementing a fine pitch of the plurality of first bonding parts 151 of the bonding part 150 and improving reliability according to the embodiment will be described later.

In contrast, the embodiment illustrated in FIG. 1a is provided such that an inner wall of the first through hole 120a is vertical. That is, the first through hole 120a of the embodiment has a width of 20 μm or less, and an inner wall of the first through hole 120a does not include a curved portion as in the conventional technology. Through this, even if a width of the first through hole 120a is made fine, the embodiment can increase a width of the first through hole 120a in a region closest to the pad 141a and 142a compared to the conventional technology, thereby securing a contact area between the pad 141a and 142a and the bonding part 150, thereby improving the adhesion.

In contrast, the embodiment illustrated in FIG. 1a is provided such that an inner wall of the first through hole 120a is vertical. Specifically, the inner wall of the first through hole 120a of the first protective layer 120 disposed on the pad 141a and 142a of the first wiring electrode 140a1 is provided so as to be perpendicular to the upper surface of the pad 141a and 142a. A part of an upper surface of the pad 141a and 142a may be in contact with a lower surface of the first protective layer 120a, and the inner wall of the first through hole 120a may be provided so as to be perpendicular to a part of the upper surface of the pad 141a and 142a in contact with the lower surface of the first protective layer 120a described above. Here, vertical does not only mean that an angle formed by the inner wall of the first through hole 120a and a part of the upper surface of the pad 141a and 142a described above is 90° (degree), and a slope angle in a range of 85° (degree) to 90° (degree) should be considered vertical considering the process error, etc. Through this, a problem of cracks occurring at an interface between the first bonding part 151 and the pad 141a and 142a can be prevented.

Referring to FIG. 1c, widths of the first through hole 120a and the second through hole 120b of the first protective layer 120 are formed to be same. Through this, a same current intensity can be applied during a plating process, so that a height difference between the first protruding portion 151b of the first bonding part 151 and the second protruding portion 152b of the second bonding part 152 can be reduced, and the semiconductor chip 320 and 330 can be mounted with high reliability without being tilted when the semiconductor chip 320 and 330 is mounted in a subsequent process.

In addition, for example, the first protruding portion 151b and the second protruding portion 152b can have different widths. As illustrated in FIG. 1c, the size and spacing of the second protruding portion 152b are larger than those of the first protruding portion 151b disposed in a region where the connection member 200 is disposed. Accordingly, it is possible to secure an allowable error of the positional alignment for improving the yield during mounting of the semiconductor chip 320 and 330, and to reduce an impedance by disposing the second protruding portion 152b in a large size. In addition, although not shown, a plurality of second through portions 152a connected to one second protruding portion 152b may be disposed while being spaced apart in the horizontal direction, in order to secure a certain degree of uniformity in a density of the first through hole 120a and the second through hole 120b during a plating process of the first bonding part 151 and the second bonding part 152, and to improve an impedance of the second bonding part 152.

According to the embodiment illustrated in FIG. 1c, a width W1 of the first through portion 151a may satisfy a range of 12 μm to 20 μm. If the width W1 of the first through portion 151a is smaller than 12 μm, an allowable current of a signal transmitted through the first through portion 151a may decrease. In addition, if the width W1 of the first through portion 151a is smaller than 12 μm, an impedance of the first through portion 151a may increase, and as an contact area with the pad 141a of the first wiring electrode 140a1 decreases, a mechanical reliability problem may occur in which the first bonding part 151 is peeled off from the pad 141 of the first wiring electrode 140a1. In addition, if the width W1 of the first through portion 151a of the first bonding part 150 is greater than 20 μm, it may be difficult to dispose all of the plurality of first through portions 151a that vertically overlap the connection member 200 within a limited space. That is, if the width W1 of the first through portion 151a is greater than 20 μm, it may be difficult to adjust a pitch between the plurality of first bonding parts 151 to 40 μm or less, and thus the circuit integration may decrease.

Meanwhile, a width W2 of the second through portion 152a may correspond to the width W1 of the first through portion 151a. For example, the width W1 of the first through portion 151a may be equal to the width W2 of the second through portion 152a.

Each of the first through portion 151a and the second through portion 152a may have a maximum width and a minimum width. The maximum width may mean a width of a region having a greatest width in an entire region in the thickness direction of each of the first through portion 151a and the second through portion 152a. In addition, the minimum width may mean a width of a region having a smallest width in the entire area in the thickness direction of each of the first through portion 151a and the second through portion 152a. In addition, each maximum width may be implemented to be 105% or less of the minimum width. Hereinafter, it is described that a maximum width is a width of an upper surface of each through portion, and a minimum width is a width of a lower surface of each through portion. However, the embodiment is not limited thereto, and each of the through portions may have the maximum width and the minimum width in another region between the upper surface and the lower surface.

The first through portion 151a may include an upper surface and a lower surface. The upper surface and the lower surface of the first through portion 151a may have corresponding or identical widths. For example, the width of the upper surface of the first through portion 151a may correspond or be identical to the width of the lower surface of the first through portion 151a. For example, the width of the upper surface of the first through portion 151a may be implemented to be 105% or less of the width of the lower surface of the first through portion 151a. Similarly, the width of the upper surface of the second through portion 152a may be implemented to be 105% or less of the width of the lower surface of the second through portion 152a.

In the embodiment, the first through portion 151a and the second through portion 152a of the first bonding part 151 and the second bonding part 152 are disposed in a first through hole 120a and a second through hole 120b of the first protective layer 120 formed using a dry film pattern. Therefore, in accordance with a shape of the dry film pattern, a slope of the inner wall of the first through portion 151a and/or the second through portion 152a can be close to vertical as described above. That is, the width of the first through portion 151a can have a slope of the inner wall close to vertical while having a width of 20 um or less, and a slope of the inner wall of the second through portion 151b can also be close to vertical.

A width W3 of the first protruding portion 151b can satisfy a range of 29 μm to 34 um. If the width W3 of the first protruding portion 151b is less than 29 um, the alignment error of the position of the semiconductor chip 320 and 330 may be exceeded when the semiconductor chip 320 and 330 are mounted, and thus the semiconductor chip 320 and 330 may not be stably bonded onto the first protruding portion 151b. For example, if the width W3 of the first protruding portion 151b is less than 29 um, the semiconductor chip 320 and 330 may not be stably mounted on the first protruding portion 151b, and thus a problem of peeling off from the first protruding portion 151b may occur. In addition, if the width W3 of the first protruding portion 151b exceeds 34 um, it may be difficult to implement a pitch of 40 um or less between a plurality of first bonding parts 151. Due to this, a number of first protruding portions 151b may not be secured, and smooth electrical connection between the semiconductor chip 320 and 330 and the connection member 200 may be difficult.

Accordingly, the first protruding portion 151b may be provided with a predetermined width W4 along a circumferential direction of the first through portion 151a on the first through portion 151a. That is, the first protruding portion 151b may be provided with a width W4 in a range of 5 um to 10 um along the circumferential direction of the first through portion 151a on the first through portion 151a. If the predetermined width W4 of the first protruding portion 151b is less than 5 um, it may be difficult to secure the alignment of the position when patterning to place the first bonding part 151 on the first through hole 120a of the first protective layer 120. In addition, if the width W4 of the first through portion 151a exceeds 10 um, it may be difficult to implement the pitch between the plurality of first bonding parts 151 to 40 um or less as described above. Due to this, it may be difficult to secure the number of the first protruding portions 151b, and smooth electrical connection between the semiconductor chip 320 and 330 and the connection member 200 may be difficult.

A spacing W5 between the protruding portions of two adjacent first bonding parts among the plurality of first bonding parts 151 of the embodiment may be 5 um to 11 um. If the spacing W5 between the protruding portions of two adjacent first bonding parts is less than 5 um, a problem may occur in which the adjacent first bonding parts are electrically short-circuited due to a process error in a process of forming the first bonding part 151. In addition, if the spacing W5 between the protruding portions of two adjacent first bonding parts exceeds 11 um, it may be difficult to implement the pitch between the plurality of first bonding parts 151 to be 40 um or less. Due to this, it may be difficult to secure the number of first protruding portions 151b, and smooth electrical connection between the semiconductor chip 320 and 330 and the connection member 200 may be difficult.

Accordingly, a horizontal distance W6 between centers of the first through portions 151a of two adjacent first bonding parts 151 among the plurality of first bonding parts 151 of the embodiment may be 40 μm or less. At this time, the horizontal distance W6 may mean a pitch between the plurality of first bonding parts 151 as described above, and may correspond to W1+W4+W5. The embodiment can make a mutual communication between the semiconductor chips 320 and 330 smoother by disposing a large number of the plurality of first bonding parts 151 in a limited space. Accordingly, electronic products such as servers to which the semiconductor package is applied can process a large amount of data, thereby achieving key technological interconnectivity with the electronic products described above.

In addition, according to the embodiment illustrated in FIG. 1e, the first via electrode 140b1 includes a first-first via electrode 141b and a first-second via electrode 142b. The first-first via electrode 141b has a smaller width and a shorter vertical direction length than the first-second via electrode 142b. That is, since the upper surface of the connection member 200 is positioned higher than the second wiring electrode 140a2, the vertical direction length of the first-first via electrode 141b can be shortened, thereby shortening a signal transmission length and reducing the impedance for a length, thereby facilitating the electrical connection between the semiconductor device 320 and 330 and the connection member 200.

According to the embodiment, the first through hole 120a is formed using a dry film pattern. In addition, the second through hole 120b can be formed by applying a same method as the first through hole 120a. Furthermore, the embodiment can allow the first through hole 120a and the second through hole 120b to have a same width. Thereafter, the first and second bonding parts 151 and 152 are formed through a plating process. At this time, by controlling the width and/or density of the first through hole 120a and the second through hole 120b, a height deviation of the first and second bonding parts 151 and 152 can be reduced during the plating process. In addition, by forming the first and second through holes 120a and 120b using a dry film pattern, a pitch of the first and second bonding parts 151 and 152 can be finely implemented.

Referring to FIG. 1d, the first protective layer 120 includes a filler. The filler may be provided as an inorganic particle, and may be provided as a silica filler as an example. When the first and second through holes 120a and 120b are implemented by a conventional laser process and/or exposure process, the filler may be exposed into the first and second through holes 120a and 120b. Therefore, when the first and second bonding parts 151 and 152 are disposed through a subsequent plating process, the filler exposed into the first and second through holes 120a and 120b comes into contact with the first and second through portions 151a and 152b. The first and second bonding parts 151 and 152, including the first and second through portions 151a and 152b are disposed with a material capable of performing a function for electrical conductivity. For example, it can be provided with a metal material, and specifically, copper metal can be used. Therefore, the filler exposed into the first and second through holes 120a and 120b and the first and second through portions 151a and 152b may not have good mutual adhesion, and may have an effect of locally reducing the width of the first and second through portions 151a and 152b. In addition, problems such as peeling or cracking due to a difference in coefficient of thermal expansion (Co-efficient of Thermal Expansion rate) may occur.

Therefore, according to a present embodiment, a dry film pattern is disposed on the pads 141a and 142a of the first wiring electrode 140a1 to correspond to a pitch W6 of a plurality of first bonding parts 151 and a width of the first through portion 151a, and the first protective layer 120 is disposed to cover the dry film pattern on the first insulating layer 110b2. Thereafter, the first protective layer 120 is etched using a chemical liquid and/or plasma to reduce the thickness of the first protective layer 120, thereby exposing the dry film pattern. Thereafter, the first and second through holes 120a and 120b are formed by separating the dry film pattern.

In a case of implementing the first and second through holes 120a and 120b using the dry film pattern according to the present embodiment, since the dry film pattern is preferentially disposed, the filler of the first protective layer 120 does not penetrate into the dry film pattern. Accordingly, the filler of the first protective layer 120 is not exposed into the first and second through holes 120a and 120b, and thus, contact between the filler and the first and second through portions 151a and 152b can be prevented, so that the electrical and/or mechanical reliability can be significantly improved. In addition, since the filler of the first protective layer 120 is evenly distributed, a coefficient of thermal expansion of the first protective layer 120 can also be evenly distributed. That is, since some regions of the first and second protruding portions 151a and 152a vertically overlap the filler of the first protective layer 120, and the filler of the first protective layer 120 vertically overlaps the partial regions of the first and second protruding portions 151a and 152a does not come into contact with the first and second through portions 151a and 152b, the occurrence of peeling and cracking between the first and second protruding portions 151a and 152a and the first protective layer 120 may be suppressed from contraction and expansion caused by the heat cycle of the first protective layer 120, and electrical and/or mechanical reliability may be greatly improved as described above. In addition, in order to further improve the above-described effect, the filler may include fillers having various different diameters, and some fillers may have a diameter smaller than a predetermined width W4 of the first protruding portion 151b disposed along a circumferential direction of the first through portion 151a on the first through portion 151a.

In addition, in a process of etching and thinning the first protective layer 120, a roughness of a surface of the first protective layer 120 may increase. Therefore, in a subsequent process in which the first and second bonding parts 151 and 152 are disposed, a contact area may increase as the first and second protruding portions 151b and 152b come into contact with the surface of the first protective layer 120 described above, thereby improving the bonding strength. Accordingly, peeling or cracking of the first and second bonding parts 151 and 152 can be prevented due to stress caused by contraction and/or expansion of the first protective layer 120 by the heat cycle.

In addition, a surface roughness of the first protective layer 120 and a surface roughness of the first and second through holes 120a and 120b may be different from each other. Specifically, an inner surface of the first protective layer 120 forming the first and second through holes 120a and 120b has a same roughness as a side surface roughness of the dry film pattern by the above-described process. During a subsequent process, the surface roughness of the first protective layer 120 increases as the first protective layer 120 is etched by and/or plasma, etc., but no change in roughness occurs on the inner surface of the first protective layer 120 forming the first and second through holes 120a and 120b. Accordingly, the surface roughness of the first protective layer 120 is different from the roughness of the first and second through holes 120a and 120b. Therefore, widths of the first and second through portions 151a and 152a can be provided uniformly while improving the adhesive strength between the first and second protruding portions 151b and 152b and the first protective layer 120, and electrical adverse effects such as signal loss can be improved. Here, the roughness of the first and second through holes 120a and 120b and the roughness of the inner surface of the first protective layer 120 refer to each other.

At this time, referring to FIG. 2b, in the conventional technology, a through hole is formed in the protective layer 20 through an exposure and development process, or a through hole is formed in the protective layer 20 through a laser process.

Referring to (a) of FIG. 2b, in a first conventional technology, a through hole was formed by exposing and developing the protective layer 12. However, due to a limitation of a resolution of the exposure process, the width W6 of the through hole passing through the first protective layer 12 exceeded 20 um, and further exceeded 35 um. Therefore, when forming a through hole in the protective layer 12 using the exposure and development process, it is difficult to refine the width and spacing of the bonding part 20, and further, it is difficult to refine the pitch between a plurality of bonding parts disposed adjacent to each other.

In addition, referring to (b) of FIG. 2b, in a second conventional technology, a through hole passing through the protective layer 12 is formed by a laser process and accordingly, the width W1 of the through hole is set to 20 um or less. However, in the second conventional technology, a through hole is provided in the protective layer 12 through laser processing and/or an exposure process, and a through portion 21 of a bonding part 20 may be disposed in the through hole. Accordingly, since the through portion 21 in the second conventional technology includes a bottleneck portion (or curved portion) having a difference in width in the thickness direction, the bonding force between the through portion 21 and the pad 40 at the bottleneck portion may be reduced. In addition, cracks may occur in a lower region of the through portion 21 due to various factors (e.g., thermal stress). Therefore, according to the second conventional technology illustrated in (b) of FIG. 2b, the through portion 21 may include a first metal layer 21-1 and a second metal layer 21-2 disposed on the first metal layer 21-1. At this time, the pad 40 may include a concave portion 40C provided at an upper surface in order to disposed the second metal layer 21-2, and the concave portion may mean a crevice. That is, as the contact area between the bonding part 20 and the pad 40 at the bottleneck portion decreases, the bonding force decreases, and to compensate for this, the concave portion 40C may be filled with the first metal layer 21-1 of the through portion 21. At this time, since the through portion 21 has a bottleneck portion, the through portion 21 must have a plurality of metal materials including different metal materials, and thus the manufacturing process may be complicated or the manufacturing cost may increase.

In contrast, the embodiment can allow the first through portion 151a and the second through portion 152a to have a width of 20 um or less, and the upper surface and the lower surface of each of the first through portion 151a and the second through portion 152a to have widths corresponding to each other. Therefore, the embodiment can maintain the bonding strength of the first through portion 151a and the second through portion 152a even if a process of forming the concave portion 40C and a process of forming the first metal layer and the second metal layer are omitted, and the manufacturing cost can be reduced accordingly. However, the embodiment is not limited thereto.

Referring to FIG. 3, in order to further improve the bonding strength of the first through portion 151a and the second through portion 152a, a concave portion 40C may be implemented in the pads 141a and 142a, and each of the first through portion 151a and the second through portion 152a may be implemented to include a first metal layer 151a1 and 152a1 filling the concave portion 40C. In addition, each of the first through portion 151a and the second through portion 152a may be implemented to include a second metal layer 151a2 and 152a2 disposed on the first metal layer 151a1 and 152a1.

For example, the second metal layer 151a2 and 152a2 may be a solid metal, and may specifically include a first metal layer 151a1 and 152a1 including nickel, and a second metal layer 151a2 and 152a2 including a metal material other than nickel. In a process of disposing the first and second bonding parts 151 and 152 on the pad 141a and 142a of the first wiring electrode 140a1, oxidation may occur if the upper surface of the pad 141a and 142a of the first wiring electrode 140a1 is partially exposed from the first protective layer 120. Due to this, the bonding strength between the pad 141a and 142a of the first wiring electrode 140a1 and the first and second bonding parts 151 and 152 may be reduced, causing cracks or peeling, or electrical characteristics may be reduced due to a surface of the oxidized pad 141a and 142a. In addition, when the width of the first through portion 151a and the second through portion 152a is 30 um or less, it is possible to prevent the occurrence of a problem in which peeling occurs between the pad 141a and 142a of the first wiring electrode 140a1 and the first and second bonding parts 151 and 152 due to thermal stress such as contraction and/or expansion of the first protective layer 120.

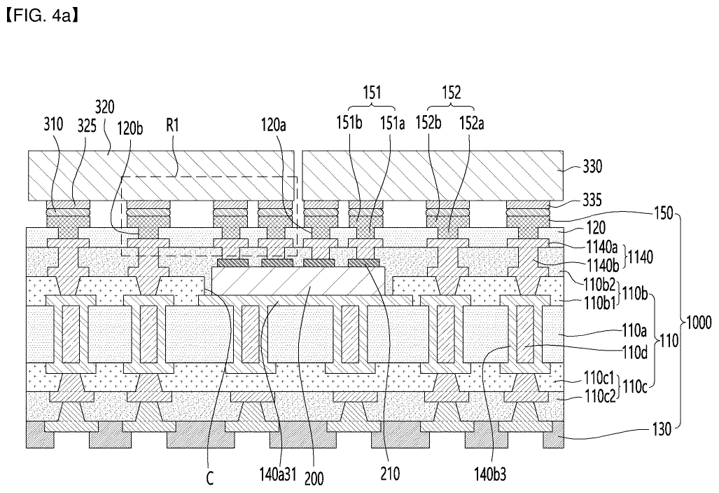

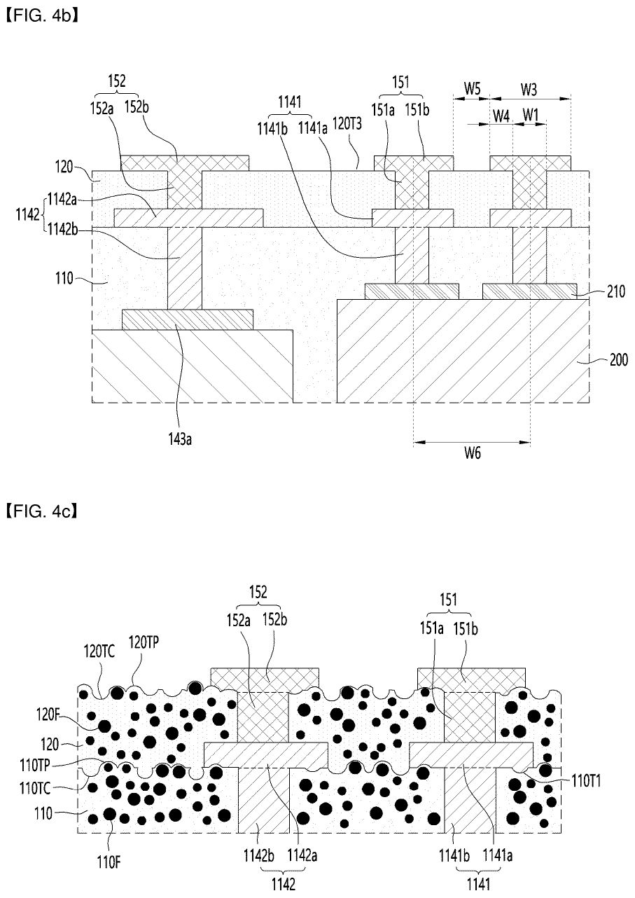

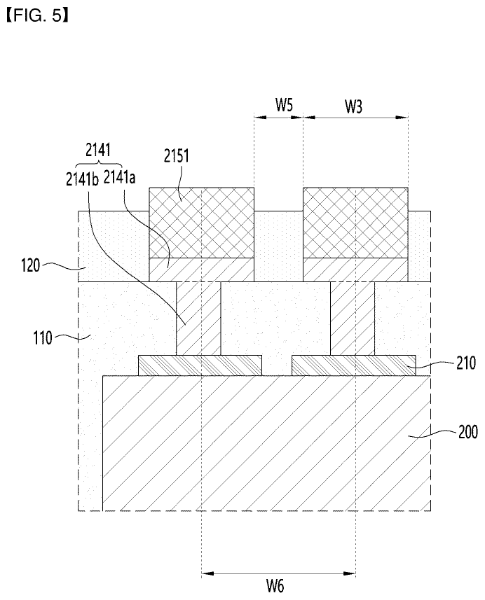

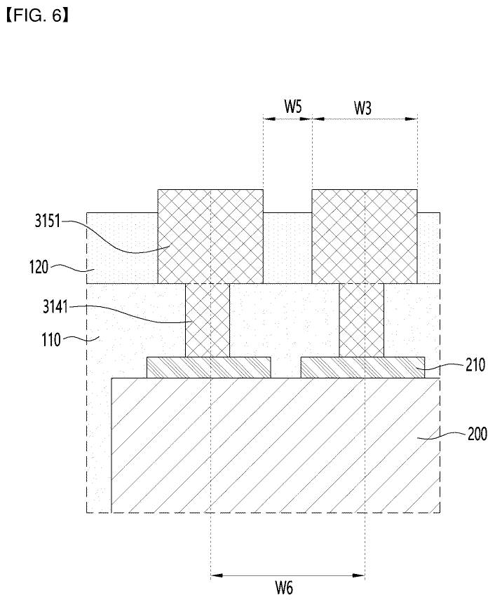

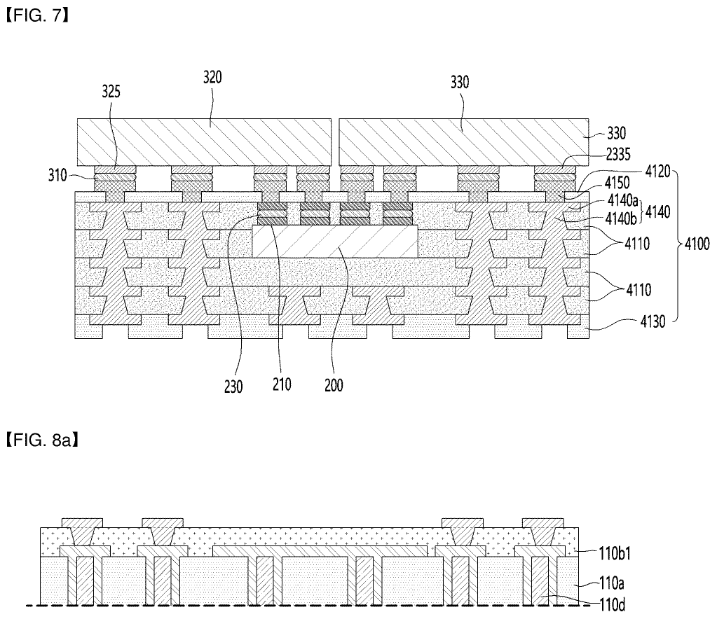

FIG. 4a is a cross-sectional view showing a semiconductor package according to the second embodiment, FIG. 4b is an enlarged view of a region R1 of FIG. 4a, and FIG. 4c is a cross-sectional view for explaining the surface roughness and structure of the first insulating layer 110b2 according to the second embodiment.

Hereinafter, the semiconductor package according to a second embodiment will be described with reference to FIGS. 4a to 4c. In the semiconductor package of the second embodiment, components that are substantially the same as those of the semiconductor package of the first embodiment are given the same reference numerals.

Referring to FIGS. 4a to 4c, the circuit board 1000 according to the second embodiment has a difference in a shape of a first via electrode 1140b compared to the circuit board 100 according to the first embodiment. The first via electrode 140b according to FIG. 1a has a sloped side surface structure whose width gradually narrows from the upper surface to the lower surface of the circuit board 100, but a side surface of the first via electrode 1140b of the circuit board 1000 according to a second embodiment has a vertical side surface structure. That is, slope angles of the first and second through portions 151a and 152a and a slope angle of the first via electrode 1140b are disposed to be the same. Specifically, the first via electrode 1140b according to the present embodiment, like the first and second bonding parts 151 and 152, includes a first-first via electrode 1141b vertically overlapping the connection member 200 and a first-second via electrode 1142b. As described above, a pitch of the pad 210 of the connection member 200 has a finer pitch than the pitch of the pad 143a of the second wiring electrode 140a2 for electrical connection between semiconductor devices 320 and 330. Accordingly, in a process for disposing the pad 1141a and 1142a of the first wiring electrode, it is difficult to dispose the pitch of the pad 1141a and 1142a finely using a processing by a conventional laser process. In addition, when the first insulating layer 110b2 is provided as an insulating layer including an inorganic filler such as ABF and a through hole is formed in the first insulating layer 110b2 through a laser process, the inorganic filler included in the first insulating layer 110b2 is exposed into the through hole, and thus side surfaces of the first via electrode 1141b and 1142b may have a concave portion corresponding to the exposed inorganic filler. Therefore, the bonding strength between the first via electrode 1141b and 1142b and the first insulating layer 110b2 is reduced, and there are electrical adverse effects such as signal loss, as well as problems such as difficulty in finely disposing the pitch of the pad 1141a and 1142a. Therefore, according to the second embodiment, the above-described problem can be solved by disposing the slope angle of the first via electrode 1141b and 1142b to have the same slope angle as the side surface of the first and second through portions 151a and 152a.

According to this embodiment, a dry film pattern is disposed on the pad 143a of the second wiring electrode 140a2 and the pad 210 of the connection member 200 to correspond to the pitch of the plurality of pads 1141a and 1142a of the first wiring electrode and the first via electrode 1141b and 1142b. Thereafter, a first insulating layer 110b2 is disposed to cover the dry film pattern. Thereafter, the first insulating layer 110b2 is etched using a chemical liquid and/or plasma to reduce the thickness of the first insulating layer 110b2, thereby exposing the dry film pattern. Thereafter, a through hole in which a first via electrode 1141b and 1142b is disposed is formed in the first insulating layer 110b2 by separating the dry film pattern, and thereafter, the first via electrode 1141b and 1142b and the pad 1141a and 1142a are disposed at a desired pitch.

Referring to FIG. 4b, a width of the first-first via electrode 1141b may correspond to the width W1 of the first through portion 151a of the first bonding part 151. In addition, the width of the first-first via electrode 1141b in the horizontal direction may satisfy a range of 12 μm to 20 μm. If the width of the first-first via electrode 1141b is smaller than 12 μm, an allowable current of a signal transmitted through the first-first via electrode 1141b may decrease or the impedance may increase. In addition, if the width W1 of the first-first via electrode 1141b is larger than 20 μm, it may be difficult to refine the pitch of the pad 1141a. In addition, widths of the first-first via electrode 1141b and the first-second via electrode 1142b may be the same. That is, the pitch of the pads 1141a and 1142a can be more easily refined. In addition, although not shown, by providing a plurality of first-second via electrodes 1142b connected to one pad 1142a so as to be spaced apart in a horizontal direction, the impedance can be improved.

A width of the pad 1141a can satisfy a range of 29 um to 34 um. If the width of the pad 1141a is less than 29 um, a contact area of the first bonding part 151 with the first through portion 151a decreases, and thus the adhesion strength may be deteriorated. Therefore, peeling between the first bonding part 151 and the pad 1141a may occur. In addition, at least a part of the first-first via electrode 1141b may not overlap with the pad 1141a in the vertical direction due to process deviation in the process of forming the pad 1141a, which may cause electrical reliability and/or mechanical reliability problems. In addition, if the width of the pad 1141a exceeds 34 μm, the effect of improving the positional alignment with the first bonding part 151 and more easily adjusting the pitch of the first bonding part 151 to the target value may be insufficient.

In addition, referring to FIG. 4b, a spacing between the plurality of adjacent pads 1141a and 1142a may be 5 um to 11 um. Accordingly, a horizontal distance W6 between centers of the plurality of adjacent pads 1141a and 1142a may be 40 um or less. In FIG. 4b, the horizontal distance W6 between the centers of pads 1141a is defined, but is not limited thereto, and may be understood as the horizontal distance between centers of a pad 1142a and a pad 1141a. According to FIG. 4b, the first-first via electrode 1141a and the first through portion 151a are mutually aligned, and the first-second via electrode 1142a and the second through portion 152a are mutually aligned. This prevents voltage drop. However, there may be alignment errors of less than 10 μm between each centerline due to process error.

Referring to FIG. 4c, a roughness may be formed on the upper surface of the first insulating layer 110b2. As with the first protective layer 120, when the first insulating layer 110b2 is etched and thinned using a chemical solution and/or plasma, roughness may be formed on a surface of the first insulating layer 110b2. Through this, the adhesive strength between the first protective layer 120 and the first insulating layer 110b2 may be improved. In addition, although not shown, a concave portion may be formed on the upper surface of the first insulating layer 110b2 due to the roughness formed on the upper surface of the first insulating layer 110b2, and the filler of the first protective layer 120 may fill the concave portion formed on the upper surface of the first insulating layer 110b2. Therefore, the adhesive strength between the first protective layer 120 and the first insulating layer 110b2 may be further improved. In addition, the filler of the first protective layer 120 and the filler of the first insulating layer 110b2 may be provided with the same material and/or the same diameter, but are not limited thereto.

FIG. 5a is an enlarged view of a region R1 of the semiconductor package of FIG. 4a according to a third embodiment.

Referring to FIG. 5a, the semiconductor package according to a third embodiment may be different from the semiconductor package of the second embodiment in a structure of a bonding part. For convenience of explanation, a following description will be based on the first bonding part that is vertically overlapped with the connection member 200.

A first electrode part 2141 includes a first via electrode 2141b and a first wiring electrode 2141a disposed on the connection member 200. In addition, a first bonding part 2151 is disposed on the first electrode part 2141.

The first bonding part 2151 includes a first through portion 2151a passing through the first protective layer 120 and a first protruding portion 2151b protruding on the first through portion 2151a.

At this time, the first through portion and the first protruding portion in the previous embodiment are provided with different widths.

In contrast, according to the third embodiment, the first through portion 2151a may have the same width as the first protruding portion 2151b. In addition, each of the first through portion 2151a and the first protruding portion 2151b may have the same width as the first wiring electrode 2141a of the first electrode part 2141.

The third embodiment can increase a volume of the first bonding part 2151 without affecting a pitch of the first bonding part 2151, thereby allowing the semiconductor device to be more stably disposed on the first bonding part 2151. Furthermore, the embodiment can improve the rigidity of the semiconductor package by increasing the volume of the first bonding part 2151, thereby preventing the semiconductor device from being greatly bent in a specific direction.

FIG. 5b is an enlarged view of a region R1 of the semiconductor package of FIG. 4a according to the fourth embodiment.

Referring to FIG. 5b, a first through portion 3141 is provided on the connection member 200. The first through portion 3141 may not have a change in width from an upper surface to a lower surface, and may pass through the first insulating layer 110b2.

A first protruding portion 3151 is disposed on the first through portion 3141. The first protruding portion 3151 may not have a change in width from the upper surface to the lower surface, and may pass through the first protective layer 120. That is, after the first protruding portion 3151 and the first through portion 3141 are disposed integrally, the first protective layer 120 is etched using a chemical solution and/or plasma to reduce the thickness of the first protective layer 120, thereby exposing the first protruding portion 3151. Accordingly, since a pitch of the first protruding portion 3151 can be implemented finer, the mutual communication between the semiconductor chip 320 and 330 and the circuit board 100 can become smoother.

FIG. 6 is a view showing a semiconductor package according to a fifth embodiment.

Referring to FIG. 6, the semiconductor package according to the fifth embodiment includes a circuit board manufactured by an ETS (Embedded Trace Substrate) method, and according to the above-described description, a circuit board according to a fifth embodiment can be classified as a coreless substrate.

Referring to FIG. 6, the semiconductor package includes an insulating layer 4110, a first protective layer 4120, a second protective layer 4130, an electrode part 4140, and a bonding part 4150. A connection member 200 is embedded in the insulating layer 4110. In addition, a contacting member 220 can be disposed between the connection member 200 and the electrode part 4140. Accordingly, the first protective layer 4120 of FIG. 6 is laminated while disposing a dry film pattern on a wiring electrode 4140a of an uppermost electrode part 4140 embedded in the insulating layer 4110, and accordingly, a through hole corresponding to the dry film pattern is provided in the first protective layer 4120. That is, in the fifth embodiment, in a process of manufacturing a circuit board using the ETS method, a process of disposing a dry film pattern corresponding to a pitch that the bonding part 4150 should have can be performed before laminating the first protective layer 4120. For example, the fifth embodiment can be manufactured by applying a process of forming a through hole in the first protective layer using the dry film pattern and the process of forming the bonding part described in the first embodiment.

The embodiment includes a protective layer and a bonding part passing through a partial region of the protective layer from an upper surface of the protective layer. At this time, the protective layer has a through hole corresponding to the bonding part. The through hole of the protective layer is formed through a dry film pattern. That is, the through hole is formed corresponding to a width and a pitch that the bonding part provided in the semiconductor package should have. That is, the embodiment forms a dry film pattern in advance considering the width and pitch of the bonding part. Through this, the embodiment can minimize a pitch between a plurality of bonding parts. For example, the embodiment can arrange a horizontal distance between centers of two adjacent bonding parts to be 40 μm or less. The embodiment can refine a pitch of the bonding part to 40 μm or less, and through this, the embodiment can improve the circuit integration degree and miniaturize the circuit board and the semiconductor package. In addition, the embodiment can reduce a distance between a plurality of bonding parts, and based on this, can minimize a transmission distance of a signal transmitted through a corresponding bump part. Therefore, the embodiment can minimize the signal transmission loss that increases according to the signal transmission distance, thereby improving the electrical characteristics of the circuit board and the semiconductor package. In addition, the embodiment can allow a semiconductor device to be disposed on the circuit board to operate stably, thereby enabling an electronic product such as a server to which the semiconductor package is applied to operate stably.

In addition, the embodiment has an electrode part disposed between the connection member and the bonding part. The electrode part passes through at least a portion of an insulating layer. At this time, the insulating layer has a through hole corresponding to the via electrode of the electrode part. In addition, the through hole of the insulating layer is provided through a dry film formed according to the width and pitch that the bonding part of the embodiment should have. Through this, the embodiment can form the electrode part corresponding to the width and pitch that the bonding part should have. Therefore, the embodiment can enable the bonding part to have a target width and pitch. In addition, the embodiment can form the electrode part at a position corresponding to the bonding part, thereby improving a positional alignment of the bonding part and the electrode part, and further improving the electrical characteristics of the bonding part and the electrode part.

In addition, the embodiment can minimize a height deviation between a plurality of bonding parts. That is, the embodiment includes a first bonding part that overlaps the connection member in the vertical direction and a second bonding part that does not overlap the connection member in the vertical direction. At this time, a size of a first through portion of the first bonding part is the same as a size of a second through portion of the second bonding part. That is, the embodiment can use a dry film pattern to make the through portions of the first bonding part and the second bonding part have the same size, thereby minimizing the height deviation between the first bonding part and the second bonding part that occurs due to a size difference.

Therefore, the embodiment can minimize the height deviation of the first bonding part and the second bonding part, thereby allowing the semiconductor element to be stably disposed on the first bonding part and the second bonding part. Therefore, the embodiment can improve the reliability of the first and second semiconductor devices. Furthermore, the embodiment can enable the operation of the first and second semiconductor elements to be performed smoothly, thereby enabling the operation of electronic products or servers to be performed smoothly.

In addition, the embodiment allows the first bonding part and the second bonding part to have the same height, thereby preventing problems such as impedance changes or signal transmission loss caused by changes in the thickness of the first bonding part and the second bonding part, and problems such as the semiconductor devices being disposed in a tilted state, and thereby further improving electrical reliability.

Furthermore, the embodiment can relatively lower a surface roughness of an interface between a through portion of each of the first bonding part and the second bonding part and the protective layer. Therefore, the embodiment can lower the surface roughness of the through portion, thereby minimizing the signal transmission loss that increases in proportion to the surface roughness. Therefore, the embodiment can further improve the operating characteristics of the semiconductor device.

Meanwhile, the upper surface of the protective layer of the embodiment can have a concave portion and a convex portion that increase an surface area of an upper surface of the protective layer by a process of thinning the thickness. The concave and convex portions can improve the reliability of the circuit board from heat cycles such as expansion and contraction of the circuit board due to heat generated during an operation of the semiconductor chip or applied from an outside. For example, since the convex and concave portions have different thicknesses, a volume deformed during thermal expansion can be different. That is, a thickness of the concave portion can be thinner than that of the convex portion, and the overall thermal deformation of the semiconductor package can be suppressed due to the difference in a thermal expansion coefficient of the convex portion and a thermal expansion coefficient of the concave portion. Therefore, the embodiment can prevent the semiconductor device coupled to an upper portion of the semiconductor package from being electrically separated during thermal expansion, and thus improve product reliability.

With reference to the first to fifth embodiments, the via electrode positioned above the connection member 200 has a different width and/or slope direction from the via electrode positioned below the connection member 200. That is, the via electrode positioned above the connection member 200 has a more vertical side surface than the via electrode positioned below the connection member 200. That is, the via electrode having the vertical side surface is positioned above the connection member 200, and thus, the effect of improving the warpage of the circuit board 100 can be achieved. In addition, when the via electrode having the vertical side surface has a finer pattern than the via electrode having the inclined side surface, the stress applied to the via electrode can be alleviated, so as to improve the electrical connection reliability between the semiconductor chip 320 and 330 and the circuit board 100. Accordingly, the via electrode having the vertical side surface can be implemented to be positioned above the connection member 200.

In addition, although the above description describes forming a through hole using a dry film in the first protective layer 120 with a width of 20 μm or less and a pitch of two adjacent through holes of 40 μm or less, it is not limited thereto. For example, the embodiment may also form a through hole in the second protective layer 130 in a same manner as a process of forming a through hole in the first protective layer 120.

In addition, the first protective layer 120 is described as having a plurality of through holes and the plurality of through holes are provided with bonding parts 150, but it is not limited thereto.

For example, at least one of the through holes provided in the first protective layer 120 may not be provided with a bonding part. In addition, the through hole not provided with a bonding part may be filled with a molding member (not shown) for molding a semiconductor chip. Therefore, the embodiment can improve an adhesive strength between the circuit board and the molding member. In addition, the embodiment can control a density of the first protective layer in an edge region of the circuit board, or firmly bond the molding member and the circuit board, thereby preventing the circuit board from being bent in a specific direction, or firmly fixing the circuit board in a case where the circuit board is bent in a specific direction to improve rigidity.

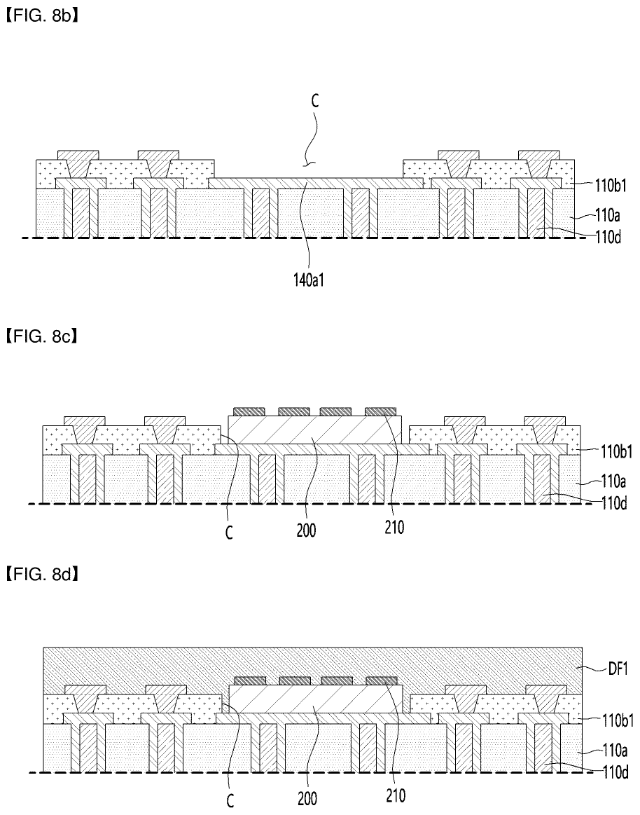

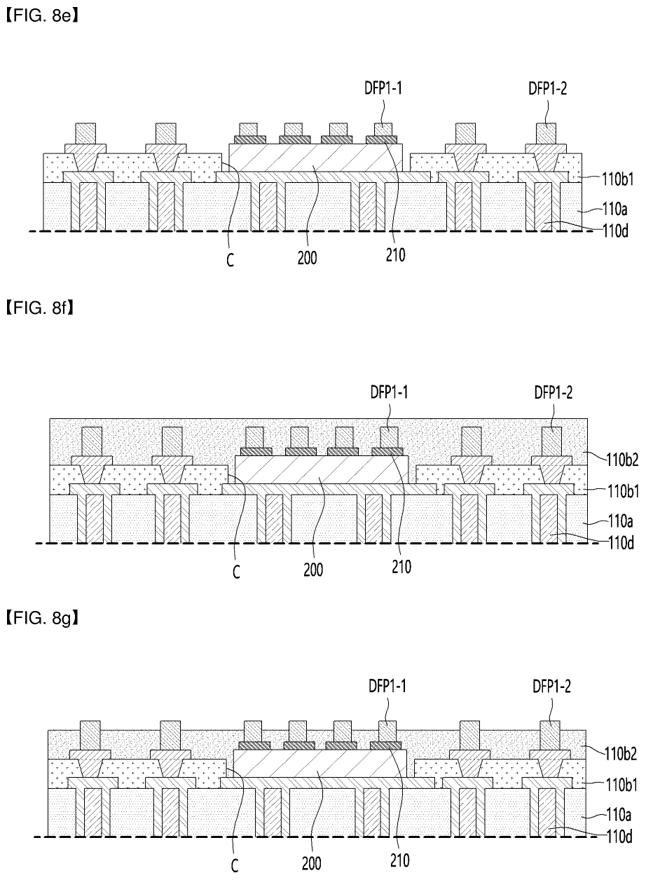

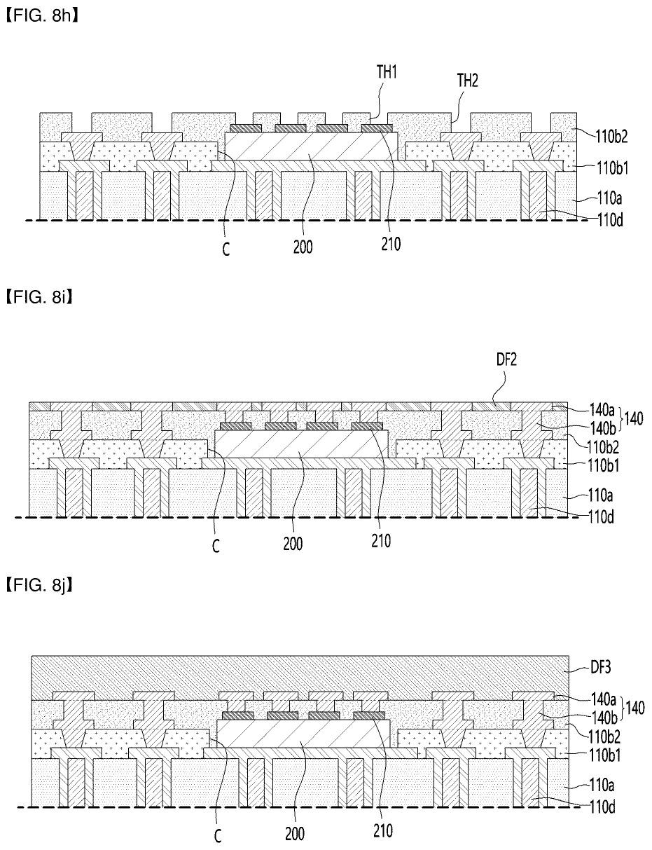

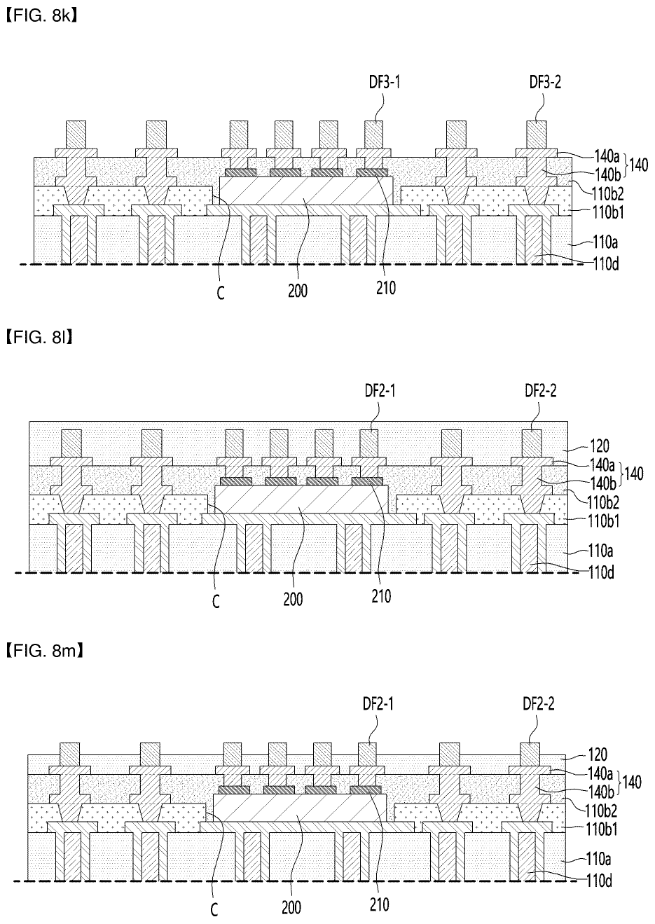

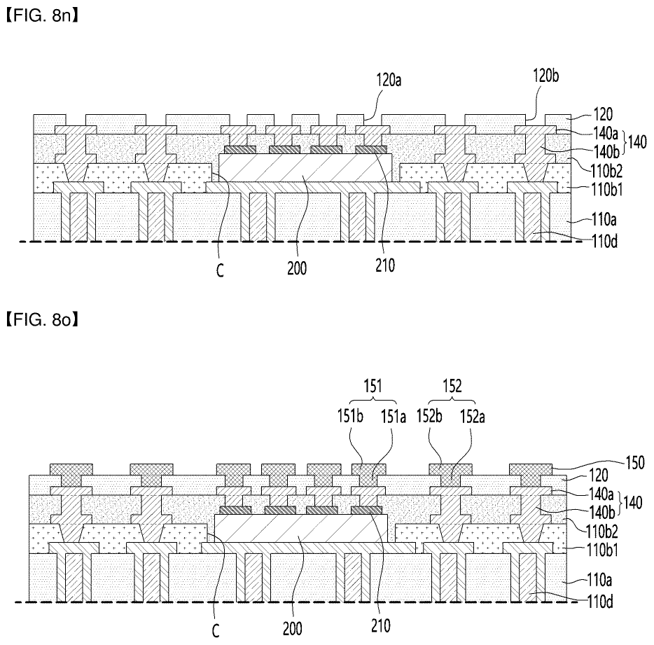

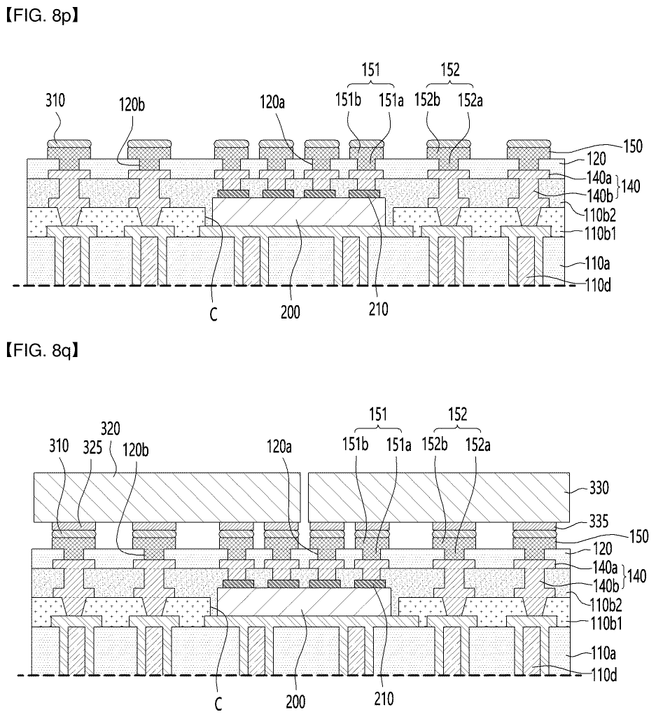

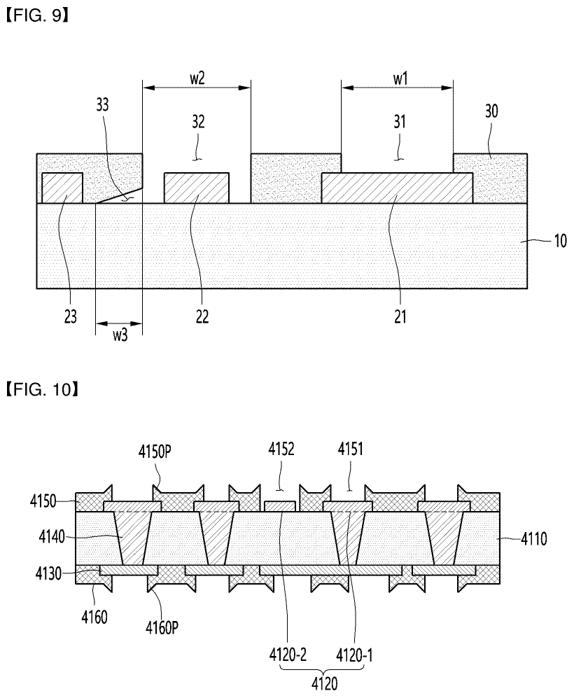

FIGS. 8a to 8q are cross-sectional views for describing a method of manufacturing the circuit board according to a second embodiment of FIG. 4A in order of processes.

Referring to FIG. 8a, the embodiment prepares a third insulating layer 110a. In addition, the embodiment can perform a process of forming an electrode part in the third insulating layer 110a. For example, the embodiment can perform a process of forming a wiring electrode on an upper surface and a lower surface of the third insulating layer 110a and a process of forming a via electrode and an insulating member 110d passing through the third insulating layer 110a.

Next, the embodiment performs a process of laminating a second insulating layer 110b1 on a third insulating layer 110a. In addition, the embodiment performs a process of forming a via electrode passing through the second insulating layer 110b1 and a wiring electrode on the second insulating layer 110b1.

Referring to FIG. 8b, the embodiment performs a process of forming a cavity (C) in the second insulating layer 110b1. At this time, a dummy electrode 141a31 is provided on the third insulating layer 110a, and the cavity (C) overlaps the dummy electrode 141a31 in a vertical direction.

Next, referring to FIG. 8c, the embodiment performs a process of applying an adhesive material on the dummy electrode 141a31, thereby attaching a connection member 200 to the cavity (C). At this time, the connection member 200 is provided with a pad 210, and the pad 210 is disposed so as to face upward.

Next, referring to FIG. 8d, the embodiment performs a process of laminating a first dry film DF1 on the second insulating layer 110b1 and the connection member 200.

Next, referring to FIG. 8e, the embodiment performs a process of exposing and developing the first dry film DF1 corresponding to a width and a pitch that the first bonding part 151 and the second bonding part 152 should have. Through this, a first dry film pattern DFP1-1 corresponding to a region where the first via electrode 141b of the first electrode part 141 is to be disposed is formed on the pad 210 of the connection member 200. In addition, a second dry film pattern DFP1-2 corresponding to a region area where the second via electrode 142b of the second electrode part 142 is to be disposed is formed on the wiring electrode.

Next, referring to FIG. 8f, the embodiment performs a process of laminating the first insulating layer 110b2. At this time, the first insulating layer 110b2 is disposed to fill the cavity (C) in which the connection member 200 is embedded. In addition, the first insulating layer 110b2 is disposed to have a height greater than that of the first dry film pattern DFP1-1 and the second dry film pattern DFP1-2.

Next, referring to FIG. 8g, the embodiment performs a process of thinning a thickness of the first insulating layer 110b2. Through this, an upper surface of the first insulating layer 110b2 is positioned lower than upper surfaces of the first dry film pattern DFP1-1 and the second dry film pattern DFP1-2. In addition, a filler provided in the second layer 110b2 of the second insulating layer 110b may escape or be exposed through the upper surface of the first insulating layer 110b2 through the process of thinning the thickness of the first insulating layer 110b2. Accordingly, an upper surface of the first insulating layer 110b2 may be provided with a concave portion and/or a convex portion corresponding to the filler provided in the first insulating layer 110b2. Furthermore, at least a part of the filler provided in the first insulating layer 110b2 may be exposed through an upper surface of the first insulating layer 110b2.

Next, referring to FIG. 8h, the embodiment performs a process of removing the first dry film pattern DFP1-1 and the second dry film pattern DFP1-2. Through this, a first through hole TH1 and a second through hole TH2 corresponding to a space where the first dry film pattern DFP1-1 and the second dry film pattern DFP1-2 are removed are formed in a second layer 110b2 of the second insulating layer 110b. In this case, the embodiment allow the first through hole TH1 and the second through hole TH2 to be formed using the first dry film pattern DFP1-1 and the second dry film pattern DFP1-2. Accordingly, the filler provided in the first insulating layer 110b2 may not escape through the first through hole TH1 and the second through hole TH2, and the filler provided in the second layer 110b2 of the second insulating layer 110b may not be exposed through the first through hole TH1 and the second through hole TH2. In addition, in the embodiment, by forming the first through hole TH1 and the second through hole TH2 using the first dry film pattern DFP1-1 and the second dry film pattern DFP1-2, an upper surface of the pad 210 of the connection member 200 may not have a concave portion.

Next, referring to FIG. 8i, the embodiment forms a second dry film DF2 on the first insulating layer 110b2. At this time, the second dry film DF2 has an opening in which a region where a wiring electrode is to be disposed is open. Next, the embodiment performs a plating process to fill the first through hole TH1 of the first insulating layer 110b2, the second through hole TH2, and the opening of the second dry film DF2. Accordingly, the embodiment can form an electrode part 1140 including a wiring electrode 1140a and a via electrode 1140b.

Next, referring to FIG. 8j, the embodiment performs a process of laminating a third dry film DF3 on the first insulating layer 110b2.

Next, referring to FIG. 8k, the embodiment performs a process of exposing and developing a third dry film DF3 corresponding to the width and pitch that the first bonding part 151 and the second bonding part 152 should have. Through this, a third dry film pattern DFP3-1 corresponding to the first bonding part 151 and a fourth dry film pattern DFP3-2 corresponding to the second bonding part 152 are formed on the wiring electrode 1140a.

Next, referring to FIG. 8l, the embodiment performs a process of laminating a first protective layer 120 on a first insulating layer 110b2. At this time, the first protective layer 120 is disposed with a height greater than that of the third dry film pattern DFP3-1 and the fourth dry film pattern DFP3-2.

Next, referring to FIG. 8m, the embodiment performs a process of thinning the thickness of the first protective layer 120. Through this, an upper surface of the first protective layer 120 is positioned lower than upper surfaces of the third dry film pattern DFP3-1 and the fourth dry film pattern DFP3-2. In addition, the filler provided in the first protective layer 120 may escape or be exposed to an outside through the process of thinning the thickness of the first protective layer 120. Accordingly, the upper surface of the first protective layer 120 may be provided with a concave portion and/or a convex portion corresponding to the filler provided in the first protective layer. Furthermore, at least a part of the filler provided in the first protective layer 120 may be exposed through the upper surface of the first protective layer 120.

Next, referring to FIG. 8n, the embodiment performs a process of removing the third dry film pattern DFP3-1 and the fourth dry film pattern DFP3-2. Through this, the first through hole 120a and the second through hole 120b are formed in the first protective layer 120. Therefore, in the embodiment, by forming the first through hole 120a and the second through hole 120b using the third dry film pattern DFP3-1 and the fourth dry film pattern DFP3-2, the filler provided in the first protective layer 120 may not escape through the first through hole 120a and the second through hole 120b, and the filler provided in the first protective layer 120 may not be exposed through the first through hole 120a and the second through hole 120b. In addition, in the embodiment, by forming the first through hole 120a and the second through hole 120b using the third dry film pattern DFP3-1 and the fourth dry film pattern DFP3-2, a concave portion may not be provided on the upper surface of the wiring electrode 140a.

Next, referring to FIG. 80, the embodiment performs a plating process for filling the first through hole 120a and the second through hole 120b, thereby forming the first bonding part 151 and the second bonding part 152.

Next, referring to FIG. 8p, the embodiment performs a process for disposing a connection part 310 on the first bonding part 151 and the second bonding part 152.

Meanwhile, he following describes a circuit board according to an additional embodiment and a semiconductor package including the same. The circuit board and the semiconductor package of the additional embodiment may be similar to the circuit board and the semiconductor package of the previous embodiment in that the circuit board and the semiconductor package include a protective layer and a through hole is formed in the protective layer. However, hereinafter, a convex portion is provided on a surface of the protective layer while forming a through hole in the protective layer using a dry film.

Before describing the embodiment, a structure of a protective layer according to a conventional technology compared to the embodiment is described.

FIG. 9 is a cross-sectional view showing a circuit board according to a comparative example.

Referring to FIG. 9, the circuit board of the comparative example includes an insulating layer 10, a circuit pattern layer, and a protective layer 30. The circuit pattern layer includes a first pad 21, a second pad 22, and a trace 23. The protective layer 30 includes a first through hole 31 that vertically overlaps the first pad 21. The first through hole 31 partially opens an upper surface of the first pad 21. A width W1 of the first through hole 31 exceeds at least 50 um depending on the exposure resolution (e.g., high resolution) of the protective layer 30. Specifically, the width W1 of the first through hole 31 exceeds at least 70 um depending on the exposure resolution (e.g., normal resolution) of the protective layer 30. Therefore, a width of the first pad 21 vertically overlapping the first through hole 31 exceeds 70 um, which is larger than the width W1 of the first through hole 31. For example, the width of the first pad 21 exceeds 90 um, which is greater than the width W1 of the first through hole 31. This is in consideration of a process deviation in a process of forming the first through hole 31.

As described above, a width of the first through hole 31 exceeds at least 50 um, or exceeds 70 um, and accordingly, a width of the first pad 21 exceeds 70 um or exceeds 90 um. Accordingly, the comparative example has a limit in reducing the gap between the plurality of first pads. That is, the comparative example has a limit in miniaturizing the width W1 of the first through hole 31, and further has a limit in miniaturizing a width of the first pad 21.

The protective layer 30 includes a second through hole 32 that vertically overlaps the second pad 22. The second through hole 32 opens an entire upper surface of the second pad 22. That is, the second through hole 32 is a through hole of a NSMD type. A width W2 of the second through hole 32 exceeds 50 um or 70 um depending on the exposure resolution of the protective layer 30. That is, the protective layer 30 has a limit in miniaturizing a width W2 of the second through hole 32.

Furthermore, the protective layer 30 performs an exposure and curing process to form the first through hole 31 and the second through hole 32. At this time, in a process of exposing and curing the protective layer 30, there is a problem that complete curing of a lower region of the protective layer 30 is not achieved. In addition, in a case where complete curing is not achieved, there is a problem that an undercut 33 is formed in a lower region of a the side wall of the second through hole 32 in a process of forming the second through hole 32.

At this time, a horizontal distance W3 of the undercut 33 of the comparative example exceeds 15 um or exceeds 20 um. The horizontal distance W3 of the undercut 33 means a horizontal distance from an innermost end to an outermost end in a lower region of a side wall of the second through hole 32.

At this time, the circuit pattern layer includes a trace 23 disposed adjacent to the second pad 22. In addition, in the comparative example, a horizontal distance W3 of the undercut 33 must be considered when disposing the trace 23. That is, in the comparative example, if the horizontal distance W3 of the undercut 33 is not considered, a side of the trace 23 may be exposed through the undercut 33. In this case, a solder ball disposed on the second pad 22 spreads to the undercut 33, and thus, a circuit short problem occurs due to contact with the trace 23. Therefore, in the comparative example, a spacing between the second pad 22 and the trace 23 is determined by considering a width W2 of the second through hole 32 and a horizontal distance W3 of the undercut 33. Therefore, in the comparative example, the spacing increases, and thus, there is a problem that the circuit integration is reduced.

In addition, as the performance of electric/electronic products has been improved recently, technologies for attaching a larger number of semiconductor devices to a limited-size substrate are being studied, and accordingly, the miniaturization of the circuit pattern is required. In the case of a semiconductor package using the circuit board of the comparative example, a limit of a minimum width of the through hole that can be formed in the protective layer 30 and a horizontal distance of the undercut must be considered, and thus, there is a limit to miniaturizing the circuit pattern.

Furthermore, functions processed in logic chips such as application processors (APs) have been increasing recently. This makes it difficult to implement all functions in one logic chip. Therefore, a space is required for mounting multiple logic chips on the circuit board. However, it is difficult to mount multiple logic chips with different functions in a limited space using the circuit board of the comparative example.

In addition, an upper surface of the protective layer 30 of the comparative example is formed substantially as a plane. Accordingly, in order to prevent diffusion of a connection part such as solder disposed in the through hole of the protective layer 30, a thickness of the protective layer 30 must be increased.

That is, the protective layer 30 of the comparative example does not include a barrier structure that prevents diffusion of solder. Accordingly, the comparative example has a problem that a solder short occurs due to diffusion of solder when a thickness of the protective layer 30 is reduced.

In addition, when increasing a thickness of the protective layer 30, the comparative example has a problem in that a design distance may be exceeded when filling an epoxy molding compound after chip mounting, and thus an unfilled region may occur.

The embodiment is intended to solve these problems, and provides a barrier structure capable of preventing the diffusion of solder on the upper surface of the protective layer. That is, the protective layer of the embodiment includes a convex portion that is provided adjacent to the through hole and surrounds an upper region of the through hole. In addition, the embodiment can improve the reliability of the solder disposed in the through hole by using the convex portion. In addition, the embodiment can significantly reduce a width of the through hole that can be formed in the protective layer compared to the comparative example. In addition, the embodiment can minimize a horizontal distance of a undercut formed at a side wall of the through hole of the protective layer or can eliminate the undercut. Furthermore, the embodiment can reduce a tolerance (SRR: Solder Resist Registration) between a center of the through hole of the protective layer and a center of the pad. In addition, the embodiment can improve the electrical and mechanical characteristics while improving the bonding strength with the molding layer.

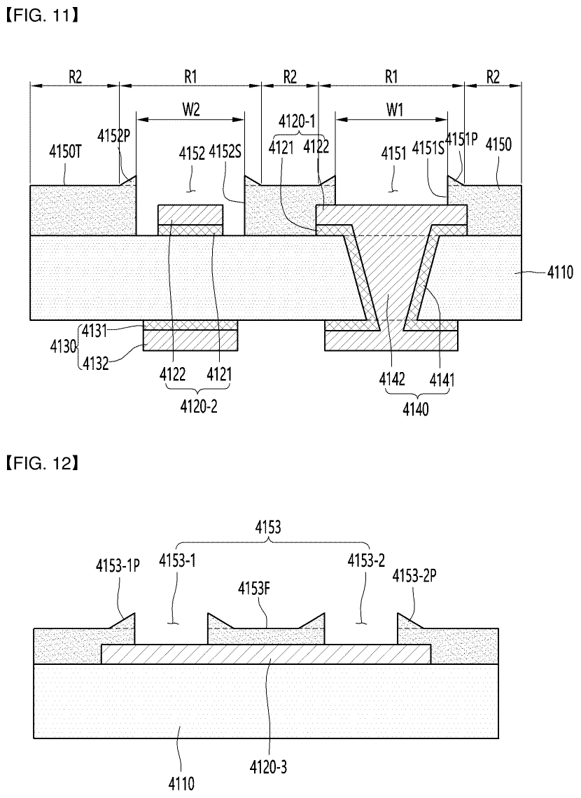

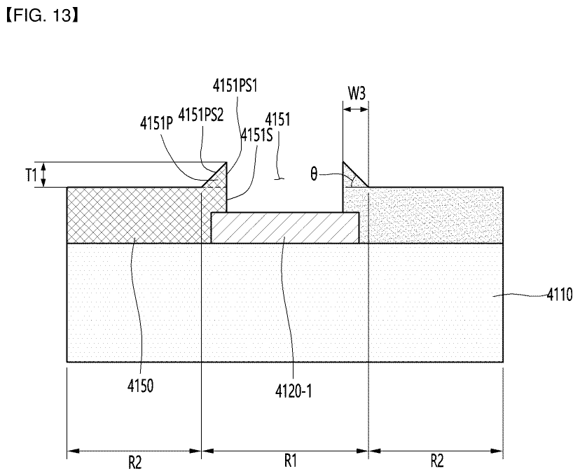

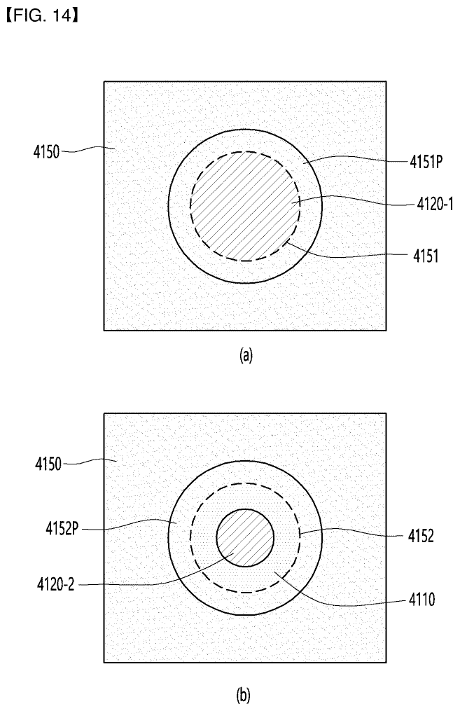

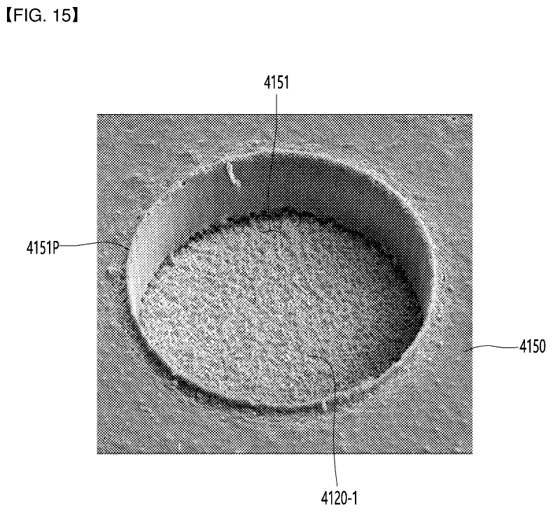

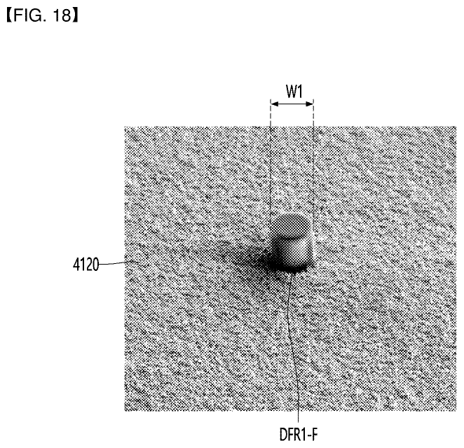

FIG. 10 is a cross-sectional view illustrating a circuit board according to a sixth embodiment, FIG. 11 is a cross-sectional view illustrating a first partial region of a circuit board of FIG. 10 in detail, FIG. 12 is a cross-sectional view illustrating a second partial region of the circuit board of FIG. 11 in detail, FIG. 13 is a cross-sectional view of a partial region of a circuit board for explaining a convex portion according to an embodiment, FIG. 14 is a plan view of a partial region of a circuit board for explaining a convex portion according to an embodiment, FIG. 15 is a scanning electron microscope image illustrating a partial region of a circuit board of FIGS. 13 and 14, FIG. 16 is a scanning electron microscope image illustrating an upper surface of a first protective layer of FIG. 12, FIG. 17 is a scanning electron microscope image illustrating an inner surface of a through hole of a first protective layer of FIG. 12, and FIG. 18 is a view illustrating a resist pattern used to form a through hole of a first protective layer according to an embodiment.

Hereinafter, a circuit board according to the sixth embodiment will be specifically described with reference to FIGS. 10 to 18.

A circuit board 4100 of a sixth embodiment includes an insulating layer 4110, an upper wiring electrode 4120, and a lower wiring electrode 4130. The upper wiring electrode 4120 may refer to an upper wiring electrode 140a1 positioned at an uppermost portion of the insulating layer in the previous embodiment. In addition, the lower wiring electrode 4130 may refer to a fifth wiring electrode 140a6 positioned at a lowermost portion of the insulating layer in the previous embodiment.

The upper wiring electrode 4120 includes a first pad 4120-1, a second pad 4120-2, and a third pad 4120-3. The first pad 4120-1, the second pad 4120-2, and the third pad 4120-3 of the upper wiring electrode 4120 may be distinguished by their widths. For example, the first pad 4120-1 may have a width greater than that of the second pad 4120-2 and a width smaller than that of the third pad 4120-3. For example, the second pad 4120-2 may have a width smaller than that of the first pad 4120-1 and the third pad 4120-3. For example, the third pad 4120-3 may have a width larger than that of the first pad 4120-1 and the second pad 4120-2.

The upper wiring electrode 4120 is required to be miniaturized, and thus, a spacing between the plurality of pads may be reduced. In addition, when the spacing between the plurality of pads is reduced due to the miniaturization implementation, the circuit integration may be improved, but a solder short may occur due to the diffusion of the solder in a process of disposing the solder. Accordingly, the embodiment includes a barrier structure capable of preventing diffusion of solder in the protective layer.

The upper wiring electrode 4120 and the lower wiring electrode 4130 may each have a multi-layer structure.

The upper wiring electrode 4120 may include a first metal layer 4121 and a second metal layer 4122. That is, each of the first pad 4120-1, the second pad 4120-2, and the third pad 4120-3 of the upper wiring electrode 4120 may include a first metal layer 4121 and a second metal layer 4122.

The first metal layer 4121 of the upper wiring electrode 4120 may protrude above an upper surface of the insulating layer 4110. The first metal layer 4121 of the upper wiring electrode 4120 may be an electroless metal layer. A thickness of the first metal layer 4121 of the upper wiring electrode 4120 can satisfy a range of 0.2 um to 3.0 um. Preferably, the thickness of the first metal layer 4121 of the upper wiring electrode 4120 can satisfy a range of 0.3 um to 2.8 um. More preferably, the thickness of the first metal layer 4121 of the upper wiring electrode 4120 can satisfy a range of 0.5 um to 2.5 um. If the thickness of the first metal layer 4121 of the upper wiring electrode 4120 is less than 0.2 um, the first metal layer 4121 of the upper wiring electrode 4120 may not function as a seed layer. If the thickness of the first metal layer 4121 of the upper wiring electrode 4120 is less than 0.2 um, it may be difficult to form a first metal layer 4121 with a uniform thickness on an upper surface of the insulating layer 4110. If the thickness of the first metal layer 4121 of the upper wiring electrode 4120 exceeds 3.0 um, a process time for forming the first metal layer 4121 of the upper wiring electrode 4120 may increase, and thus the yield may decrease. In addition, if the thickness of the first metal layer 4121 of the upper wiring electrode 4120 exceeds 3.0 um, an etching time of the first metal layer 4121 in a process of forming the upper wiring electrode 4120 may increase. In addition, if the thickness of the first metal layer 4121 of the upper wiring electrode 4120 exceeds 3.0 um, deformation of the second metal layer 4122 of the upper wiring electrode 4120 may occur when the first metal layer 4121 of the upper wiring electrode 4120 is etched. Here, deformation of the second metal layer 4122 of the upper wiring electrode 4120 may mean that a difference between a width of the upper surface and a width of the lower surface of the second metal layer 4122 increases as a side of the second metal layer 4122 is also etched when the first metal layer 4121 is etched. For example, deformation of the second metal layer 4122 of the upper wiring electrode 4120 may mean that a shape of a vertical cross-section of the second metal layer 4122 changes from a square to a trapezoidal shape. In addition, if the thickness of the first metal layer 4121 of the upper wiring electrode 4120 exceeds 3.0 um, the etching amount in the etching process of the first metal layer 4121 increases, and accordingly, a depth of a groove (e.g., undercut) formed at a side of the first metal layer 4121 and a side of the second metal layer 4122 may increase. For example, if the etching amount in the etching process of the first metal layer 4121 increases, the difference between the width of the first metal layer 4121 and the width of the second metal layer 4122 may increase. In addition, when the difference between the width of the first metal layer 4121 and the width of the second metal layer 4122 increases, electrical characteristics may deteriorate due to an increase in signal transmission loss. In addition, when the difference between the width of the first metal layer 4121 and the width of the second metal layer 4122 becomes large, dendrites may be formed by electromigration, thereby deteriorating the electrical characteristics and/or physical characteristics of the upper wiring electrode 4120. The second metal layer 4122 may be an electrolytically plated layer using the first metal layer 4121 as a seed layer. The second metal layer 4122 of the upper wiring electrode 4120 may be formed on the first metal layer 4121 with a certain thickness. The second metal layer 4122 of the upper wiring electrode 4120 may include the same metal as the first metal layer 4121 of the upper wiring electrode 4120, but is not limited thereto. For example, the first metal layer 4121 and the second metal layer 4122 of the upper wiring electrode 4120 may each include copper.

A thickness of the second metal layer 4122 of the upper wiring electrode 4120 may be greater than a thickness of the first metal layer 4121 of the upper wiring electrode 4120. The thickness of the second metal layer 4122 of the upper wiring electrode 4120 may satisfy a range of 3.5 um to 25 um. Preferably, the thickness of the second metal layer 4122 of the upper wiring electrode 4120 may satisfy a range of 4.0 um to 23 um. More preferably, the thickness of the second metal layer 4122 of the upper wiring electrode 4120 may satisfy a range of 4.5 um to 22 um. If the thickness of the second metal layer 4122 of the upper wiring electrode 4120 is less than 3.5 um, the second metal layer 4122 may also be etched during the etching process of the first metal layer 4121. If the thickness of the second metal layer 4122 of the upper wiring electrode 4120 is less than 3.5 um, an allowable current of a signal transmitted through the upper wiring electrode may decrease, and thus the electrical characteristics may deteriorate. If the thickness of the second metal layer 4122 of the upper wiring electrode 4120 exceeds 25 um, it may be difficult to miniaturize the upper wiring electrode 4120. For example, if the thickness of the second metal layer 4122 of the upper wiring electrode 4120 exceeds 25 um, the width and spacing of the patterns constituting the upper wiring electrode 4120 may not satisfy required conditions. Accordingly, the circuit integration may be reduced or a volume of the circuit board and the semiconductor package may be increased.

The lower wiring electrode 4130 may include a first metal layer 4131 and a second metal layer 4132 corresponding to the upper wiring electrode 4120.

The circuit board 4100 may include a via electrode 4140. The via electrode 4140 may pass through the insulating layer 4110. Preferably, the via electrode 4140 may pass through the insulating layer 4110 to electrically connect between the upper wiring electrode 4120 and the lower wiring electrode 4130. At this time, when the insulating layer 4110 has a multi-layer structure, the via electrode 4140 may be spaced apart in the vertical direction and electrically connect between adjacent wiring electrodes.

In addition, the via electrode 4140 includes a first metal layer 4141 and a second metal layer 4142 corresponding to the upper wiring electrode and the lower wiring electrode.

A first protective layer 4150 may be included on the insulating layer 4110. For example, the circuit board 4100 may include a second protective layer 4160 disposed under the insulating layer 4110.

The first protective layer 4150 includes at least one through hole. In addition, the second protective layer 4160 includes at least one through hole. At this time, although not shown in the drawing, a bonding part 150 as shown in FIGS. 1a to 1d may be provided in the through hole of the first protective layer 4150.

In addition, the first protective layer 4150 and the second protective layer 4160 may include convex portions 4150P and 4160P. The convex portions 4150P and 4160P may be provided on the surfaces of the first protective layer 4150 and the second protective layer 4160. In addition, the convex portion 4150P of the first protective layer 4150 may be provided to surround the through portion of the bonding part 150. That is, the convex portion 4150P of the first protective layer 4150 may be provided on the first protective layer 120 illustrated in FIGS. 1a to 1d, and through this, the bonding part 150 may include a portion surrounded by the convex portion 4150 of the first protective layer 4150.

That is, the insulating layer 4100 includes a side surface positioned between the upper surface and the lower surface. In addition, the first protective layer 4150 includes a lower surface facing the upper surface of the insulating layer 4100, an upper surface corresponding to the lower surface of the first protective layer 4150, and a side surface between the upper surface and the lower surface of the first protective layer 4150. At this time, the side surface of the first protective layer 4150 includes an inner surface surrounding the through portion of the bonding part 150 and an outer surface adjacent to the side surface of the insulating layer 4100. In addition, a length of the vertical direction of the inner surface of the first protective layer 4150 is different from a length of the vertical direction of the outer surface of the first protective layer 4150. For example, a length of the vertical direction of the inner surface of the first protective layer 4150 is greater than a length of the vertical direction of the outer surface. Through this, the embodiment can allow the bonding part 150 be more stably supported by the first protective layer 4150, thereby improving the physical reliability and/or electrical reliability of the bonding part 150.

That is, the first protective layer 4150 includes a convex portion 4150P. In addition, the second protective layer 4160 includes a convex portion 4160P.

The convex portion 4150P of the first protective layer 4150 can be convex in an upward direction on the upper surface of the first protective layer 4150. Preferably, the convex portion 4150P of the first protective layer 4150 can protrude upward on the upper surface of the first protective layer 4150 adjacent to the through hole.

Specifically, the first protective layer 4150 can be divided into a plurality of regions in the horizontal direction. For example, the first protective layer 4150 includes a through hole and a first region R1 adjacent to the through hole. In addition, the first protective layer 4150 includes a second region R2 other than the first region R1. In addition, the first region R1 of the first protective layer 4150 may have a first height. In this case, the first height may mean a vertical distance from the upper surface of the insulating layer 4110 to an upper surface of the first region R1 of the first protective layer 4150. In addition, the second region R2 of the first protective layer 4150 may have a second height different from the first height. The second height may mean a vertical distance from the upper surface of the insulating layer 4110 to an upper surface of the second region R2 of the first protective layer 4150. In addition, the first height may be greater than the second height. That is, the upper surface of the first protective layer 4150 of the embodiment may include a region whose height increases as it approaches the through hole. For example, a convex portion 4150P that is positioned higher than the second region R2 of the first protective layer 4150 and is convex in the upward direction may be formed in the first region R1 of the first protective layer 4150.

The convex portion 4160P of the second protective layer 4160 may be convex in a downward direction from a lower surface of the second protective layer 4160. Preferably, the convex portion 4160P of the second protective layer 4160 may protrude downward from the lower surface of the second protective layer 4160 adjacent to the through hole. In addition, the second protective layer 4160 may also include a first region and a second region corresponding to the first protective layer 4150. In addition, a first height of a first region of the second protective layer 4160 may be greater than a second height of a second region of the second protective layer 4160. At this time, the first height of the first region of the second protective layer 4160 may mean a vertical distance from a lower surface of the insulating layer 4110 to a lower surface of the first region of the second protective layer 4160. In addition, a second height of the second region of the second protective layer 4160 may mean a vertical distance from a lower surface of the insulating layer 4110 to a lower surface of the second region of the second protective layer 4160.

The first protective layer 4150 includes a first through hole 4151. For example, the first protective layer 4150 may include a first through hole 4151 that vertically overlaps with the first pad 4120-1 of the upper wiring electrode 4120.

The first through hole 4151 of the first protective layer 4150 may partially vertically overlap with the upper surface of the first pad 4120-1. A width W1 of the first through hole 4151 of the first protective layer 4150 may be smaller than a width of an upper surface of the first pad 4120-1. For example, the first protective layer 4150 may include a first through hole 4151 that covers at least a portion of the upper surface of the first pad 4120-1 while exposing a remaining portion of the upper surface of the first pad 4120-1.

A width W1 of the first through hole 4151 of the first protective layer 4150 can satisfy a range of 10 μm to 20 μm. Preferably, the width W1 of the first through hole 4151 of the first protective layer 4150 can satisfy a range of 12 μm to 20 μm. More preferably, the width W1 of the first through hole 4151 of the first protective layer 4150 can satisfy a range of 13 μm to 20 μm.

At this time, when the first through hole 4151 of the first protective layer 4150 has a change in width in the thickness direction, the width W1 of the first through hole 4151 can mean a width of a region having a largest width among the entire region.

If the width W1 of the first through hole 4151 of the first protective layer 4150 is less than 10 um, an amount of solder applied to a connection part, such as a solder ball, disposed in the first through hole 4151 may be reduced, thereby reducing the bonding strength with the semiconductor device. If the width W1 of the first through hole 4151 of the first protective layer 4150 exceeds 20 um, the width of the first pad 4120-1 increases correspondingly, and thus the circuit integration may decrease.

The first through hole 4151 of the first protective layer 4150 may have almost no change in width from a region adjacent to the upper surface of the first protective layer 4150 to a region adjacent to the lower surface of the first protective layer 4150. Here, a fact that there is no change in width may mean that a slope of a first inner surface 4151S of the first protective layer 4150 constituting the first through hole 4151 is close to vertical. For example, the fact that there is no change in width may mean that a difference in width between a region having a maximum width and a region having a minimum width in the entire region in the thickness direction of the first through hole 4151 is 3 um or less, 2.5 um or less, 2 um or less, 1.5 um or less, 1 um or less, or 0.5 um or less. The first through hole 4151 of the first protective layer 4150 is formed using a resist pattern as described in the previous embodiment.

An upper surface 4150T of the first protective layer 4150 may have a surface roughness different from the surface roughness of a first inner surface 4151S of the first through hole 4151.

In other words, the upper surface 4150T of the first protective layer 4150 may have a different roughness from the inner surface (4150S, see FIG. 17) of the through hole of the first protective layer 4150. The inner surface 4150S of the through hole may include a first inner surface 4151S of the first through hole 4151 and a second inner surface 4152S of the second through hole 4152. The surface roughness of the upper surface 4150T of the first protective layer 4150 may be greater than the surface roughness of the inner surface of the through hole of the first protective layer 4150.

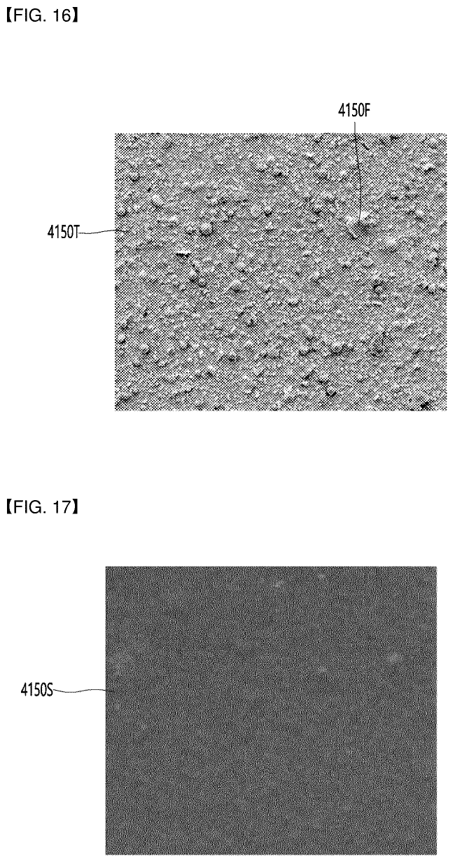

Referring to FIG. 16, the first protective layer 4150 includes a resin and a filler 4150F dispersed within the resin. At this time, when the first protective layer 4150 is etched using a chemical solution and/or plasma, etc., the filler 4150F disposed in the first protective layer 4150 may be exposed to the upper surface 4150T of the first protective layer 4150. Alternatively, the filler 4150F may not be exposed through the inner surface 4150S of the through hole of the first protective layer 4150, or the amount of filler exposed through the inner surface 4150S of the through hole of the first protective layer 4150 may be smaller than the amount of filler exposed to the upper surface 4150T of the first protective layer 4150. Accordingly, the upper surface 4150T of the first protective layer 4150 may have a greater surface roughness than the inner surface of the through hole of the first protective layer 4150 due to the filler 4150F.

The surface roughness of the upper surface 4150T of the first protective layer 4150 can be increased by the filler 4150F exposed through the upper surface 4150T of the first protective layer 4150. Through this, the embodiment can increase a bonding area between the first protective layer 4150 and the molding layer in a molding process after mounting the semiconductor device on the circuit board, thereby improving the bonding strength.

The first protective layer 4150 includes a second through hole 4152. For example, the first protective layer 4150 can include a second through hole 4152 that vertically overlaps with the second pad 4120-2 of the upper wiring electrode 4120.

At this time, the second through hole 4152 of the first protective layer 4150 can vertically overlap with the upper surface of the second pad 4120-2 as a whole. That is, a width W2 of the second through hole 4152 of the first protective layer 4150 may be larger than a width of the upper surface of the second pad 4120-2. For example, the first protective layer 4150 may entirely expose the upper surface and the inner surface of the second pad 4120-2. For example, a second inner surface 4152S of the second through hole 4152 of the first protective layer 4150 may be spaced apart from and not in contact with the second pad 4120-2. For example, the second pad 4120-2 may not be in contact with the first protective layer 4150.

At this time, the embodiment forms a resist pattern by exposing and developing a photosensitive film capable of implementing a relatively fine pattern, rather than exposing and developing the protective layer itself, such as a solder resist. In addition, the embodiment forms a through hole in the first protective layer 4150 using a resist pattern. Therefore, the embodiment can reduce a size of the through hole formed in the first protective layer 4150 compared to the comparative example, thereby improving the circuit integration.

At this time, since the embodiment does not expose and develop the first protective layer 4150, the first protective layer 4150 does not need to contain a photo initiator. For example, a general solder resist contains a photo initiator for exposure and development. At this time, the photo initiator acts as a factor that deteriorates the physical characteristics and electrical characteristics of the circuit board.

Here, since the embodiment does not expose and develop the first protective layer 4150, the first protective layer 4150 does not contain a photo initiator. Accordingly, the embodiment can improve the physical characteristics and electrical characteristics of the circuit board by not containing a photo initiator in the first protective layer 4150.

Furthermore, the embodiment can expand types of insulating layers that can be used as the first protective layer 4150 since the first protective layer 4150 does not include a photo initiator, and further reduces an unit cost required for developing the protective layer.

For example, the first protective layer 4150 of the embodiment can be a solder resist without a photo initiator. Unlike this, the first protective layer 4150 of the embodiment can use an insulating layer in which an inorganic filler of silica or alumina is disposed in a thermosetting resin or a thermoplastic resin without including glass fibers. For example, the first protective layer 4150 can use ABF (Ajinomoto Build-up Film), FR-4, BT (Bismaleimide Triazine), PID (Photo Imageable Dielectric resin), etc.

However, according to an embodiment, the first protective layer 4150 and the second protective layer 4160 of the present invention may be implemented using a solder resist used in a general circuit board. For example, according to an embodiment, the first protective layer 4150 and the second protective layer 4160 may include a photo initiator.

The upper surface 4150T of the first protective layer 4150 is provided with a convex portion 4150P.

For example, the first protective layer 4150 may have a first height in the first region R1 greater than a second height in the second region R2 due to the convex portion 4150P.

The first region R1 of the first protective layer 4150 is a region adjacent to a through hole formed in the first protective layer 4150. For example, a convex portion 4150P may be convex in an upper direction, and may be formed in the first region R1 of the first protective layer 4150.

At this time, the convex portion 4150P may be formed adjacent to the through hole on the upper surface of the first protective layer 4150. For example, the convex portion 4150P may be convex in an upper region of the through hole of the first protective layer 4150. For example, the convex portion 4150P may be convex in the upper direction while being connected to the through hole of the first protective layer 4150.

Preferably, the convex portion 4150P may be formed to surround an inner edge of the through hole of the first protective layer 4150. The convex portion 4150P is connected to the through hole of the first protective layer 4150. Accordingly, an inner region of the convex portion 4150P connected to the through hole can also be referred to as a part of the through hole.

At this time, the convex portion 4150P does not follow a profile of a surface of the upper wiring electrode 4120 disposed on the upper surface of the insulating layer 4110. For example, a general protective layer is formed along the profile of the wiring electrode. For example, a general protective layer has a large height in a region vertically overlapping with the wiring electrode, and a small height in a region not overlapping with the wiring electrode. This is a structural feature that appears due to the difference in surface height in the process of forming the protective layer. That is, a region overlapping with the wiring electrode in the protective layer has a larger height than a region not overlapping with the wiring electrode, and thus, the region can also be referred to as the convex portion. However, this is different from a structural feature of the convex portion 4150P of the present invention.

That is, a general protective layer formed along the profile of a wiring electrode, 1) is convex in the entire region overlapping the wiring electrode, and 2) is not convex in the entire region not overlapping the wiring electrode.

In contrast, the first protective layer 4150 of the present invention, in which a convex portion 4150P is formed based on the through hole, 1) is convex in a region adjacent to the through hole, 2) at this time, a convex region includes not only a region vertically overlapping with the wiring electrode but also a region not vertically overlapping, and 3) a region spaced apart from the through hole among the region vertically overlapping with the wiring electrode is not convex.

At this time, the filler 4150F is exposed on the upper surface 4150T of the first region R1 and the second region R2 of the first protective layer 4150. In other words, the convex portion 4150P of the present invention is not a structure naturally formed by the profile of the wiring electrode, but a structural feature provided in the process of forming the through hole of the first protective layer 4150 of the present invention. In addition, the convex portion 4150P of the embodiment can function as a barrier structure that prevents diffusion of a connection part such as a solder ball in a packaging process.

Referring to FIG. 11, FIG. 14 (a), and FIG. 15, the first protective layer 4150 includes a first convex portion 4151P. The first convex portion 4151P can be formed in a region of the upper surface of the first protective layer 4150 adjacent to the first through hole 4151. For example, the first convex portion 4151P can be formed in the first region R1 of the first protective layer 4150 adjacent to the first through hole 4151. The first convex portion 4151P may be provided to surround an inner edge of the upper surface of the first through hole 4151. The first convex portion 4151P is positioned adjacent to the first through hole 4151. At this time, a first inner surface 4151S of the first through hole 4151 vertically overlaps with the first pad 4120-1. In addition, the first convex portion 4151P is connected to the first inner surface 4151S of the first through hole 4151. Accordingly, the first convex portion 4151P may vertically overlap with the first pad 4120-1. At this time, the upper surface 4150T of the first protective layer 4150 adjacent to the first convex portion 4151P and vertically overlapping the first pad 4120-1 may be flat rather than convex. At this time, being flat may mean that a height deviation in an entire region of the upper surface is 1 um or less, 0.8 um or less, 0.5 um or less, or 0.2 um or less. At this time, the height deviation may be divided into a height deviation in a portion where the filler 4150F is exposed and a height deviation in a portion where the filler 4150F is not exposed.

The first convex portion 4151P of the first through hole 4151 may partially vertically overlap the first pad 4120-1. This may mean that the first region R1 of the first protective layer 4150 adjacent to the first through hole 4151 partially overlaps vertically with the first pad 4120-1. For example, the second region R2 of the first protective layer 4150 may not vertically overlap with the first pad 4120-1. The first convex portion 4151P or the first region R1 may include an overlapping region that vertically overlaps with the first pad 4120-1 and a non-overlapping region that vertically does not overlap with the first pad 4120-1.

Referring to FIG. 11 and FIG. 14 (b), the first protective layer 4150 includes a second convex portion 4152P. The second convex portion 4152P may be formed in the first region R1 of the first protective layer 4150 adjacent to the second through hole 4152 among the upper surface of the first protective layer 4150. Preferably, the second convex portion 4152P may be provided to surround an inner edge of the upper surface of the second through hole 4152. At this time, the second inner surface 4152S of the second through hole 4152 does not vertically overlap with the second pad 4120-2. In addition, the second convex portion 4152P is connected to the second inner surface 4152S of the second through hole 4152. Accordingly, the second convex portion 4152P may not vertically overlap with the second pad 4120-2. That is, the second convex portion 4160P positioned adjacent to the second through hole 4152 may not vertically overlap the upper wiring electrode 4120 unlike the first convex portion 4151P.

That is, the first region R1 of the first protective layer 4150 adjacent to the second convex portion 4152P or the second through hole 4152 may not vertically overlap with the upper wiring electrode 4120 including the second pad 4120-2.

In addition, referring to FIG. 12, the first protective layer 4150 may include a third convex portion. The first protective layer 4150 may include a third through hole 4153 that vertically overlaps with the third pad 4120-3 of the upper wiring electrode 4120. At this time, the third through hole 4153 may be divided into a plurality of sub through holes. The third pad 4120-3 may be a ground pad. For example, the third pad 4120-3 may be a large-area pad.

Accordingly, the first protective layer 4150 includes a third through hole 4153 including a plurality of sub through holes that partially expose the third pad 4120-3. The third through hole 4153 may include a first sub through hole 4153-1 that partially exposes the third pad 4120-3. In addition, the third through hole 4153 may include a second sub through hole 4153-2 that is spaced apart from the first sub through hole 4153-1 and partially exposes the third pad 4120-3.

The first protective layer 4150 may include a third convex portion adjacent to the third through hole 4153. For example, the third convex portion of the first protective layer 4150 includes a third-first convex portion 4153-1P surrounding an upper portion of the first sub-through hole 4153-1 of the third through hole 4153. In addition, the third convex portion of the first protective layer 4150 includes a third-second convex portion 4153-2P surrounding an upper portion of the second sub-through hole 4153-2 of the third through hole 4153. At this time, an upper surface 153F between the third-first convex portion 4153-1P and the third-second convex portion 4153-2P may be non-convex and flat while vertically overlapping the third pad 4120-3 among the upper surfaces of the first protective layer 4150. That is, the upper surface 153F between the third-first convex portion 4153-1P and the third-second convex portion 4153-2P can be positioned lower than the third-first convex portion 4153-1P and the third-second convex portion 4153-2P.

The first convex portion 4151P will be described in detail. In addition, the second convex portion 4152P and the third convex portion 4153P can have a structure corresponding to the first convex portion 4151P described below.

Referring to FIG. 5, the first convex portion 4151P can be provided to surround an upper region of the first through hole 4151 with a closed loop shape. That is, the first region R1 of the first protective layer 4150 may be disposed in the upper region of the first through hole 4151 and surrounding the first through hole 4151.

The first convex portion 4151P may have a shape in which the width decreases or is maintained as it goes from the lower surface to the upper surface. The width of the first convex portion 4151P may mean a distance in the horizontal direction of the first convex portion 4151P. For example, a height of the first region R1 of the first protective layer 4150 including the first convex portion 4151P may decrease toward the second region R2. A vertical cross-sectional shape of the first convex portion 4151P may be a triangle, but is not limited thereto. For example, the vertical cross-sectional shape of the first convex portion 4151P may be provided in various shapes such as a step shape, a fan shape, a polygonal shape, etc.

At this time, the first convex portion 4151P may be formed in a process of etching the first protective layer 4150 using the resist pattern DFR1-F. That is, when etching the first protective layer 4150 using the resist pattern DFR1-F, it may be formed by controlling the etching conditions in a region adjacent to the resist pattern DFR1-F. In addition, the shape, width, thickness, and outer slope of the first convex portion 4151P may be controlled by controlling the etching conditions.

The first convex portion 4151P includes an inner surface 4151PS1 and an outer surface 4151PS2. The inner surface 4151PS1 of the first convex portion 4151P is connected to the first inner surface 4151S of the first through hole 4151. Accordingly, the inner surface 4151PS1 of the first convex portion 4151P may also be referred to as a part of the first inner surface 4151S of the first through hole 4151. The inner surface 4151PS1 of the first convex portion 4151P may have a predetermined slope. For example, the inner surface 4151PS1 of the first convex portion 4151P may have a slope corresponding to the slope of the first inner surface 4151S of the first through hole 4151.

The inner surface 4151PS1 of the first convex portion 4151P may have a predetermined height. For example, the inner surface 4151PS1 of the first convex portion 4151P may have a vertical length T1 corresponding to the thickness of the first convex portion 4151P. The vertical length T1 may mean any one of the vertical length of the inner surface 4151PS1 of the first convex portion 4151P, the vertical length of the outer surface 4151PS2 of the first convex portion 4151P, and the thickness of the first convex portion 4151P. In addition, the vertical length T1 may mean a difference between the first height of the first region R1 of the first protective layer 4150 and the second height of the second region R2.

The vertical length T1 or the thickness of the first convex portion 4151P may satisfy a range of 1.0 μm to 4.0 μm. Preferably, the thickness or the vertical length T1 or the first convex portion 4151P can satisfy a range of 1.2 μm to 3.8 um. The thickness or the vertical length T1 of the first convex portion 4151P can satisfy a range of 1.5 um to 3.5 um. If the thickness or the vertical length T1 of the first convex portion 4151P is less than 1.0 um, an effect exhibited by the first convex portion 4151P may be insignificant. For example, if the thickness or the vertical length T1 of the first convex portion 4151P is less than 1.0 um, the solder diffusion prevention effect or the solder short prevention effect may be insignificant. If the vertical length T1 or the thickness of the first convex portion 4151P exceeds 4.0 um, a distance between the first pad 4120-1 and the semiconductor device at the position where the first convex portion 4151P is disposed increases, and accordingly, signal transmission loss may increase due to the increase in signal transmission distance. In addition, if the vertical length T1 or the thickness of the first convex portion 4151P exceeds 4.0 um, a width of the first convex portion 4151P must increase in order for the first convex portion 4151P to maintain a certain strength, and thus, an unfilled region may occur during a formation of the molding layer.

The width W3 of the first convex portion 4151P may satisfy a range of 0.5 um to 2.5 um. Preferably, the width W3 of the first convex portion 4151P can satisfy a range of 0.7 um to 2.3 um. More preferably, the width W3 of the first convex portion 4151P can satisfy a range of 0.9 um to 2.0 um. The width W3 of the first convex portion 4151P can mean a maximum width in an entire region in the thickness direction of the first convex portion 4151P. For example, the width W3 of the first convex portion 4151P can mean a width of the first region R1 of the first protective layer 4150 adjacent to the first through hole 4151. If the width W3 of the first convex portion 4151P is less than 0.5 um, the rigidity of the first convex portion 4151P can be reduced. In addition, if the width W3 of the first convex portion 4151P is less than 0.5 um, a problem may occur in which the first convex portion 4151P collapses due to pressure applied during a process of disposing a connection part, such as a solder ball, in the first through hole 4151. In addition, if the width W3 of the first convex portion 4151P exceeds 2.5 um, the filling of the molding layer in the corresponding region may not occur, and thus, a physical and/or electrical reliability problem may occur due to the molding not being performed.

The outer surface 4151PS2 of the first convex portion 4151P may have a predetermined slope angle (θ). The slope angle (θ) of the outer surface 4151PS2 of the first convex portion 4151P may mean the slope of an imaginary straight line connecting the uppermost and lowermost ends of the outer surface 4151PS2 of the first convex portion 4151P. Specifically, the slope angle (θ) of the outer surface 4151PS2 of the first convex portion 4151P may mean an internal angle formed by the outer surface 4151PS2 of the first convex portion 4151P and the lower surface of the first convex portion 4151P. For example, the slope angle (θ) of the outer surface 4151PS2 of the first convex portion 4151P may mean the slope angle of the upper surface of the first region R1 of the first protective layer 4150. For example, the slope angle (θ) of the outer surface 4151PS2 of the first convex portion 4151P may mean an inner angle between the upper surface of the first region R1 of the first protective layer 4150 and the lower surface of the first region R1. The slope angle (θ) of the outer surface 4151PS2 of the first convex portion 4151P may satisfy a range between 50 degrees and 75 degrees. Preferably, the slope angle (θ) of the outer surface 4151PS2 of the first convex portion 4151P may satisfy a range between 52 degrees and 73 degrees. More preferably, the slope angle (θ) of the outer surface 4151PS2 of the first convex portion 4151P can satisfy a range between 55 degrees and 70 degrees. If the slope angle (θ) of the outer surface 4151PS2 of the first convex portion 4151P is less than 50 degrees, the width W3 of the first convex portion 4151P may increase, and thus a reliability problem may occur in the filling process of the molding layer. In addition, if the slope angle (θ) of the outer surface 4151PS2 of the first convex portion 4151P exceeds 75 degrees, the rigidity of the first convex portion 4151P may be reduced, or the vertical length T1 of the first convex portion 4151P may increase.

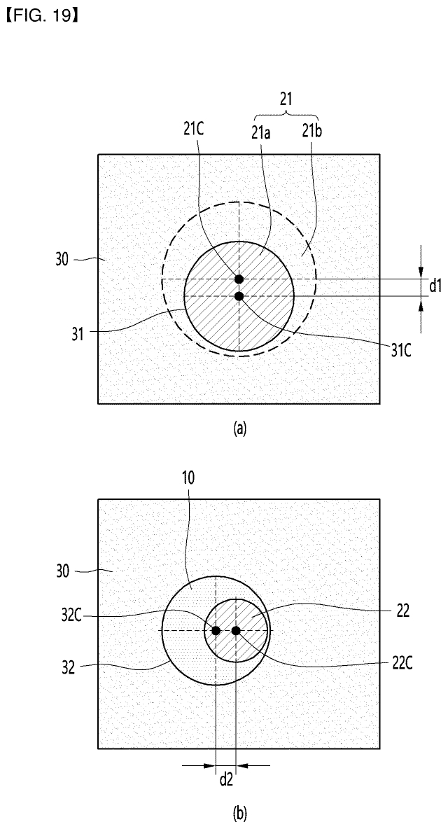

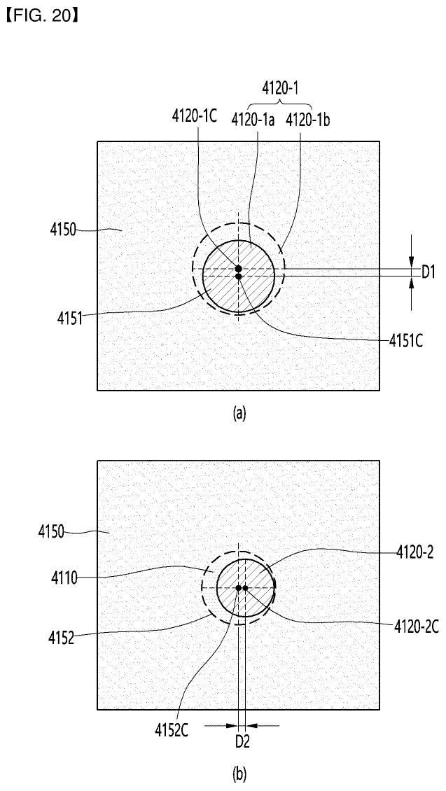

FIG. 19 is a plan view for explaining a tolerance (SRR: Solder Resist Registration) according to a comparative example, and FIG. 20 is a view for explaining a tolerance according to a sixth embodiment.

Referring to FIG. 19 (a), in the comparative example, the first pad 21 includes a first portion 21a exposed through a first through hole 31 of a protective layer 30 and a second portion 21b covered with a protective layer 30. At this time, in the comparative example, the protective layer 30 is exposed and developed to form the first through hole 31. At this time, the protective layer 30 has a significantly lower exposure resolution than the DFR. Accordingly, in the comparative example, it can be confirmed that a center 21C of the first pad 21 and a center 31C of the first through hole 31 are misaligned by a first tolerance d1. Specifically, the first tolerance d1 between the center 21C of the first pad 21 and the center 31C of the first through hole 31 in the comparative example exceeds 12.5 μm, or exceeds 14 μm, or exceeds 15 μm. Accordingly, in the comparative example, an alignment reliability problem may occur in which at least a part of the first through hole 31 does not vertically overlap with the first pad 21.

Referring to (b) of FIG. 19, in the comparative example, the second pad 22 is entirely exposed through the second through hole 32 of the protective layer 30. At this time, in the comparative example, the protective layer 30 is exposed and developed in order to form the second through hole 32. At this time, the protective layer 30 has a significantly lower exposure resolution than the DFR. Accordingly, in the comparative example, it can be confirmed that a center 22C of the second pad 22 and a center 32C of the second through hole 32 are misaligned by a second tolerance d2. Specifically, the second tolerance d2 between the center 22C of the second pad 22 and the center 32C of the second through hole 32 in the comparative example exceeds 12.5 um, or exceeds 14 um, or exceeds 15 um. Accordingly, in the comparative example, an alignment reliability problem may occur in which at least a portion of the upper surface of the second pad 22 is covered by the protective layer 30.

In contrast, the embodiment can significantly reduce the tolerance compared to the comparative example.

For example, referring to (a) of FIG. 20, in the case of the embodiment, the first pad 4120-1 includes a first portion 4120-1a exposed through the first through hole 4151 of the first protective layer 4150 and a second portion 4120-1b covered by the first protective layer 4150. At this time, in the embodiment, in order to form the first through hole 4151, a resist pattern DFR1-F formed through DFR is used instead of exposing and developing the first protective layer 4150. Accordingly, in the embodiment, it can be confirmed that a center 4120-1C of the first pad 4120-1 and a center 4151C of the first through hole 4151 are misaligned by a third tolerance d1 that is significantly reduced compared to the first tolerance d1 of the comparative example. Specifically, the third tolerance d1 between the center 4120-1C of the first pad 4120-1 of the embodiment and the center 4151C of the first through hole 4151 is 10 um or less, or 9 um or less, or 8 um or less. Therefore, the embodiment can improve the alignment accuracy between the first through hole 4151 and the first pad 4120-1. Through this, the embodiment can further improve the electrical reliability and/or physical reliability of the circuit board.

In addition, referring to (b) of FIG. 20, in the case of the embodiment, the second pad 4120-2 is entirely exposed through the second through hole 4152 of the first protective layer 4150. At this time, in the embodiment, in order to form the second through hole 4152, the resist pattern DFR1-F formed through DFR is used instead of exposing and developing the first protective layer 4150. Accordingly, in the embodiment, it can be confirmed that a center 4120-2C of the second pad 4120-2 and a center 4152C of the second through hole 4152 are misaligned by a fourth tolerance D2 that is significantly reduced compared to the second tolerance d2 of the comparative example. Specifically, the fourth tolerance D2 between the center 4120-1C of the second pad 4120-2 and the center 4152C of the second through hole 4152 of the embodiment is 10 um or less, or 9 um or less, or 8 um or less. Therefore, the embodiment can improve the alignment accuracy between the second through hole 4152 and the second pad 4120-2. Through this, the embodiment can further improve the electrical reliability and/or physical reliability of the circuit board.

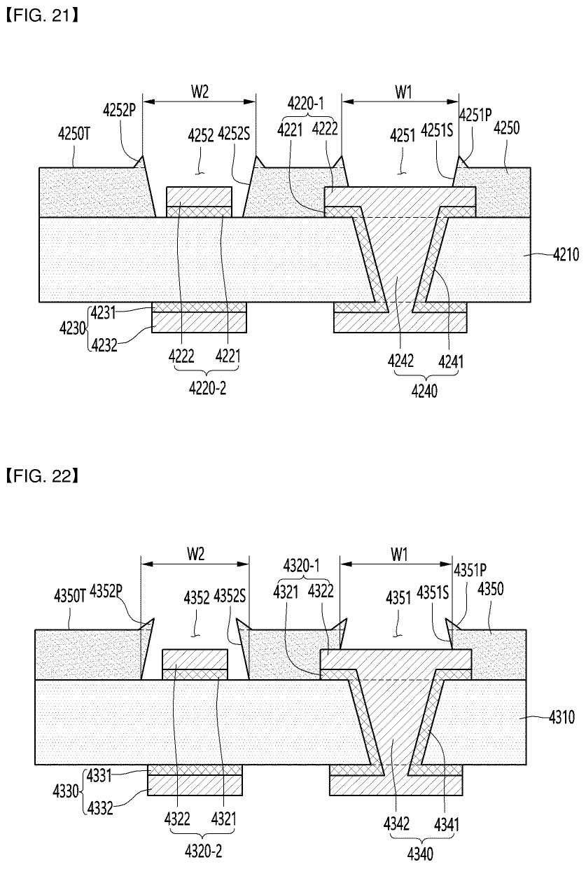

FIG. 21 is a cross-sectional view showing a circuit board according to a seventh embodiment.

Referring to FIG. 21, the circuit board according to the seventh embodiment includes an insulating layer 4210, an upper wiring electrode 4220, a lower wiring electrode 4230, a via electrode 4240, a first protective layer 4250, and a second protective layer 4260. The upper wiring electrode 4220, the lower wiring electrode 4230, and the via electrode 4240 include a first metal layer 4221, 4231, 4241 and a second metal layer 4222, 4232, and 4242, respectively.

At this time, an inner surface of the through hole in the seventh embodiment has a substantially vertical slope with respect to the upper surface of the insulating layer. Differently, an inner surface of the through hole in the eighth embodiment may have a slope with respect to the upper surface of the insulating layer.

For example, the upper wiring electrode 4220 includes a first pad 4220-1 and a second pad 4220-2. In addition, the first protective layer 4250 includes a first through hole 4251 that vertically overlaps with the first pad 4220-1. In addition, the first protective layer 4250 includes a second through hole 4252 that vertically overlaps with the second pad 4220-2.

At this time, a basic structure of the first through hole 4251 and the second through hole 4252 is same as that of the sixth embodiment, and a detailed description thereof is omitted.

A width of the first through hole 4251 may change from the upper surface to the lower surface of the first protective layer 4250. For example, a first inner surface 4251S of the first protective layer 4250 of the first protective layer 4250 may have a slope in which the width decreases toward a downward direction. That is, in the seventh embodiment, a photosensitive film used to form the first through hole 4251 is a negative type, and a resist pattern DFR1-F may be formed using the negative type photosensitive film. Accordingly, the resist pattern DFR1-F may have a shape in which the width decreases toward the downward direction. In addition, a first inner surface 4251S of the first through hole 4251 of the first protective layer 4250 formed by the resist pattern DFR1-F may have a slope in which the width decreases toward the downward direction. The negative type photosensitive film has the characteristic that, when exposed and developed, the parts that were not exposed to light are developed and removed.

Correspondingly, the second inner surface 4252S of the second through hole 4252 of the first protective layer 4250 may also have a slope whose width decreases toward a downward direction.

At this time, the embodiment does not include an undercut in the first inner surface 4251S and the second inner surface 4252S. Accordingly, each of the first inner surface 4251S and the second inner surface 4252S has a slope whose width decreases from an upper end to a lower end. At this time, the first through hole 4251 and the second through hole 4252 only include a slope whose width decreases from an upper end to a lower end of the first inner surface 4251S and the second inner surface 4252S, respectively, and do not include a slope in which the width is maintained or a slope in which the width increases. In other words, a slope in which the width is maintained or a slope in which the width increases may mean an undercut. In addition, since the embodiment does not include an undercut, each of the first inner surface 4251S and the second inner surface 4252S of the first through hole 4251 and the second through hole 4252 may include only a slope in which the width decreases, and may not include a slope in which the width is maintained or the width increases. At this time, the embodiment forms a through hole in the first protective layer 4250 using a negative type photosensitive film as described above. Through this, the embodiment can ensure that a removal of the resist pattern DFR1-F is smoothly performed in a process of removing the resist pattern DFR1-F after forming the through hole in the first protective layer 4250. Through this, the embodiment can solve the problem of the first protective layer 4250 being separated from the insulating layer 4210 in the process of removing the resist pattern DFR1-F.

The first protective layer 4250 includes a first convex portion 4251P surrounding an upper portion of the first through hole 4251. In addition, a slope of the inner surface of the first convex portion 4251P may have a slope corresponding to the slope of the first inner surface 4251S of the first through hole 4251. In addition, the slope of the inner surface of the first convex portion 4251P may mean a portion that horizontally overlaps with the first convex portion 4251P, and the first inner surface 4251S of the first through hole 4251 may mean a region that horizontally overlaps with the second region R2 of the first protective layer 4250.

The first protective layer 4250 includes a second convex portion 4252P surrounding an upper portion of the second through hole 4252. In addition, the inner surface of the second convex portion 4252P may have a slope corresponding to a slope of the second inner surface 4252S of the second through hole 4252.

FIG. 22 is a cross-sectional view showing a circuit board according to the eighth embodiment.

Referring to FIG. 22, the circuit board of the eighth embodiment includes an insulating layer 4310, an upper wiring electrode 4320, a lower wiring electrode 4330, a via electrode 4340, a first protective layer 4350, and a second protective layer 4360. The upper wiring electrode 4320, the lower wiring electrode 4330, and the through electrode 4340 include a first metal layer 4321, 4331, and 4341 and a second metal layer 4322, 4332, and 4342, respectively.

At this time, an inner surface of the through hole in the sixth embodiment has a substantially vertical slope with respect to the upper surface of the insulating layer, and an inner surface of the through hole in the seventh embodiment has a slope whose width decreases in a downward direction. In addition, an inner surface of the through hole of the eighth embodiment may have a slope whose width increases in the downward direction.

For example, the upper wiring electrode 4320 includes a first pad 4320-1 and a second pad 4320-2. In addition, the first protective layer 4350 includes a first through hole 4351 that vertically overlaps the first pad 4320-1. In addition, the first protective layer 4350 includes a second through hole 4352 that vertically overlaps the second pad 4320-2.

A width of the first through hole 4351 may change from the upper surface of the first protective layer 4350 to the lower surface. For example, the first inner surface 4351S of the first protective layer 4350 of the first protective layer 4350 may have a slope whose width increases toward the downward direction. That is, in the eighth embodiment, a photosensitive film used to form the first through hole 4351 is a positive type, and the resist pattern DFR1-F may be formed using the positive type photosensitive film. Through this, the resist pattern DFR1-F may have a shape whose width increases toward the downward direction. In addition, the first inner surface 4351S of the first through hole 4351 of the first protective layer 4350 formed by the resist pattern DFR1-F may have a slope whose width increases toward the downward direction. The positive type photosensitive film has a characteristic that, during exposure and development, a portion that has received light is developed and removed.

Correspondingly, the second inner surface 4352S of the second through hole 4352 of the first protective layer 4350 may also have a slope whose width decreases toward the downward direction. At this time, in the eighth embodiment, as the width of the through hole increases toward the downward direction, when a connection part such as a solder ball is disposed in the through hole, the through hole may function as an anchor. Through this, the embodiment may improve the bonding property with the connection part.

In addition, the first protective layer 4350 includes a first convex portion 4351P surrounding an upper portion of the first through hole 4351. In addition, the inner surface of the first convex portion 4351P may have a slope corresponding to a slope of the first inner surface 4351S of the first through hole 4351.

In addition, the first protective layer 4350 includes a second convex portion 4352P surrounding an upper portion of the second through hole 4352. In addition, the inner surface of the second convex portion 4352P may have a slope corresponding to a slope of the second inner surface 4352S of the second through hole 4352.

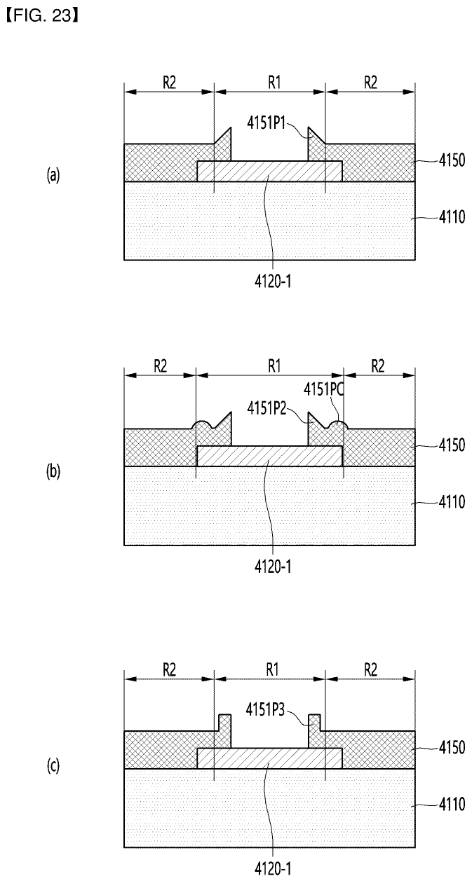

FIG. 23 is a view showing various modified examples of the circuit board of the embodiment.

In the circuit board of the sixth embodiment, the first convex portion 4151P formed in the first region R1 of the first protective layer 4150 partially overlaps the first pad 4120-1 in a vertical direction.

In contrast, referring to (a) of FIG. 23, an entire region of the first convex portion 151P1 formed in the first region R1 of the first protective layer 4150 may vertically overlap with the first pad 4120-1. For example, a boundary between the first region R1 and the second region R2 of the first protective layer 4150 may vertically overlap with the first pad 4120-1.

In addition, referring to (b) of FIG. 23, the first convex portion 151P2 formed in the first region R1 of the first protective layer 4150 may have a sub-convex portion 4151PC formed in a region that vertically overlaps with an edge region of the first pad 4120-1. The sub-convex portion 4151PC may be a portion that protrudes due to a height of the first pad 4120-1 in a process of applying the first protective layer 4150.

Meanwhile, the convex portion in the previous embodiment had a slope having a certain slope. For example, the convex portion in the previous embodiment had a shape whose width changed from an upper side to a lower side. For example, a height of the first region R1 of the first protective layer 4150 gradually decreases toward the second region R2.

Unlike this, referring to (c) of FIG. 23, the first convex portion 4151P3 formed in the first region R1 of the first protective layer 4150 may have a shape without a change in width. For example, the upper surface of the first region R1 of the first protective layer 4150 may not have a change in height. For example, a vertical cross-sectional shape of the first convex portion 4151P3 may have a rectangular shape.

Meanwhile, although FIG. 23 describes a modified example of the first convex portion, the second convex portion and the third convex portion in the sixth embodiment may also be modified to have the same structure.

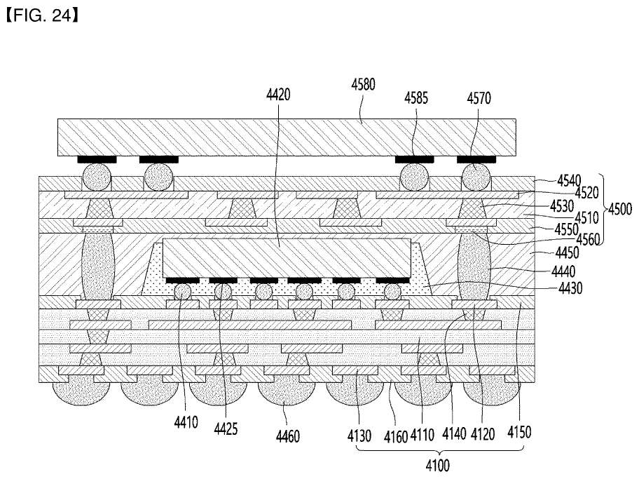

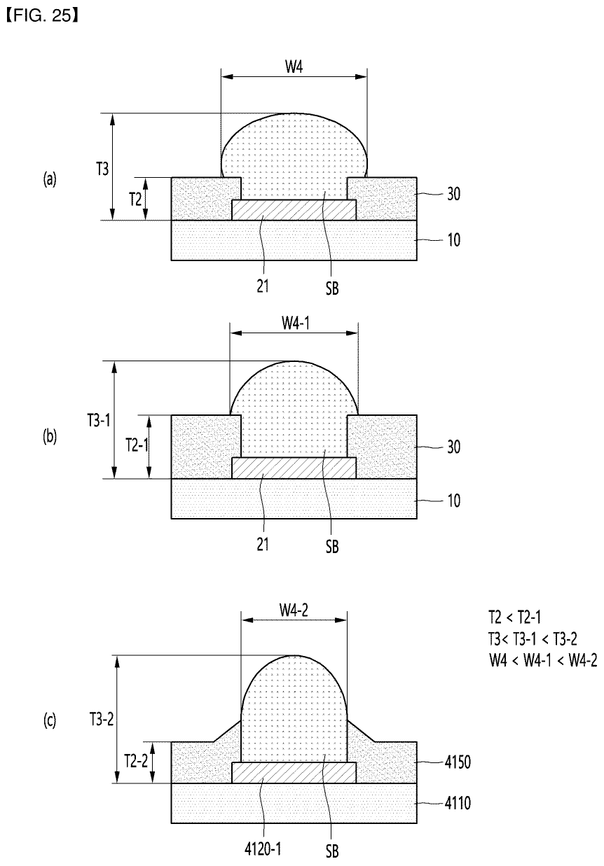

FIG. 24 is a cross-sectional view illustrating a semiconductor package according to another embodiment, and FIG. 25 is a view showing arrangement reliability of first connection parts of embodiments and comparative examples.

Referring to FIGS. 24 and 25, the semiconductor package of another embodiment may have a POP (Package On package) structure.

The first connection part 4410 is disposed on a circuit board. In addition, a semiconductor chip 4420 is mounted on the first connection part 4410, a terminal 4425 of the semiconductor chip 4420 is connected to the wiring electrode of the circuit board through the first connection part 4410.

At this time, referring to (a) of FIG. 25, in the first comparative example, a through hole is formed in a protective layer 30 having the same thickness T2 as the thickness of the first protective layer of the present invention, and a certain amount of solder balls SB are disposed in the through hole. At this time, in the first comparative example, since a thickness T2 of the protective layer is relatively small, the diffusion of the solder balls SB cannot be effectively prevented. Accordingly, in the first comparative example, the degree of diffusion of the solder balls SB is large, and accordingly, a width W4 of the solder balls SB is relatively large. In addition, as the diffusion of the solder balls SB increases in the first comparative example, a thickness T3 of the solder balls SB also appears relatively low.

Also, referring to (b) of FIG. 25, in the second comparative example, a through hole is formed in the protective layer 30 having a thickness T2-1 greater than the thickness of the first protective layer of the present invention and the protective layer 30 of the first comparative example, and a certain amount of solder balls SB are disposed in the through hole. At this time, in the second comparative example, the thickness T2-1 of the protective layer is greater than the thickness T2 of the protective layer of the first comparative example, and accordingly, the diffusion of the solder balls SB can be prevented to some extent. However, even if the thickness T2-1 of the protective layer 30 is increased as in the second comparative example, it can be confirmed that the diffusion of the solder balls SB occurs, and accordingly, it can be confirmed that the width W4-1 due to the diffusion of the solder balls SB is greater than the through hole of the protective layer 30. Accordingly, it can be confirmed that the thickness T3-1 of the solder balls SB of the second comparative example increases compared to the first comparative example, but does not have the target thickness. In addition, in the second comparative example, since an entire region of the protective layer 30 has a thickness T2-1, the flowability of EMC may be reduced during EMC filling for forming the molding layer, and thus, a region where EMC is not filled may occur.

In contrast, referring to (c) of FIG. 25, the protective layer 4150 of the embodiment forms a convex portion 4150P adjacent to the through hole on the lower surface so as to have the thickness T2 of the protective layer 30 of the first comparative example.

Accordingly, the embodiment was able to confirm that a width W4-2 of the first connection part 4410 corresponds to a width of the through hole by the convex portion 4150P. Through this, the embodiment can efficiently reduce a pitch between a plurality of first connection parts.

Furthermore, the embodiment was able to confirm that a height of the first connection part 4410 is maintained by the convex portion 4150P. Through this, it was confirmed that the first connection part 4410 was disposed with a greater thickness T3-2 than the first comparative example and the second comparative example, even when the same amount of solder was applied.

In addition, the semiconductor package may include an underfill 4430. The underfill 4430 may be disposed to cover a periphery of the semiconductor chip 4420 on the circuit board. However, the underfill 4430 may be optionally omitted. For example, the semiconductor package may perform the function of the underfill 4430 in the molding layer 4450 while the underfill 4430 is omitted.

The semiconductor package may include a second connection part 4440. The second connection part 4440 is disposed on the wiring electrode of the circuit board. The second connection part 4440 may be a bump. As an example, the second connection part 4440 may be a solder bump, but is not limited thereto. For example, the second connection part 4440 may be a post bump. For example, the second connection part 4440 may include a copper post and a solder bump disposed on the copper post. An upper surface of the second connection part 4440 may be positioned higher than the upper surface of the semiconductor chip 4420. This may prevent the semiconductor device 4420 from being damaged during a process of bonding an external substrate 4500 disposed on the second connection part 4440.

The semiconductor package may include a molding layer 4450. The molding layer 4450 may mold components disposed on the circuit board. The molding layer 4450 may include an opening. For example, the molding layer 4450 may include an opening that overlaps an upper surface of the second connection part 4440 in a vertical direction.

The semiconductor package includes a third connection part 4460.

The third connection part 4460 may be disposed under a wiring electrode disposed at a lowermost side of the circuit board. The third connection part 4460 may be a solder for connecting the semiconductor package of the embodiment to a separate external substrate (e.g., a main board of an electronic device), but is not limited thereto.

The semiconductor package includes an external substrate 4500. The external substrate 4500 may mean a separate substrate coupled with the circuit board of the embodiment. For example, the semiconductor chip 4420 disposed on the circuit board may be a logic chip such as a CPU or GPU, and the external substrate 4500 may mean a memory substrate on which a memory chip connected to the logic chip is disposed. The external substrate 4500 may be an interposer that connects between the memory substrate on which the semiconductor chip 4420 corresponding to the memory chip is disposed and the circuit board.

The external substrate 4500 may include an insulating layer 4510, a circuit layer 4520, a through electrode 4530, an upper protective layer 4540, and a lower protective layer 4550. In addition, the external substrate 4500 may include a fourth connection part 4560. The fourth connection part 4560 may be disposed between the external substrate 4500 and the third connection part 4440.

In addition, the semiconductor package may include a fifth connection part 4570. The fifth connection part 4570 may be disposed on the external substrate 4500.

The semiconductor package may include a semiconductor chip 4580. The semiconductor chip 4580 may be mounted on the external substrate 4500 through the fifth connection part 4570.

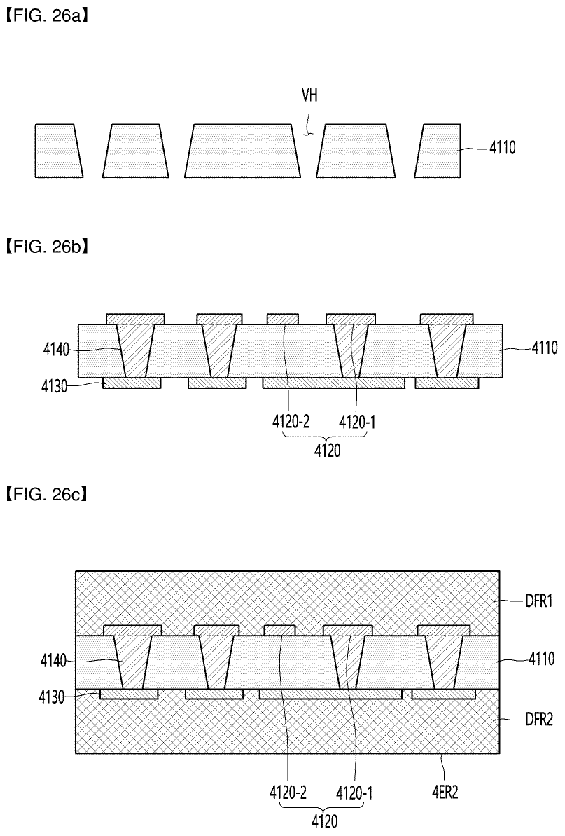

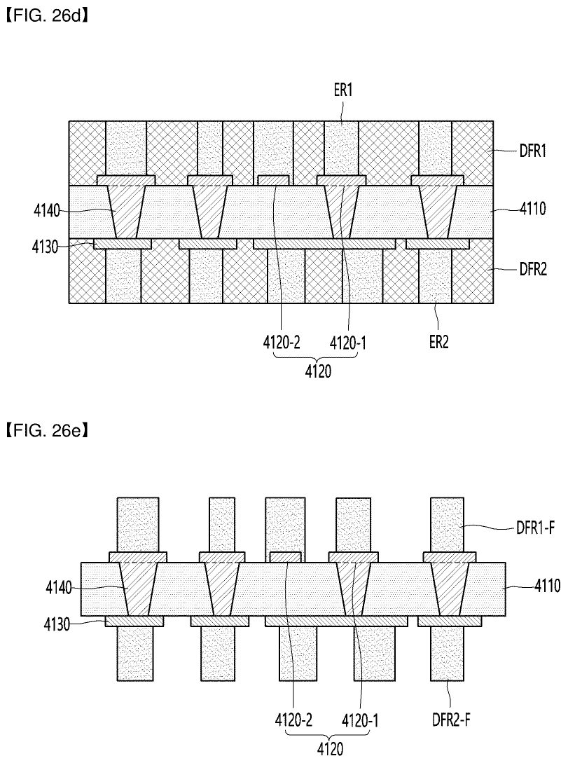

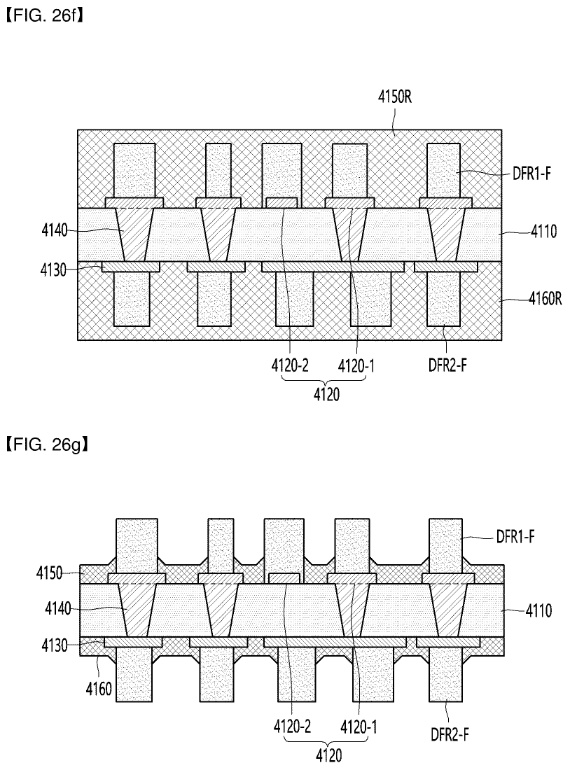

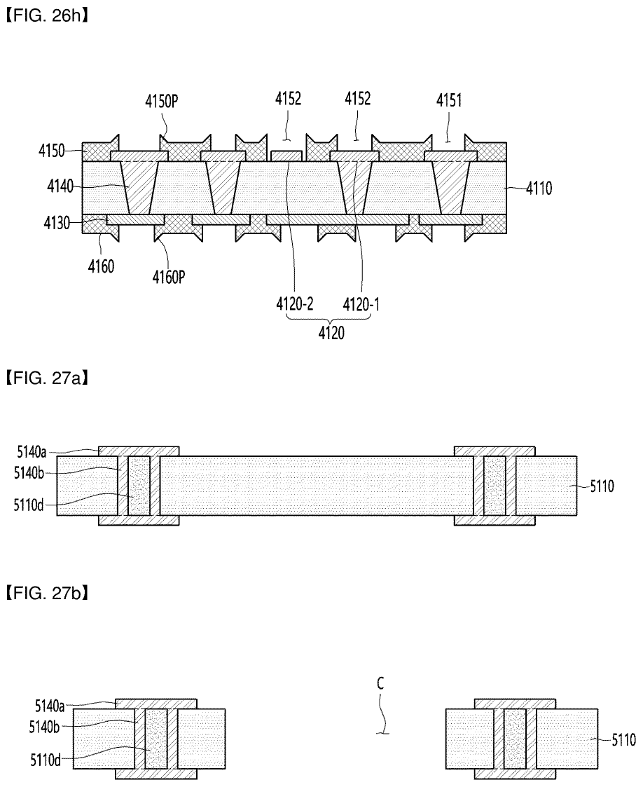

FIGS. 26a to 26h are cross-sectional views for describing a method of manufacturing the circuit board shown in FIG. 10 in order of processes.

Referring to FIG. 26a, in the embodiment, an insulating layer 4110 is prepared. Thereafter, the embodiment forms a through hole VH passing through the upper surface and the lower surface of the insulating layer 4110.

Next, referring to FIG. 26b, the embodiment can form a via electrode 4140 filling the through hole VH on the insulating layer 4110. In addition, the embodiment can form an upper wiring electrode 4120 including a first pad 4120-1 and a second pad 4120-2 on the upper surface of the insulating layer 4110. In addition, the embodiment can form a lower wiring electrode 4130 on the lower surface of the insulating layer 4110.

Thereafter, referring to FIG. 26c, the embodiment forms a first dry film DFR1 on the insulating layer 4110. At this time, the first dry film DFR1 may be disposed to cover the upper wiring electrode 4120 entirely. In addition, the embodiment forms a second dry film DFR2 under the insulating layer 4110. At this time, the second dry film DFR2 may be disposed to cover the lower wiring electrode 4130 entirely.

Next, referring to FIG. 26d, the embodiment can perform a process of forming a first exposure pattern ER1 by exposing and curing a first dry film DFR1. At this time, the first dry film DFR1 may be a negative type. Accordingly, a portion that has not been exposed to light may be removed by subsequent development, and the first exposure pattern ER1 that has been exposed to light may not be removed. In addition, the embodiment can perform a process of forming a second exposure pattern ER2 by exposing and curing a second dry film DFR2. At this time, the second dry film DFR2 may be a negative type. Accordingly, a portion that has not been exposed to light may be removed by subsequent development, and the second exposure pattern ER2 that has been exposed to light may not be removed.

Next, referring to FIG. 26e, the embodiment may perform a process of forming a first resist pattern DFR1-F by removing a region of the first dry film DFR1 except for the first exposure pattern ER1. At this time, the first resist pattern DFR1-F may be formed on the insulating layer 4110 to correspond to a region where a through hole of the first protective layer 4150 is to be formed. In addition, the embodiment may perform a process of forming a second resist pattern DFR2-F by removing a region of the second dry film DFR2 except for the second exposure pattern ER2. At this time, the second resist pattern DFR2-F may be formed on the insulating layer 4110 to correspond to a region where a through hole of the second protective layer 4160 is to be formed.

Next, referring to FIG. 26f, the embodiment may form a first protective layer 4150R covering the first resist pattern DFR1-F on the insulating layer 4110. In addition, the embodiment may form a second protective layer 4160R covering the second resist pattern DFR2-F under the insulating layer 4110.

Next, referring to FIG. 26g, the embodiment can perform a process of reducing a thickness of the first protective layer 4150R to a target thickness by removing the first protective layer 4150R by etching.

The etching process may be performed using an organic alkaline compound containing tetramethylammonium hydroxide (TMAH) or trimethyl-2-hydroxyethylammonium hydroxide (choline).

In addition, the embodiment may perform a process of reducing the thickness of the second protective layer 4160R to a target thickness by removing the second protective layer 4160R by etching. At this time, the embodiment controls the etching conditions in a region adjacent to the first resist pattern DFR1-F and a region adjacent to the second resist pattern DFR2-F. For example, the embodiment controls an etching degree of the first protective layer 150R in a region adjacent to the first resist pattern DFR1-F. Through this, the first protective layer 4150R can include a convex portion 4150P formed adjacent to the first resist pattern DFR1-F. Correspondingly, the embodiment controls an etching degree of the second protective layer 4160R in a region adjacent to the second resist pattern DFR2-F. Through this, the second protective layer 4160R can include a convex portion 4160P formed adjacent to the second resist pattern DFR2-F.

Next, referring to FIG. 26h, the embodiment can perform a process of removing the first resist pattern DFR1-F and the second resist pattern DFR2-F. Accordingly, the embodiment can form a through hole and a convex portion in the first protective layer 4150 and the second protective layer 4160 corresponding to the first resist pattern DFR1-F and the second resist pattern DFR2-F, respectively.

Hereinafter, a method for manufacturing a semiconductor package according to another embodiment is described.

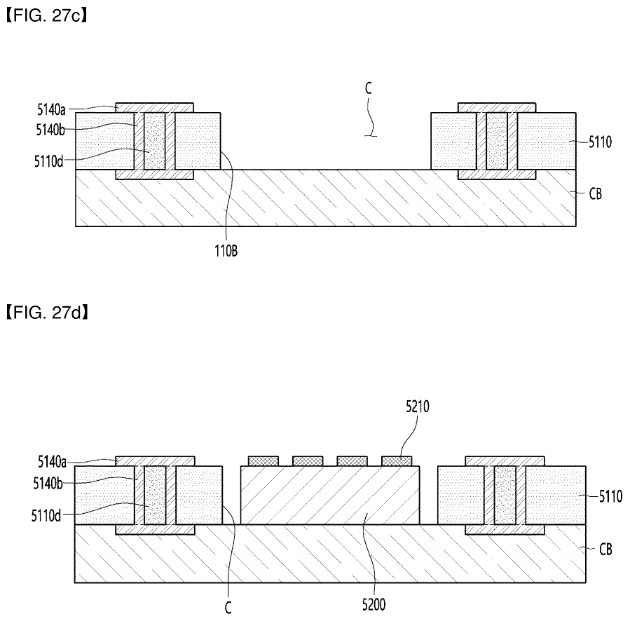

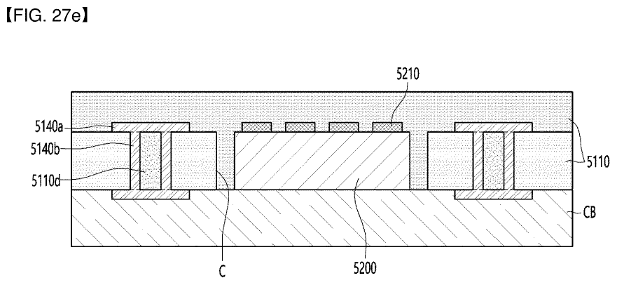

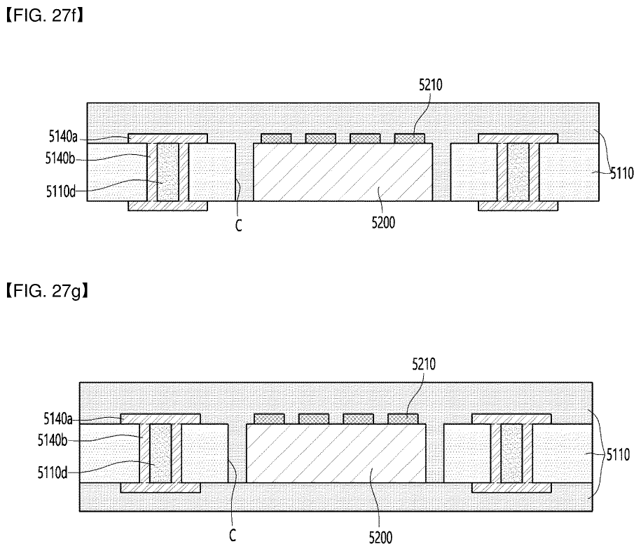

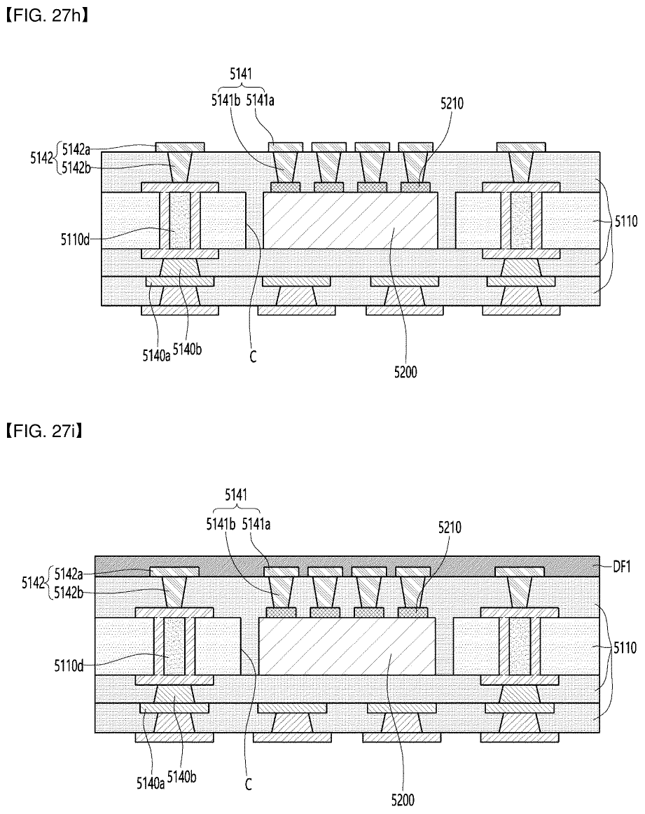

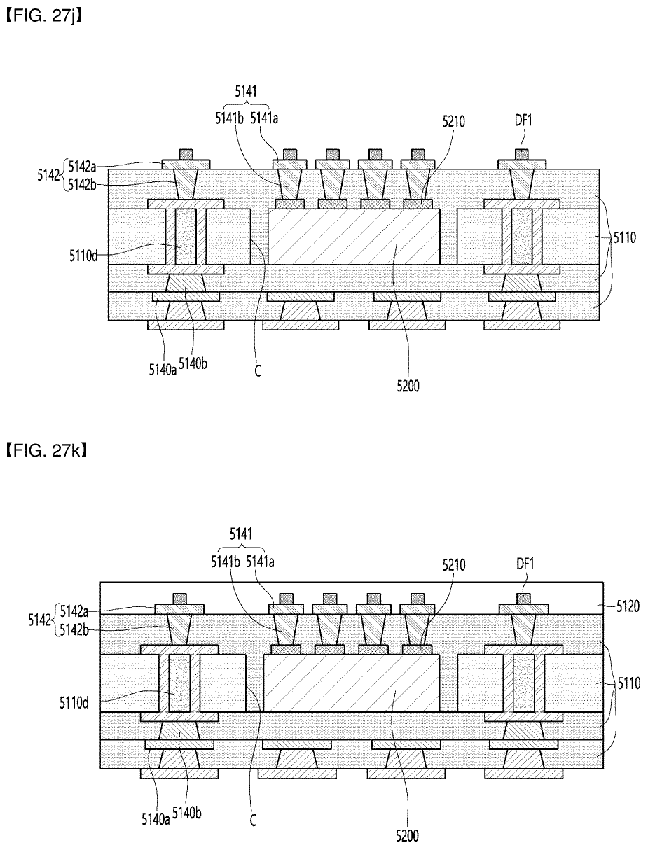

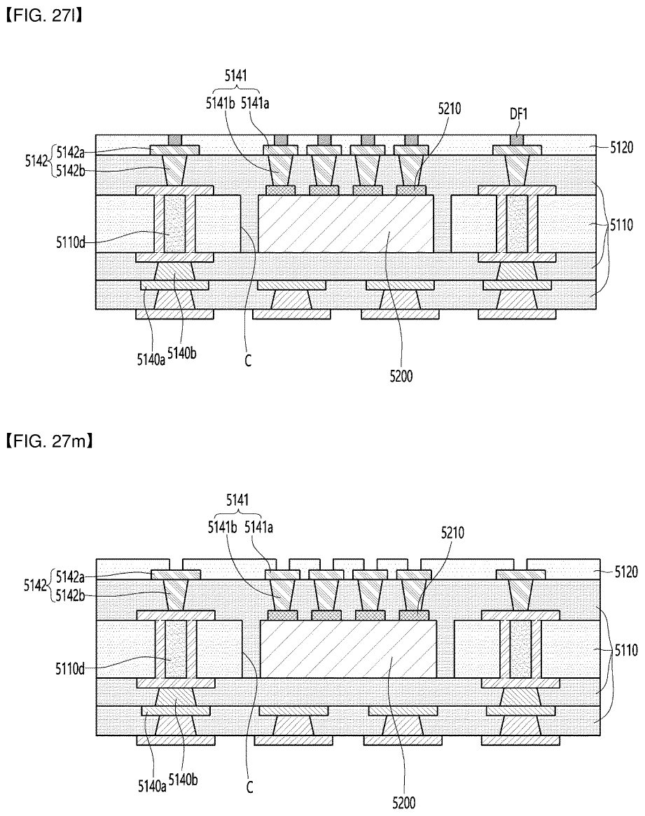

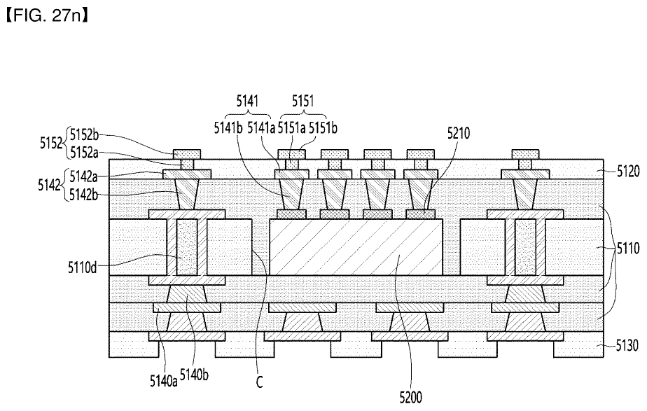

FIGS. 27a to 27n are cross-sectional views for describing a method of manufacturing a circuit board according to another embodiment in order of processes. The embodiment described below is similar to a structure of the circuit board illustrated in FIG. 1a. However, a position of the cavity (C) in the circuit board and a number of layers of the insulating layer described below may be different from that of the circuit board illustrated in FIG. 1a.

Referring to FIG. 27a, the embodiment prepares one layer of the insulating layer 5110. The one layer of the insulating layer 5110 may correspond to the third insulating layer 110a of the first embodiment of FIG. 1A.

Thereafter, the embodiment may perform a process of forming an electrode part on the one layer of the insulating layer 5110. For example, the embodiment may perform a process of forming a wiring electrode 5140a on each of the upper surface and the lower surface of the one layer of the insulating layer 5110, a process of forming a via electrode 5140b passing through the one layer of the insulating layer 5110, and a process of forming an insulating member 5110d surrounded by the via electrode 5140b.

Referring to FIG. 27b, the embodiment may perform a process of forming a cavity (C) passing through the one layer of the insulating layer 5110. For example, the cavity (C) in the first embodiment of FIG. 1a is provided in the second insulating layer 110b1. Unlike this, the cavity (C) in the other embodiment may be provided in the one layer of the insulating layer 5110, which is the third insulating layer disposed in a center. In addition, although the cavity (C) is illustrated in FIG. 27b as being provided passing through the one layer of the insulating layer 5110, the embodiment is not limited thereto, and the cavity (C) may have a groove shape that does not pass through the insulating layer 5110.

Referring to FIG. 27c, the embodiment may perform a process of attaching a carrier film CB to a lower portion of the insulating layer 5110. The carrier film CB may be provided to cover the lower portion of the cavity (C) of the insulating layer 5110.

Referring to FIG. 27d, the embodiment may perform a process of attaching a connection member 200 on a carrier film CB vertically overlapping a cavity (C).

Referring to FIG. 27e, the embodiment may laminate a laminated insulating layer (e.g., an upper insulating layer) filling the cavity (C) on the insulating layer 5110.

Referring to FIG. 27f, the embodiment may perform a process of removing the carrier film CB.

Referring to FIG. 27g, the embodiment may laminate an additional laminated insulating layer under the insulating layer 5110. For example, the embodiment may perform a process of laminating a lower insulating layer. At this time, a number of layers of the upper insulating layer and the lower insulating layer may be different. For example, as shown in FIG. 27h, a number of layers of the upper insulating layer may be smaller than a number of layers of the lower insulating layer.

Referring to FIG. 27h, the embodiment may perform a process of forming a wiring electrode and a via electrode in the upper insulating layer and the lower insulating layer, respectively. At this time, a first electrode part 5141 including a first pad 5141a and a first via electrode 5141b that overlap with a connection member 5200 in the vertical direction, and a second electrode part 5142 including a second pad 5142a and a second via electrode 5142b that do not overlap with the connection member 5200 in the vertical direction may be formed in the upper insulating layer.

Referring to FIG. 27i, the embodiment may perform a process of forming a dry film DF1 covering the first pad 5141a and the second pad 5142a on the upper insulating layer of the insulating layer 5110.

Referring to FIG. 27j, the embodiment can perform a process of exposing and developing the dry film (DF1) to form an exposure pattern at a position corresponding to a position where the first and second through holes are to be formed in the protective layer. At this time, the exposure pattern may have substantially the same widths of an upper surface of the exposure pattern and an lower surface of the exposure pattern, and further, the widths of the upper surface of the exposure pattern and the lower surface of the exposure pattern may be 20 um or less, respectively.

Referring to FIG. 27k, the embodiment may perform a process of forming a first protective layer 5120 covering the exposure pattern on the upper insulating layer.

Referring to FIG. 27l, the embodiment can perform a process of removing the first protective layer 5120 by etching, thereby allowing an upper surface of the first protective layer 5120 to have a height lower than an upper surface of the exposure pattern.

Referring to FIG. 27m, the embodiment can perform a process of removing the exposure pattern. Accordingly, the embodiment can form a through hole TH in the first protective layer 5120 corresponding to a position where the exposure pattern is removed.

Referring to FIG. 27n, the embodiment can perform a process of forming a first bonding part 5151 and a second bonding part 5152 in the through hole of the first protective layer 5120. For example, the embodiment can form a first bonding part 5151 including a first through portion 5151a and a first protruding portion 5151b that overlap with the connection member 5200 in the vertical direction. In addition, the embodiment can form a second bonding part 5152 including a second through portion 5152a and a second protruding portion 5152b that do not overlap with the connection member 5200 in the vertical direction.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
an insulating structure including an upper surface and a lower surface;
a protective layer disposed on the upper surface of the insulating structure;
a connection member embedded in the insulating structure; and
a wiring electrode embedded in the insulating structure and including an upper pad part disposed between the insulating structure and the protective layer,
a first via electrode electrically connected to the connection member by passing through a portion of the insulating structure from the upper pad part and having a width narrower than a width of the upper pad part;
a second via electrode embedded in the insulating structure and disposed closer to a lower surface of the insulating structure than the connection member; and
a bonding part including a protruding portion disposed on the protective layer and a through portion passing through the protective layer from the protruding portion and directly contacting the upper pad part,
wherein the bonding part includes a first bonding part overlapping the connection member in a vertical direction, and a second bonding part not overlapping the connection member in the vertical direction, and
wherein a slope angle of each of a through portion of the first bonding part and a through portion of the second bonding part with respect to the upper surface of the insulating structure is closer to vertical than a slope angle of the second via electrode with respect to the upper surface of the insulating structure.

2. The circuit board of claim 1, wherein the first bonding part is provided in plural, and
wherein a separation distance in a horizontal direction between two first bonding parts that are closest to each other among the plurality of first bonding parts is 26 um or less.

3. The circuit board of claim 2, wherein each of the plurality of first bonding parts includes a plurality of first protruding portions, and
wherein a width of each of the plurality of first protruding portions in the horizontal direction is 29 μm to 34 μm.

4. The circuit board of claim 1, wherein the protective layer includes a plurality of first fillers, and
wherein the through portion of the first bonding part does not contact the plurality of first fillers.

5. The circuit board of claim 1, wherein the first via electrode includes a first overlapping via electrode overlapping the connection member in the vertical direction, and
wherein a slope angle of the first overlapping via electrode is same as a slope angle of the through portion of the first bonding part.

6. The circuit board of claim 1, wherein the insulating structure includes a plurality of laminated insulating layers disposed between the upper surface of the insulating structure and the lower surface of the insulating structure,
wherein the plurality of laminated insulating layers include an upper insulating layer forming the upper surface of the insulating structure, and a lower insulating layer forming the lower surface of the insulating structure,
wherein the wiring layer further includes a plurality of wiring electrodes disposed respectively within the plurality of laminated insulating layers, a plurality of via electrodes connecting the plurality of wiring electrodes, and a lower pad part disposed on the lower surface of the insulating structure,
wherein the plurality of via electrodes further include a plurality of upper vias overlapping the connection member along a horizontal direction, and a plurality of lower vias disposed between the plurality of upper vias and the lower surface of the insulating layer, and
wherein a slope angle of the upper via is symmetrical to a slope angle of the lower via.

7. The circuit board of claim 6, wherein a thickness of the upper insulating layer is thinner than a thickness of the lower insulating layer.

8. The circuit board of claim 5, wherein a first through portion of the first bonding part vertically overlaps at least a portion of the first overlapping via electrode.

9. The circuit board of claim 1, wherein the insulating structure includes a side surface positioned between the upper surface and the lower surface,
wherein the protective layer includes a lower surface of the protective layer facing the upper surface of the insulating structure, an upper surface of the protective layer corresponding to the lower surface of the protective layer, and a side surface of the protective layer positioned between the lower surface of the protective layer and the upper surface of the protective laver, and
wherein the side surface of the protective layer includes an inner surface surrounding the first through portion and the second through portion, respectively, and an outer surface adjacent to the side surface of the insulating structure, and
wherein a length in the vertical direction of the inner surface is different from a length in the vertical direction of the outer surface.

10. The circuit board of claim 9, wherein the length in the vertical direction of the inner surface is greater than the length in the vertical direction of the outer surface.

11. The circuit board of claim 9, wherein the upper surface of the protective layer is provided with a convex portion surrounding the first through portion and the second through portion.

12. The circuit board of claim 9, wherein a height of the upper surface of the protective layer in an adjacent region closest to the first through portion and the second through portion is higher than a height of the upper surface of the protective layer in a region farther away from the first through portion and the second through portion than the adjacent region.

13. The circuit board of claim 4, wherein at least one of the plurality of first fillers is positioned higher than the upper surface of the protective layer.

14. The circuit board of claim 3, wherein a width in the horizontal direction of the first through portion and a width in the horizontal direction of the protruding portion of each of the plurality of first bonding parts are same.

15. The circuit board of claim 6, wherein the first via electrode includes an overlapping via electrode disposed between the connecting member and the protective layer, and
wherein a slope angle of the overlapping via electrode and the slope angle of the upper via are different.

16. The circuit board of claim 15, wherein the slope angle of the overlapping via electrode is closer to perpendicular to the upper surface of the insulating structure than the slope angle of the upper via.

17. The circuit board of claim 13, wherein the upper surface of the protective layer includes a concave portion concave toward the insulating structure and a convex portion convex in a direction away from the insulating structure.

18. The circuit board of claim 17, wherein a curvature of the concave portion and the convex portion corresponds to a curvature of the first filler.

19. The circuit board of claim 3, wherein a surface roughness of an interface between the protective layer and the first through portion is smaller than a surface roughness of an interface between the protective layer and the first protruding portion.

20. The circuit board of claim 1, wherein a width of the through portion of the first bonding part in the horizontal direction is equal to a width of the through portion of the second bonding part in the horizontal direction.
